(19) United States
(12) Patent Application Publication
(10) Pub. No.: US 2025/0336860 A1
(43) Pub. Date: Oct. 30, 2025

(54) HYBRID-BONDING STACK INCLUDING A PROCESSOR DIE AND MULTI-CACHE-LEVEL MEMORY DIES AND METHODS OF FORMING THE SAME

(71) Applicant: Taiwan Semiconductor Manufacturing Company Limited, Hsinchu (TW)

(72) Inventors: Yi Ching Ong, Hsinchu (TW); Kuo-Ching Huang, Hsinchu City (TW); Yu-Sheng Chen, Taoyuan City (TW); Kuei-Hung Shen, Hsinchu City (TW); Yu-Jen Wang, Hsinchu City (TW); Harry-Hak-Lay Chuang, Zhubei City (TW)

(21) Appl. No.: 18/647,104

(22) Filed: Apr. 26, 2024

(51) Int. Cl. H01L 23/00; H01L 25/18

(52) U.S. Cl. CPC H01L 24/08; H01L 24/16; H01L 24/32; H01L 24/73; H01L 24/80; H01L 24/96; H01L 24/97; H01L 25/18; H01L 2224/08145; H01L 2224/16145; H01L 2224/16225; H01L 2224/32145; H01L 2224/32225; H01L 2224/73204; H01L 2224/80895; H01L 2224/80896; H01L 2224/96; H01L 2224/97; H01L 2225/06513; H01L 2225/06517; H01L 2924/1431; H01L 2924/1436

(57) ABSTRACT

A device structure may be formed by bonding a processor die with at least one memory die using metal-to-metal bonding. The processor die comprises processing units for performing logical operations. The at least one memory die comprises at least two types of memory arrays selected from a static random access memory array, a gain cell random access memory array, and magnetoresistive random access memory array, and a resistive random access memory array. A bonded assembly of the processor die and the at least one memory die is formed. The bonded assembly can be bonded to an interposer using a first array of solder material portions that is bonded to on-die bump structures of the processor die and to a first subset of first bump structures of the interposer.

### BACKGROUND

There is a growing demand in the semiconductor industry for providing multiple levels of cache memories for a processor with a wide signal bandwidth and with reduced signal delay.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram illustrating a sequence of processing steps that may be used to form composite packages according to an aspect of the present disclosure.

FIG. 2A is a vertical cross-sectional view of a processor wafer that may be used during fabrication of the composite packages of the present disclosure.

FIG. 2B is an exemplary layout of a processor die within the processor wafer of FIG. 2A.

FIG. 3 is a vertical cross-sectional view of a memory wafer that may be used during fabrication of the composite packages of the present disclosure.

FIGS. 4A-4C are sequential vertical cross-sectional views of a first exemplary structure during formation of a first reconstituted memory wafer that may be used during fabrication of the composite packages of the present disclosure.

FIGS. 5A-5C are sequential vertical cross-sectional views of a second exemplary structure during formation of a second reconstituted memory wafer that may be used during fabrication of the composite packages of the present disclosure.

FIGS. 6A-6K are vertical cross-sectional view of various configurations of a first composite package according to embodiments of the present disclosure.

FIGS. 7A-7K are vertical cross-sectional view of various configurations of a second composite package according to embodiments of the present disclosure.

FIGS. 8A-8C are circuit schematics of various memory elements that may be used in the memory dies of the present disclosure.

FIGS. 9A-9L are schematic vertical cross-sectional views of various configurations of the first composite package of the present disclosure.

FIGS. 10A-10L are schematic vertical cross-sectional views of various configurations of the second composite package of the present disclosure.

FIGS. 11A-11L are schematic vertical cross-sectional views of various configurations of a third composite package of the present disclosure.

FIGS. 12A-12L are schematic vertical cross-sectional views of various configurations of a fourth composite package of the present disclosure.

FIG. 13 is a vertical cross-sectional view of an interposer according to an embodiment of the present disclosure.

FIG. 14 is a vertical cross-sectional view of a bonded assembly including the interposer and a logic die according to an embodiment of the present disclosure.

FIG. 15 is a vertical cross-sectional view of a bonded assembly including the interposer, the logic die, and a high-bandwidth memory (HBM) die according to an embodiment of the present disclosure.

FIG. 16 is a vertical cross-sectional view of a bonded assembly including the interposer, the logic die, the HBM die, and a composite package according to an embodiment of the present disclosure.

FIG. 17 is a vertical cross-sectional view of a bonded assembly including the interposer, the logic die, an HBM die, the composite package, and a packaging substrate according to an embodiment of the present disclosure.

FIG. 18 is a first flowchart illustrating steps for forming a device structure according to an embodiment of the present disclosure.

FIG. 19 is a second flowchart illustrating steps for forming a device structure according to an embodiment of the present disclosure.

FIG. 20 is a third flowchart illustrating steps for forming a device structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. Generally, all devices of the present disclosure may be rotated unless otherwise specified, and the spatially relative descriptors used herein may likewise be interpreted accordingly. Unless explicitly stated otherwise, each element having the same reference numeral is presumed to have the same material composition and to have a thickness within a same thickness range.

The present disclosure is directed to a system-on-chip (SoIC) architecture using an innovative memory combination that is suitable for high performance applications. High performance applications such as artificial intelligence (AI) applications require a large amount of cache memory. Other related signal routing schemes between processors and cache memory dies face significant hurdles in physical scaling for advanced generations. Particularly, two-dimensional scaling approaches are encountering limitations due to physical limits of signal routing.

According to an aspect of the present disclosure, a three-dimensional (3D) stacking method is disclosed, which uses hybrid bonding to form a composite package including a processor die with a combination of cache memories of different types having different signal latencies and different signal bandwidths. For example, the different types of cache memories may include static random access memories (SRAMs), gain cell random access memories (GCRAMs), magnetoresistive random access memories (MRAMs), and/or resistive random access memories (RRAMs). Metal-to-metal bonding with the dies with the composite package provide high bandwidth signal paths for the cache memories, and may effectively meet requirements for multiple cache level memories. For example, a set of cache memories including a level 1 cache memory, a level 2 cache memory, a level 3 cache memory, and a level 4 cache memory may be provided by the combination of different types of memories in the composite die of the present disclosure. The composite package of various embodiments of the present disclosure may enhance cache density, thereby meeting the exacting demands of high performance processing applications for advanced semiconductor packages. Additionally, the integration of diverse cache levels within the composite package may satisfy a spectrum of diverse design requirements to provide versatile solutions for various applications. Various embodiments of the present disclosure are now described with reference to accompanying drawings.

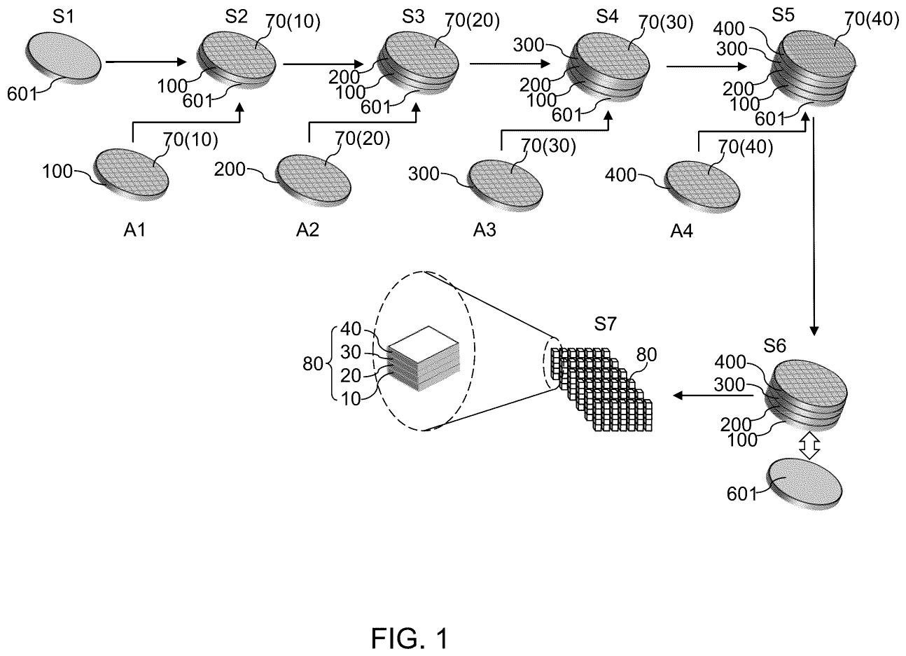

Referring to FIG. 1, a sequence of processing steps that may be used to form composite packages 80 according to an aspect of the present disclosure is schematically illustrated. At a first processing step S1, a carrier wafer 601 is provided, which may comprise a circular wafer or a polygonal wafer such as a rectangular wafer. In embodiments in which the carrier wafer 601 comprises a circular wafer, the diameter of the carrier wafer 601 may be, for example, 200 mm, 300 mm, 450 mm, etc. Generally, the carrier wafer 601 may comprise a semiconductor wafer, an insulating wafer, a conductive wafer, or a composite wafer having sufficient mechanical strength to support additional wafers to be subsequently attached thereto. The thickness of the carrier wafer 601 may be in a range from 500 microns to 2 mm, although lesser and greater thicknesses may also be used. In one embodiment, the carrier wafer 601 may comprise a commercially available silicon wafer.

Referring to a first auxiliary processing step A1, a first wafer 100 is provided. The first wafer 100 comprises a two-dimensional array of first semiconductor dies 70. Each of the first semiconductor dies 70 comprises a respective array of front metal bonding pads configured for metal-to-metal bonding. As used herein, metal-to-metal bonding refers to a bonding method in which two sets of metal bonding pads provided in two semiconductor dies are brought into direct contact with each other and are annealed at an elevated temperature to induce intermetallic diffusion of a metal across each interface between mating pairs of the metal bonding pads to a degree that provides bonding between the mating pairs of the metal bonding pads. Metal-to-metal bonding does not use any intermediary material such as a solder material. Rather, the material diffusion of the metal in the mating pairs of metal bonding pads into each other causes bonding between the mating pairs of metal bonding pads. Thus, each mating pair of metal bonding pads used in metal-to-metal bonding are in direct contact at grain boundaries that are not contained within a Euclidean plane at an atomic scale, i.e., at the scale of nanometers. Typical materials that may be used for metal-to-metal bonding include copper, copper alloys, nickel, aluminum, silver, gold, etc. Metal-to-metal bonding may be used without an addition type of bonding, or may be used in conjunction with dielectric-to-dielectric bonding. A combination of metal-to-metal bonding and dielectric-to-dielectric bonding is referred to as hybrid bonding.

According to an aspect of the present disclosure, the first semiconductor dies 70 in the first wafer 100 comprises processor dies 10. In one embodiment, a two-dimensional array of first semiconductor dies 70 in the first wafer 100 may comprise a two-dimensional array of processor dies 10. A processor die refers to a semiconductor die that contains at least one processing unit. A processing unit refers to any electronic component configured for executing instructions and performing operations within a computer system. A processing unit may be any of a central processing unit (CPU), a graphics processing unit (GPU), digital signal processor (DSP), a neural processing unit (NPU), an artificial intelligence (AI) accelerator, etc. Further, a processor die may include multiple processing units as in the embodiment of a system-on-chip (SoIC) die. For example, an SoIC die may comprise a CPU, a GPU, a DSP, and/or an NPU. In addition, the processor die 10 may optionally include a cache memory, which is referred to as an L1 cache memory (i.e., a first-level cache memory) comprising a static random access memory (SRAM). Such a cache memory that is present within a processor die is generally referred to as an embedded cache memory.

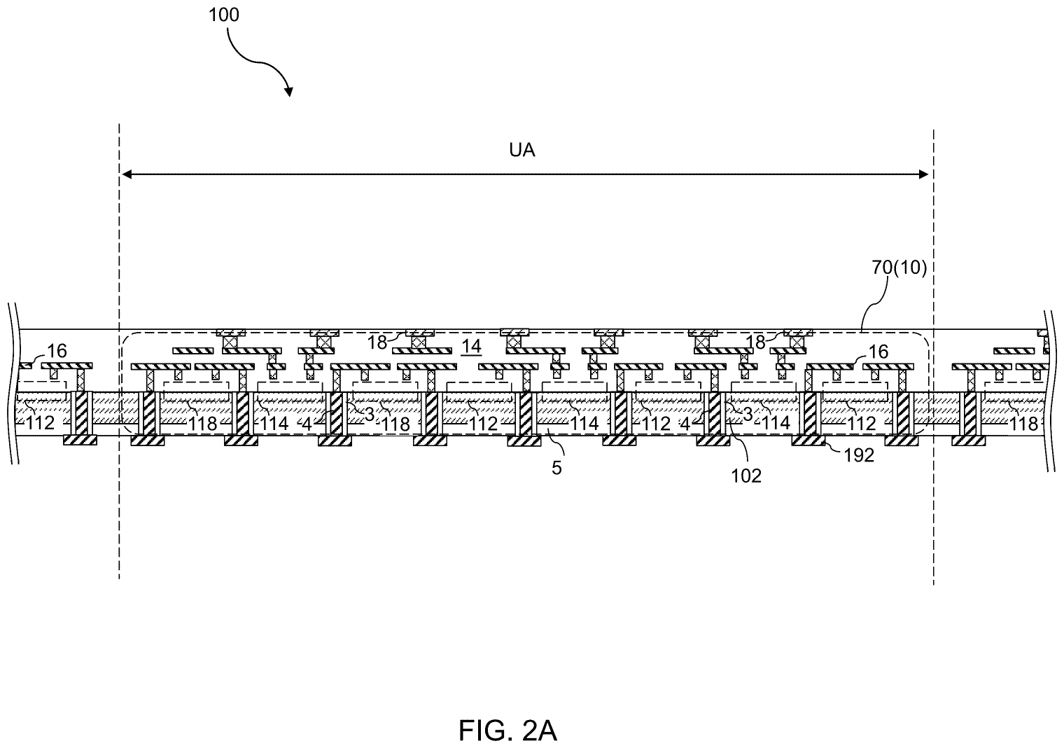

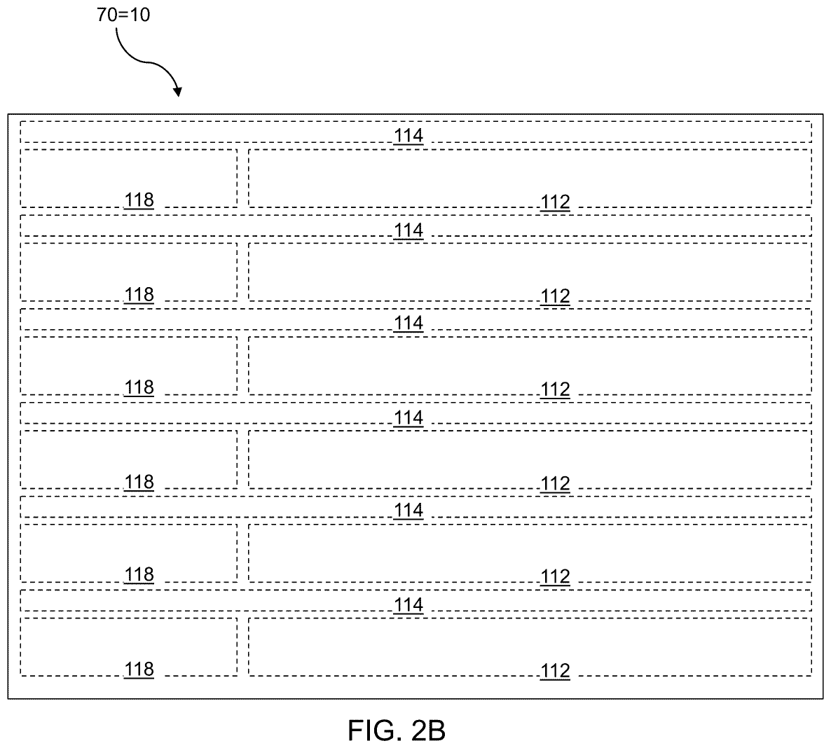

Referring to FIG. 2A, an example of a first wafer 100 that may be provided at the first auxiliary processing step A1 in FIG. 1 is illustrated in detail. A unit area UA of the first wafer 100 includes a single semiconductor die 70, which is a processor die 10. In this example, the first wafer 100 may comprise a semiconductor-based wafer including a semiconductor substrate that continuously extends over an entire area of the first wafer 100 as a single contiguous structure. As used herein, a semiconductor-based wafer refers to a wafer including a single contiguous semiconductor substrate having a same lateral extent as the wafer. In this embodiment, the first wafer 100 as illustrated in FIG. 2A may be provided, for example, by providing a semiconductor substrate having a thickness (such as a thickness in a range from 500 microns to 1 mm), by forming vertically-extending via cavities having a depth in a range from 5 microns to 30 microns in an upper portion of the semiconductor substrate and by filling the vertically-extending via cavities with combinations of an insulating spacer 3 and a through-substrate via (TSV) structure 4, by forming various functional units (112, 114, 118) including a respective set of semiconductor devices on a top surface of, and/or within an upper portion of, the semiconductor substrate, by forming metal interconnect structures 16 and front metal bonding pads 18 formed within dielectric material layers 14, by thinning the semiconductor substrate from the backside to provide the semiconductor substrate 102 as illustrated in FIG. 2A, by recessing the backside surface of the semiconductor substrate 102, by forming a backside insulating layers 5 in the recessed volume on the backside of the semiconductor substrate 102, by exposing backside surfaces of the TSV structures 4, and by forming on-die bump structures 192 on the physically exposed surfaces of the TSV structures 4. The front metal bonding pads 18 may be arranged as a two-dimensional periodic array such as a rectangular array or a hexagonal array. The pitch, i.e., the periodicity, of an array of front metal bonding pads 18 along a direction of periodicity may be in a range from 1 micron to 20 microns, although lesser and grater pitches may also be employed. The on-die bump structures 192 may comprise microbump structures configured for chip-to-chip (C2) bonding, or may comprise solder-bonding pads configured for controlled collapse chip connection (C4) bonding.

The thickness of the semiconductor substrate 102 after thinning may be in a range from 1 micron to 30 microns, and each of the on-die bump structures 192 may be formed on a respective one of the TSV structures 4. Electrically conductive paths may be formed between the front metal bonding pads 18 and the various functional units (112, 114, 118). Additional electrically conductive paths may be formed between the on-die bump structures 192 and the various functional units (112, 114, 118). Each such electrically conductive path may comprise a respective one of the TSV structures 4. Optionally, electrically conductive paths may be formed between the front metal bonding pads 18 and the on-die bump structures 192. Each such electrically conductive path may comprise a respective one of the TSV structures 4.

The first wafer 100 may comprise a two-dimensional periodic repetition of semiconductor dies 70, which is a two-dimensional repetition of processor dies 10. The semiconductor dies 70 within the first wafer 100 are referred to as first semiconductor dies 70, which are processor dies 10. The first semiconductor dies 70 are interconnected to one another by the semiconductor substrate 102 upon formation of the first wafer 100, and each of the first semiconductor dies 70 comprises a respective portion of the semiconductor substrate 102, which continuously extends over the entire area of the first wafer 100.

Generally, a first wafer 100 including a two-dimensional array of first semiconductor dies 70 including arrays of first front metal bonding pads 18 and arrays of on-die bump structures 192 may be attached to a top surface of a carrier wafer 601. The first wafer 100 may comprise a semiconductor-based wafer.

Referring to FIG. 2B, an exemplary layout of a processor die 10 (comprising a first semiconductor die 70 within the first wafer 100) is illustrated in a plan view. The plan view of a view along a vertical direction that is perpendicular to the top surface and the bottom surface of the first wafer 100. The processor die 10 comprises at least one processing unit 112 for performing logical operations, at least one unified memory controller unit 114, and at least one input/output controller unit 118. In one embodiment, the processor die 10 may comprise a plurality of processing units 112, a plurality of unified memory controller units 114, and/or a plurality of input/output controller units 118. The at least one processing unit 112 may include one or more instances of any, and/or each, a CPU, a GPU, a DSP, an NPU, an AI accelerator, etc.

As will be discussed in subsequent sections in detail, memory dies to be subsequently bonded to the processor die 10 through metal-to-metal bonding may comprise at least two types of memory arrays. As used herein, a “type” of memory array refers to a memory array using a same operational principle for data storage. The at least two-types of memory arrays may be selected from a static random access memory (SRAM) array, a gain cell random access memory (GCRAM) array, and magnetoresistive random access memory (MRAM) array, and a resistive random access memory (RRAM) array. An SRAM uses latching of coupled sets of field effect transistors as an operating principle. A GCRAM uses amplification of the effect of a trapped electrical charge in a transistor circuit as an operating principle. An MRAM uses changes in magnetoresistance as a function of relative alignment of magnetization directions of two magnetization layers as an operating principle. An RRAM uses changes in resistance in a programmable material that offers at least two different resistive states as an operating principle. The various types of memory arrays have different latency and different memory density (i.e., the number of memory bits that may be stored per unit area).

Each of the memory dies to be subsequently used may have a respective set of memory address input nodes, and the processor die 10 comprises at least one unified memory controller unit 114 each including a set of memory address output nodes that may be subsequently electrically connected to each set of memory address input nodes within one or more memory dies that are subsequently bonded to the processor die 10.

In one embodiment, a unified memory controller unit 114 may be configured to access each memory element within the at least two types of memory arrays through selection of bit values of a memory address that is transmitted to the set of memory address output nodes. In one embodiment, a unified memory controller unit 114 may include a set of data input node, and each memory die to be subsequently bonded to the processor die 10 may comprise a respective set of data output nodes that is electrically connected to the set of data input nodes. In one embodiment, a unified memory controller unit 114 may be configured to receive data stored in any memory element within the at least two types of memory arrays through the set of data input nodes.

Referring back to FIG. 1, and specifically to a second auxiliary processing step A2 illustrated in FIG. 1, a second wafer 200 is provided. The second wafer 200 includes a two-dimensional array of second semiconductor dies 70 including arrays of second front metal bonding pads and arrays of second backside metal bonding pads. The second semiconductor dies 70 may comprise first memory dies 20. Thus, the second wafer 200 may comprise a two-dimensional array of first memory dies 20. The periodicity of the two-dimensional array of first memory dies 20 may be the same as the periodicity of the two-dimensional array of processor dies 10 in the first wafer 100. Generally, the second wafer 200 may comprise a semiconductor-based wafer or a reconstituted wafer. In some embodiments, the second wafer 200 may be oriented such that first bonding pads of the second wafer 200 face bonding pads of the second wafer 100 to be subsequently bonded with the first bonding pads of the second wafer.

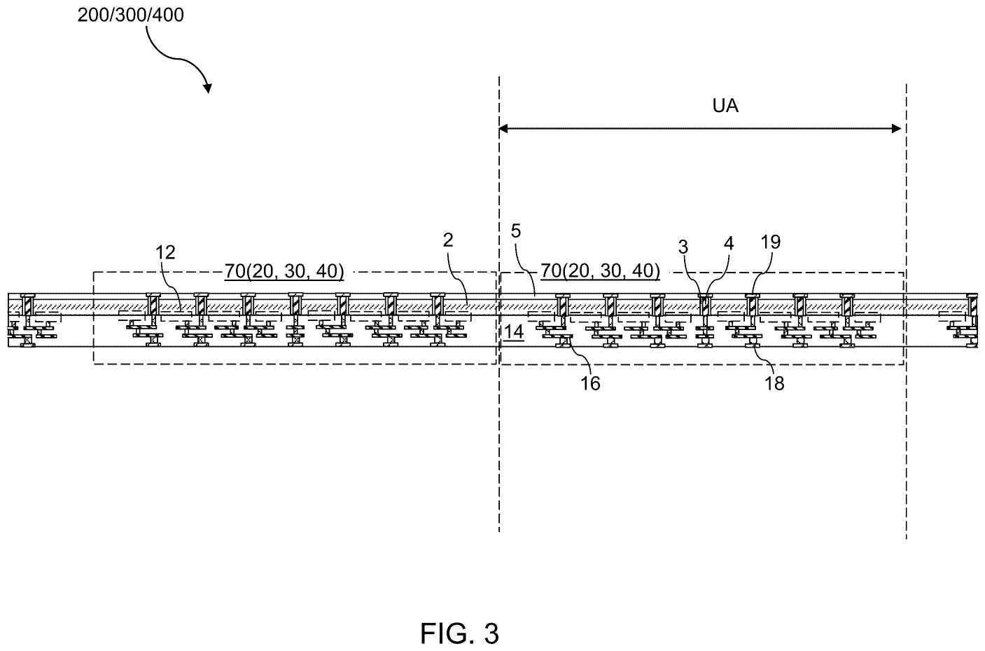

Referring to FIG. 3, an example of a second wafer 200 that may be provided at the second auxiliary processing step A2 in FIG. 1 is illustrated. A third wafer 300 and/or a fourth wafer 400 to be subsequently used in later processing steps of FIG. 1 may have the same structure as, or may have a structure that is similar to, the second wafer 200 illustrated in FIG. 3. Each unit area UA within the second wafer 200 may comprise a respective semiconductor die 70, which may be a first memory die 20. Similarly, each unit area UA within the third wafer 300 may comprise a respective semiconductor die 70, which may be a second memory die 30, and each unit area UA within the fourth wafer 400 may comprise a respective semiconductor die 70, which may be a third memory die 30. As such, all descriptions related to the second wafer 200 are equally applicable to the third wafer 300 and to the fourth wafer 400.

In one embodiment, the second wafer 200 may comprise a semiconductor-based wafer including a semiconductor substrate that continuously extends over an entire area of the second wafer 200 as a single contiguous structure. In this embodiment, the second wafer 200 as illustrated in FIG. 3 may be provided, for example, by providing a semiconductor substrate having a thickness (such as a thickness in a range from 500 microns to 1 mm), by forming vertically-extending via cavities having a depth in a range from 5 microns to 30 microns in an upper portion of the semiconductor substrate and filling the vertically-extending via cavities with combinations of an insulating spacer 3 and a through-substrate via (TSV) structure 4, by forming semiconductor devices 12 on a top surface of, and/or within an upper portion of, the semiconductor substrate, by forming metal interconnect structures 16 and front metal bonding pads 18 formed within dielectric material layers 14, thinning the semiconductor substrate from the backside to provide the semiconductor substrate 2 as illustrated in FIG. 3, and by forming backside metal bonding pads 19 within a backside insulating layers 5 on the backside of the semiconductor substrate 2. The backside metal bonding pads 19 may be arranged as a two-dimensional periodic array such as a rectangular array or a hexagonal array. The pitch, i.e., the periodicity, of an array of backside metal bonding pads 19 along a direction of periodicity may be the same as the pitch of an array of front metal bonding pads 18 of the semiconductor dies 70 in the first wafer 100. For example, the pitch of an array of backside metal bonding pads 19 may be in a range from 1 micron to 20 microns, although lesser and grater pitches may also be employed. Likewise, the front metal bonding pads 18 of the semiconductor dies 70 in the second wafer 200 may be arranged as a two-dimensional periodic array such as a rectangular array or a hexagonal array. The pitch of an array of front metal bonding pads 18 in the semiconductor dies 70 of the second wafer 200 along a direction of periodicity may be in a range from 1 micron to 20 microns, although lesser and grater pitches may also be employed. Generally, the pitch and the pattern for each mating arrays of metal bonding pads (18, 19) may be matched to provide effective metal-to-metal bonding for all the wafers to be bonded among one another.

The thickness of the semiconductor substrate 2 after thinning may be in a range from 1 microns to 30 microns, and each of the backside metal bonding pads 19 may be formed on a respective one of the TSV structures 4. Electrically conductive paths may be formed between the front metal bonding pads 18 and the backside metal bonding pads 19. Each such electrically conductive path may comprise a respective one of the TSV structures 4. The second wafer 200 may comprise a two-dimensional periodic repetition of semiconductor dies 70. The semiconductor dies 70 within the second wafer 200 are memory dies, which are referred to as first memory dies 20. The first memory dies 20 are interconnected to one another, and each of the first memory dies 20 comprises a respective portion of the semiconductor substrate 2, which continuously extends over the entire area of the second wafer 200.

The semiconductor devices 12 within each first memory die 20 comprises at least one type of memory array and at least one memory interface control unit. In one embodiment, the semiconductor devices 12 within each first memory die 20 may comprise at least two types of memory arrays. The at least two-types of memory arrays may be selected from a static random access memory (SRAM) array, a gain cell random access memory (GCRAM) array, and magnetoresistive random access memory (MRAM) array, and a resistive random access memory (RRAM) array.

In one embodiment, each memory interface control unit within a first memory die 20 may provide address decoding and routing. In other words, each memory interface control unit may interpret incoming memory addresses received from a processor die 10 to be subsequently bonded to the first memory die 20, and may identify the specific location within a memory array in the first memory die 20 in which the target data needs to be accessed or stored. Further, each memory interface control unit within a first memory die 20 may provide control of memory operations. Thus, each memory interface control unit within a first memory die 20 may coordinate read and write operations within a memory array in the first memory die 20 based on instructions received from the processor die 10, and may manage data retrieval, storage, and modification. In addition, each memory interface control unit within a first memory die 20 may provide data communication. Thus, each memory interface control unit within a first memory die 20 may facilitate the transfer of data bits between a memory array of the first memory die 20 and the processor die 10, and may ensure the accurate transmission of information according to the specified memory addressing.

Further, each memory interface control unit within a first memory die 20 may provide timing and synchronization. In other words, each memory interface control unit within a first memory die 20 may manage the timing and synchronization of memory access to each memory array in the first memory die 20, and may ensure proper alignment between the operation of the first memory die 20 and the requirements of the processor die 10. Each memory interface control unit within a first memory die 20 may provide error handling and correction. In this embodiment, each memory interface control unit within a first memory die 20 may include mechanisms for error detection and correction to enable maintenance of data integrity during read and write operations. Each memory interface control unit within a first memory die 20 may provide interface protocol handling. In other words, each memory interface control unit within a first memory die 20 may deal with the protocols that allow for communication between the first memory die 20 and the processor die 10, ensuring compatibility and adherence to established communication standards. In addition, each memory interface control unit within a first memory die 20 may provide power management. For example, each memory interface control unit within a first memory die 20 may oversee power-related aspects within the first memory die 20, thereby optimizing power usage and managing energy consumption during memory operations. Generally, each memory interface control unit within a first memory die 20 may facilitate efficient and accurate communication between the memory array(s) in the first memory die 20 and a processor die 10 to be subsequently bonded to the first memory die 20, ensuring seamless data transfer, access, and storage within the first memory die 20.

In one embodiment, each first memory die 20 comprises a respective set of memory address input nodes within a respective memory interface control unit (which may comprise a subset of the semiconductor devices 12 within the first memory die 20). In one embodiment, each memory interface control unit may comprise a respective set of memory address input nodes. Each processor die 10 described above may comprise a unified memory controller unit 114 including a set of memory address output nodes that are electrically connected to each set of memory address input nodes within each first memory die 20.

In one embodiment, each first memory die 20 may comprise at least two types of memory arrays using different operational principles and having different signal latencies. In one embodiment, a unified memory controller unit 114 in a processor die 10 described above may be configured to access each memory element within the at least two types of memory arrays that are present within a first memory die 20 through selection of bit values of a memory address that is transmitted to the set of memory address output nodes. In one embodiment, the unified memory controller unit 114 in a processor die 10 may include a set of data input nodes, and a first memory die 20 may comprise a set of data output nodes that is electrically connected to the set of data input nodes. In this embodiment, the unified memory controller unit 114 of the processor die 10 may be configured to receive data stored in any memory element within the at least two types of memory arrays through the set of data input nodes.

In one embodiment, memory latencies are different among the at least two types of memory arrays in the first memory die 20. In this embodiment, the unified memory controller unit 114 in a processor die 10 to be subsequently bonded to the first memory die 20 may be configured to sequentially address two different types of memory arrays among the at least two types of memory arrays, and to sequentially receive two sets of data stored in the two different types of memory arrays with a temporal offset using a same set of data input nodes.

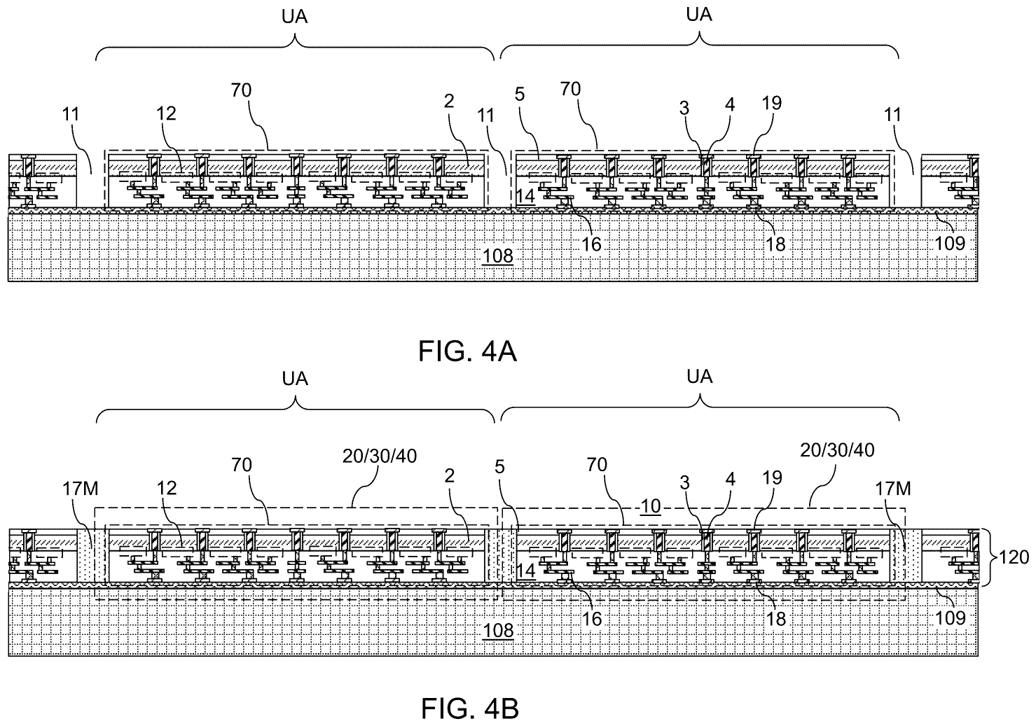

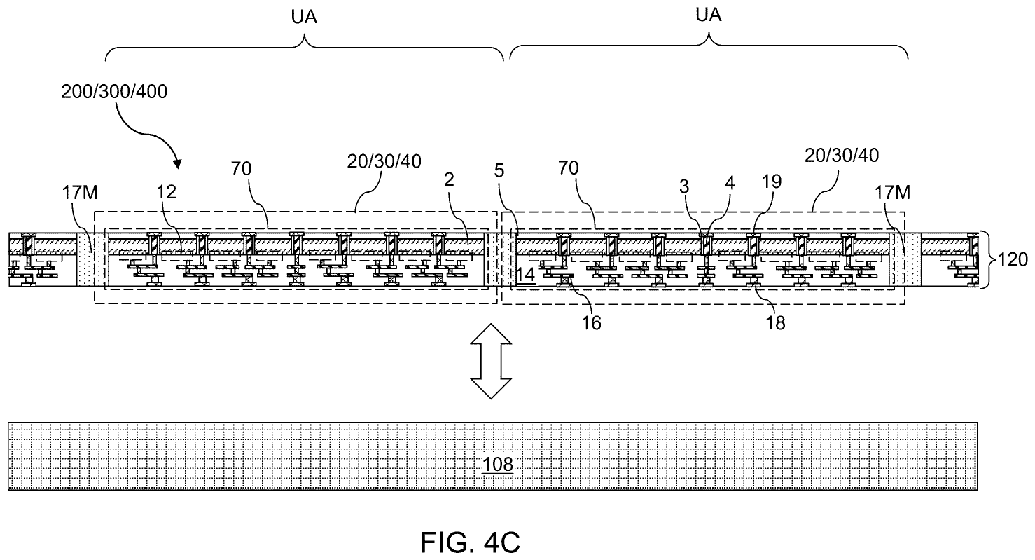

Alternatively, the second wafer 200 provided at the second auxiliary processing step A2 illustrated in FIG. 1 may comprise a reconstituted wafer instead of a semiconductor-based wafer. FIGS. 4A-4C are sequential schematic vertical cross-sectional views of a first exemplary structure during formation of a first reconstituted wafer 120 that may be used as the second wafer 200.

Referring to FIG. 4A, the first exemplary structure comprises a carrier substrate 108, a first adhesive layer 109 formed on a top surface of the carrier substrate 108, and a two-dimensional array of semiconductor dies 70 that are attached to the first adhesive layer 109. The carrier substrate 108 may include an optically transparent substrate such as a glass substrate or a sapphire substrate. The carrier substrate 108 may have a circular shape or a polygonal shape in a top-down view. In embodiments in which the carrier substrate 108 has a circular shape in the top-down view, the diameter of the carrier substrate 108 may be in a range from 150 mm to 450 mm, although lesser and greater diameters may be used. In addition, the thickness of the carrier substrate 108 may be in a range from 500 microns to 2,000 microns, although lesser and greater thicknesses may also be used. Alternatively, the carrier substrate 108 may be provided in a rectangular panel format. The dimensions of the carrier substrate 108 in such alternative embodiments may be substantially the same.

The first adhesive layer 109 may be applied to the front-side surface of the carrier substrate 108. In one embodiment, the first adhesive layer 109 may be a light-to-heat conversion (LTHC) layer. The LTHC layer may be a solvent-based coating applied using a spin coating method. The LTHC layer may convert ultraviolet light to heat, which may cause the material of the LTHC layer to lose adhesion. Alternatively, the first adhesive layer 109 may include a thermally decomposing adhesive material. For example, the first adhesive layer 109 may include an acrylic pressure-sensitive adhesive that decomposes at an elevated temperature. The debonding temperature of the thermally decomposing adhesive material may be in a range from 150 degrees to 200 degrees Celsius.

The first semiconductor dies 70 (which may be the first memory dies 20) may be attached to the first adhesive layer 109 in a two-dimensional periodic pattern, i.e., as a two-dimensional periodic array of first semiconductor dies 70. The area of the repetition unit is herein referred to as a unit area UA. Each first semiconductor die 70 may comprise a semiconductor substrate 2, an array of through-substrate via (TSV) structures 4, an array of insulating spacers 3, semiconductor devices 12 formed on a top side of the semiconductor substrate 2, metal interconnect structures 16 and front metal bonding pads 18 that are formed within dielectric material layers 14, a backside insulating layer 5, and backside metal bonding pads 19 formed within the backside insulating layer 5 and contacting a backside surface of a respective one of the TSV structures 4. In one embodiment, the first semiconductor dies 70 may be provided by dicing a wafer having substantially the same structure as the second wafer 200 described above into discrete semiconductor dies. The first semiconductor dies 70 may comprise logic dies, system-on-chip (SoC) dies, memory dies, or any other type of semiconductor dies known in the art. Gaps 11 between first semiconductor dies 70 attached to the first adhesive layer 109 in a two-dimensional periodic pattern may provide spacing and isolation between neighboring pairs of first semiconductor dies 70.

Referring to FIG. 4B, a molding compound may be applied to the gaps 11 between neighboring pairs of semiconductor dies 70. The molding compound may include an epoxy-containing compound that may be hardened (i.e., cured) to provide a dielectric material portion having sufficient stiffness and mechanical strength. The molding compound may include epoxy resin, hardener, silica (as a filler material), and other additives. The molding compound may be provided in a liquid form or in a solid form depending on the viscosity and flowability. Liquid molding compound provides better handling, good flowability, less voids, better fill, and less flow marks. Solid molding compound provides less cure shrinkage, better stand-off, and less die drift. A high filler content (such as 85% in weight) within an molding compound may shorten the time in mold, lower the mold shrinkage, and reduce the mold warpage. Uniform filler size distribution in the molding compound may reduce flow marks, and may enhance flowability. The curing temperature of the molding compound may be lower than the release (debonding) temperature of the first adhesive layer 109 in embodiments in which the adhesive layer includes a thermally debonding material. For example, the curing temperature of the molding compound may be in a range from 125° C. to 150° C.

The molding compound may be cured at a curing temperature to form an molding compound matrix 17M that laterally surrounds the two-dimensional array of semiconductor dies 70. The molding compound matrix 17M includes a plurality of molding compound die frames that are interconnected to one another. Each molding compound die frame is a portion of the molding compound matrix 17M that is located within an area of a repetition unit within a two-dimensional periodic array of structures overlying the carrier substrate 108. Thus, each molding compound die frame laterally surrounds and embeds a respective semiconductor die 70. Young's modulus of pure epoxy is about 3.35 GPa, and Young's modulus of the molding compound may be higher than Young's modulus of pure epoxy by adding additives. Young's modulus of molding compound may be greater than 3.5 GPa. In some embodiments, suitable alternative molding materials may be used for the molding compound matrix 17M.

Portions of the molding compound matrix 17M that overlies the horizontal plane including the top surfaces of the semiconductor dies 70 may be removed by a planarization process. For example, the portions of the molding compound matrix 17M that overlies the horizontal plane may be removed using a chemical mechanical planarization (CMP). The combination of the remaining portion of the molding compound matrix 17M and the semiconductor dies 70 comprises a reconstituted wafer 120. Each portion of the molding compound matrix 17M located within a unit area UA constitutes an molding compound die frame.

Referring to FIG. 4C, the first adhesive layer 109 may be decomposed by ultraviolet radiation or by a thermal anneal at a debonding temperature. In embodiments in which the carrier substrate 108 includes an optically transparent material and the first adhesive layer 109 includes an LTHC layer, the first adhesive layer 109 may be decomposed by irradiating ultraviolet light through the transparent carrier substrate. The LTHC layer absorbs the ultraviolet radiation and generates heat, which decomposes the material of the LTHC layer and cause the transparent carrier substrate to be detached from the reconstituted wafer 120. In embodiments in which the first adhesive layer 109 includes a thermally decomposing adhesive material, a thermal anneal process at a debonding temperature may be performed to detach the carrier substrate 108 from the reconstituted wafer 120. The detached reconstituted wafer 120 may be used as the second wafer 200 as provided at the auxiliary processing step A2 in FIG. 1.

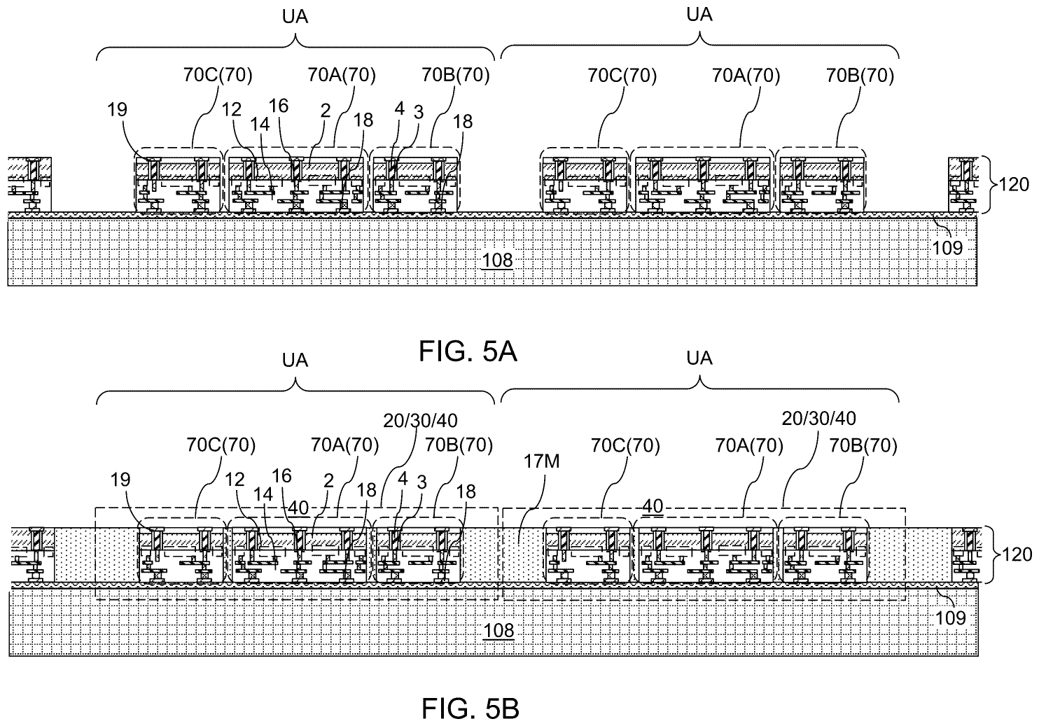

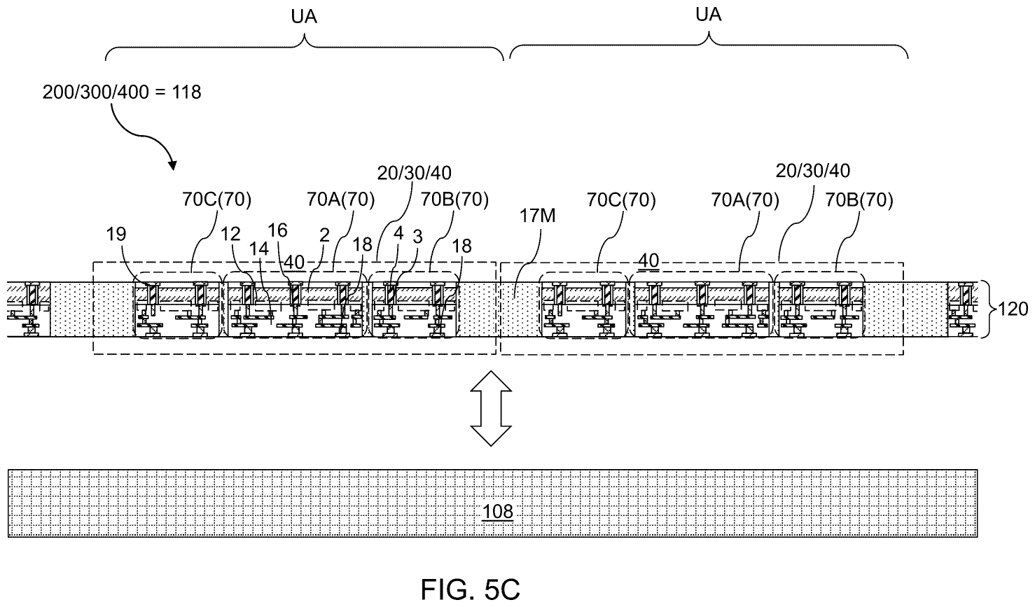

In some embodiments, a reconstituted wafer 120 that is used as the second wafer 200 at the first auxiliary processing step A1 illustrated in FIG. 1 may comprise a plurality of semiconductor dies 70 and/or at least one optional dummy die within each unit area UA. FIGS. 5A-5C are sequential schematic vertical cross-sectional views of a second exemplary structure during formation of a second reconstituted wafer 120 that may be used as the second wafer 200.

Referring to FIG. 5A, the second exemplary structure may be derived from the first exemplary structure illustrated in FIG. 4A by using a plurality of semiconductor dies (70A, 70B, 70C) per unit area UA in lieu of a single semiconductor die 70 per unit area UA in the first exemplary structure of FIG. 3A. In this embodiment, the plurality of semiconductor dies (70A, 70B, 70C) within each unit area UA comprises at least a first-type semiconductor die 70A, a second-type semiconductor die 70B, and optionally a third-type semiconductor die 70C and additional semiconductor dies (not illustrated). Each of the semiconductor dies 70 within a unit area UA may comprise a memory die. In one embodiment, the semiconductor dies 70 within a unit area UA may comprise two or more types of memory dies including a respective memory array of different types. For example, first-type semiconductor die 70A may comprise an SRAM die, a second-type semiconductor die 70B may comprise a GCRAM die, a third-type semiconductor die 70C may comprise an MRAM die, and an additional semiconductor die, if present, may comprise an RRAM die.

Alternatively, one or more of the plurality of semiconductor dies (70A, 70B, 70C) may be replaced with a dummy die, which is a non-functional die that is used for the sake of facilitating a planarization process that planarizes the molding compound matrix 17M. For example, one or more of the second-type semiconductor die 70B, the optional third-type semiconductor die 70C, and the optional additional semiconductor dies (not illustrated) may be replaced with a dummy die. Such embodiments are expressly contemplated herein.

Each of the plurality of semiconductor dies (70A, 70B, 70C) may comprise a semiconductor substrate 2, an optional array of through-substrate via (TSV) structures 4, an optional array of insulating spacers 3, semiconductor devices 12 formed on a top side of the semiconductor substrate 2, metal interconnect structures 16 and front metal bonding pads 18 that are formed within dielectric material layers 14, a backside insulating layer 5, and backside metal bonding pads 19 formed within the backside insulating layer 5 and contacting a backside surface of a respective one of the TSV structures 4. At least one, a plurality, and/or each, of the plurality of semiconductor dies (70A, 70B, 70C) may comprise a respective array of through-substrate via (TSV) structures 4 and a respective array of insulating spacers 3. At least one, a plurality, and/or each, of the plurality of semiconductor dies (70A, 70B, 70C) may comprise a respective set of semiconductor devices 12. The semiconductor devices 12 may comprise at least one type of memory array and at least one memory interface control unit as described above with reference to FIG. 3.

Referring to FIG. 5B, the processing steps described with reference to FIG. 4B may be performed to form a molding compound matrix 17M that laterally surrounds each semiconductor die 70 over the carrier substrate 108.

Referring to FIG. 5C, the processing steps described with reference to FIG. 4C may be performed to detach the reconstituted wafer 120 from the carrier substrate 108. The reconstituted wafer 120 may be used as the second wafer 200 as provided at the second auxiliary processing step A2 in FIG. 1.

Referring to a third processing step S3 illustrated in FIG. 1, the second wafer 200 may be bonded to the first wafer 100 by performing a first metal-to-metal bonding process. In one embodiment, the arrays of first top metal bonding pads in the first wafer 100 are bonded to the arrays of second bottom metal bonding pads in the second wafer 200 through first intermetallic diffusion. In one embodiment, the first top metal bonding pads in the first wafer 100 may be copper bonding pads, the arrays of second bottom metal bonding pads in the second wafer 200 may be additional copper bonding pads, and the metal-to-metal bonding may be copper-to-copper bonding. Additionally, dielectric-to-dielectric bonding such as silicon oxide-to-silicon oxide bonding may be performed between a topmost insulating layer of the first wafer 100 and a bottommost insulating layer of the second wafer 200 to provide a hybrid bonding, which is also referred to an SoIC bonding.

In one embodiment, the first top metal bonding pads in the first wafer 100 may comprise first front metal bonding pads 18 formed within the dielectric material layers 14 of the first wafer 100, and the second bottom metal bonding pads in the second wafer 200 may comprise second backside metal bonding pads 19 formed within the backside insulating layer 5 of the second wafer 200. In this embodiment, a dielectric-to-dielectric bonding between the dielectric material layers 14 of the first wafer 100 and the backside insulating layer 5 of the second wafer 200 may be performed concurrently with the metal-to-metal bonding.

In another embodiment, the first top metal bonding pads in the first wafer 100 may comprise first front metal bonding pads 18 formed within the dielectric material layers 14 of the first wafer 100, and the second bottom metal bonding pads in the second wafer 200 may comprise second front metal bonding pads 18 formed within the dielectric material layers 14 of the second wafer 200. In this embodiment, a dielectric-to-dielectric bonding between the dielectric material layers 14 of the first wafer 100 and the dielectric material layers 14 of the second wafer 200 may be performed concurrently with the metal-to-metal bonding.

In yet another embodiment, the first top metal bonding pads in the first wafer 100 may comprise first backside metal bonding pads 19 formed within the backside insulating layer 5 of the first wafer 100, and the second bottom metal bonding pads in the second wafer 200 may comprise second backside metal bonding pads 19 formed within the backside insulating layer 5 of the second wafer 200. In this embodiment, a dielectric-to-dielectric bonding between the backside insulating layer 5 of the first wafer 100 and the backside insulating layer 5 of the second wafer 200 may be performed concurrently with the metal-to-metal bonding.

In still another embodiment, the first top metal bonding pads in the first wafer 100 may comprise first backside metal bonding pads 19 formed within the backside insulating layer 5 of the first wafer 100, and the second bottom metal bonding pads in the second wafer 200 may comprise second front metal bonding pads 18 formed within the dielectric material layers 14 of the second wafer 200. In this embodiment, a dielectric-to-dielectric bonding between the backside insulating layer 5 of the first wafer 100 and the dielectric material layers 14 of the second wafer 200 may be performed concurrently with the metal-to-metal bonding.

Generally, the array of first semiconductor dies 70 (which is an array of processor dies 10) in the first wafer 100 and the array of second semiconductor dies 70 (which is an array of first memory dies 20) in the second wafer 200 may have the same shape for each unit area UA, and may have the same two-dimensional periodicity. Generally, a second wafer 200 including a two-dimensional array of second semiconductor dies 70 including arrays of second front metal bonding pads 18 and arrays of second backside metal bonding pads 19 may be attached to the first wafer 100 by performing a first metal-to-metal bonding process in which the arrays of first front metal bonding pads 18 are bonded to the arrays of second backside metal bonding pads 19 through first intermetallic diffusion.

Referring to a third auxiliary processing step A3 illustrated in FIG. 1, a third wafer 300 is provided. The third wafer 300 includes a two-dimensional array of third semiconductor dies 70 including arrays of third front metal bonding pads and arrays of third backside metal bonding pads. The array of third semiconductor dies 70 may be an array of second memory dies 30. The second memory dies 30 may have any configuration that is described above with reference to the first memory dies 20, and thus, is capable of providing any of the functionalities described with reference to the first memory dies 20. The second memory dies 30 may, or may not, be the same as the first memory dies 20. In one embodiment, the second memory dies 30 may include at least one type of memory array that is not contained in the first memory dies 20. Alternatively or additionally, the first memory dies 20 may, or may not, lack (i.e., be free of) at least one type of memory array that is present within the first memory dies 20. The second memory dies 30 may, or may not, include a same set of types of memory arrays as the first memory dies 20.

Generally, the third wafer 300 may have a semiconductor-based wafer illustrated in FIG. 3, or may be a reconstituted wafer 120 illustrated in FIG. 4C or 5C. In other words, any of the semiconductor-based wafer illustrated in FIG. 3 or the reconstituted wafers 120 illustrated in FIGS. 4C and 5C may be used for the third wafer 300. Therefore, any type of wafer that may be used for the second wafer 200 may be used as the third wafer 300.

Referring to a fourth processing step S4 illustrated in FIG. 1, the third wafer 300 may be bonded to the second wafer 200 by performing a second metal-to-metal bonding process. The arrays of second front metal bonding pads 18 in the second wafer 200 are bonded to the arrays of third backside metal bonding pads 19 in the third wafer 300 through second intermetallic diffusion. In one embodiment, the second front metal bonding pads 18 in the second wafer 200 may be copper bonding pads, the arrays of third backside metal bonding pads 19 in the third wafer 300 may be additional copper bonding pads, and the metal-to-metal bonding may be copper-to-copper bonding. Additionally, dielectric-to-dielectric bonding such as silicon oxide-to-silicon oxide bonding may be performed between a topmost insulating layer of the second wafer 200 and a bottommost insulating layer of the third wafer 300.

In one embodiment, the second top metal bonding pads in the second wafer 200 may comprise second front metal bonding pads 18 formed within the dielectric material layers 14 of the second wafer 200, and the third bottom metal bonding pads in the third wafer 300 may comprise third backside metal bonding pads 19 formed within the backside insulating layer 5 of the third wafer 300. In this embodiment, a dielectric-to-dielectric bonding between the dielectric material layers 14 of the second wafer 200 and the backside insulating layer 5 of the third wafer 300 may be performed concurrently with the metal-to-metal bonding.

In another embodiment, the second top metal bonding pads in the second wafer 200 may comprise second front metal bonding pads 18 formed within the dielectric material layers 14 of the second wafer 200, and the third bottom metal bonding pads in the third wafer 300 may comprise third front metal bonding pads 18 formed within the dielectric material layers 14 of the third wafer 300. In this embodiment, a dielectric-to-dielectric bonding between the dielectric material layers 14 of the second wafer 200 and the dielectric material layers 14 of the third wafer 300 may be performed concurrently with the metal-to-metal bonding.

In yet another embodiment, the second top metal bonding pads in the second wafer 200 may comprise second backside metal bonding pads 19 formed within the backside insulating layer 5 of the second wafer 200, and the third bottom metal bonding pads in the third wafer 300 may comprise third backside metal bonding pads 19 formed within the backside insulating layer 5 of the third wafer 300. In this embodiment, a dielectric-to-dielectric bonding between the backside insulating layer 5 of the second wafer 200 and the backside insulating layer 5 of the third wafer 300 may be performed concurrently with the metal-to-metal bonding.

In still another embodiment, the second top metal bonding pads in the second wafer 200 may comprise second backside metal bonding pads 19 formed within the backside insulating layer 5 of the second wafer 200, and the third bottom metal bonding pads in the third wafer 300 may comprise third front metal bonding pads 18 formed within the dielectric material layers 14 of the third wafer 300. In this embodiment, a dielectric-to-dielectric bonding between the backside insulating layer 5 of the second wafer 200 and the dielectric material layers 14 of the third wafer 300 may be performed concurrently with the metal-to-metal bonding.

Generally, the array of second semiconductor dies 70 (which is an array of first memory dies 20) in the second wafer 200 and the array of third semiconductor dies 70 (which is an array of second memory dies 30) in the third wafer 300 may have the same shape for each unit area UA, and may have the same two-dimensional periodicity. Generally, a third wafer 300 including a two-dimensional array of third semiconductor dies 70 (which is a two-dimensional array of second memory dies 30) including arrays of third front metal bonding pads 18 and arrays of third backside metal bonding pads 19 may be attached to the second wafer 200 by performing a second metal-to-metal bonding process in which the arrays of second front metal bonding pads 18 are bonded to the arrays of third backside metal bonding pads 19 through second intermetallic diffusion.

Referring to a fourth auxiliary processing steps A4 in FIG. 1, a fourth wafer 400 is provided. The fourth wafer 400 includes a two-dimensional array of fourth semiconductor dies 70 including arrays of fourth front metal bonding pads and arrays of fourth backside metal bonding pads. The array of fourth semiconductor dies 70 may be an array of third memory dies 40. The third memory dies 40 may have any configuration that is described above with reference to the first memory dies 20, and thus, is capable of providing any of the functionalities described with reference to the first memory dies 20. The third memory dies 40 may, or may not, be the same as the first memory dies 20, and may, or may not, be the same as the second memory dies 30. In one embodiment, the third memory dies 40 may include at least one type of memory array that is not contained in the second memory dies 30, and/or may include at least one type of memory array that is not contained in the first memory dies 20. Alternatively and/or additionally, the third memory dies 40 may, or may not, lack (i.e., be free of) at least one type of memory array that is present within the second memory dies 30, and/or at least one type of memory array that is present within the first memory dies 20. The third memory dies 40 may, or may not, include a same set of types of memory arrays as the second memory dies 30 and/or the first memory dies 20.

Generally, the fourth wafer 400 may have a semiconductor-based wafer illustrated in FIG. 3, or may be a reconstituted wafer 120 illustrated in FIG. 4C or 5C. In other words, any of the semiconductor-based wafer illustrated in FIG. 3 or the reconstituted wafers 120 illustrated in FIGS. 4C and 5C may be used for the fourth wafer 400. Therefore, any type of wafer that may be used for the second wafer 200 may be used as the fourth wafer 400.

Referring to a fifth processing step S5 illustrated in FIG. 1, the fourth wafer 400 may be bonded to the third wafer 300 by performing a third metal-to-metal bonding process. The arrays of third front metal bonding pads 18 in the third wafer 300 are bonded to the arrays of fourth backside metal bonding pads 19 in the fourth wafer 400 through third intermetallic diffusion. In one embodiment, the third front metal bonding pads 18 in the third wafer 300 may be copper bonding pads, the arrays of fourth backside metal bonding pads 19 in the fourth wafer 400 may be additional copper bonding pads, and the metal-to-metal bonding may be copper-to-copper bonding. Additionally, dielectric-to-dielectric bonding such as silicon oxide-to-silicon oxide bonding may be performed between a topmost insulating layer of the third wafer 300 and a bottommost insulating layer of the fourth wafer 400.

In one embodiment, the third top metal bonding pads in the third wafer 300 may comprise third front metal bonding pads 18 formed within the dielectric material layers 14 of the third wafer 300, and the fourth bottom metal bonding pads in the fourth wafer 400 may comprise fourth backside metal bonding pads 19 formed within the backside insulating layer 5 of the fourth wafer 400. In this embodiment, a dielectric-to-dielectric bonding between the dielectric material layers 14 of the third wafer 300 and the backside insulating layer 5 of the fourth wafer 400 may be performed concurrently with the metal-to-metal bonding.

In another embodiment, the third top metal bonding pads in the third wafer 300 may comprise third front metal bonding pads 18 formed within the dielectric material layers 14 of the third wafer 300, and the fourth bottom metal bonding pads in the fourth wafer 400 may comprise fourth front metal bonding pads 18 formed within the dielectric material layers 14 of the fourth wafer 400. In this embodiment, a dielectric-to-dielectric bonding between the dielectric material layers 14 of the third wafer 300 and the dielectric material layers 14 of the fourth wafer 400 may be performed concurrently with the metal-to-metal bonding.

In yet another embodiment, the third top metal bonding pads in the third wafer 300 may comprise third backside metal bonding pads 19 formed within the backside insulating layer 5 of the third wafer 300, and the fourth bottom metal bonding pads in the fourth wafer 400 may comprise fourth backside metal bonding pads 19 formed within the backside insulating layer 5 of the fourth wafer 400. In this embodiment, a dielectric-to-dielectric bonding between the backside insulating layer 5 of the third wafer 300 and the backside insulating layer 5 of the fourth wafer 400 may be performed concurrently with the metal-to-metal bonding.

In still another embodiment, the third top metal bonding pads in the third wafer 300 may comprise third backside metal bonding pads 19 formed within the backside insulating layer 5 of the third wafer 300, and the fourth bottom metal bonding pads in the fourth wafer 400 may comprise fourth front metal bonding pads 18 formed within the dielectric material layers 14 of the fourth wafer 400. In this embodiment, a dielectric-to-dielectric bonding between the backside insulating layer 5 of the third wafer 300 and the dielectric material layers 14 of the fourth wafer 400 may be performed concurrently with the metal-to-metal bonding.

Generally, the array of third semiconductor dies 70 (which is an array of second memory dies 30) in the third wafer 300 and the array of fourth semiconductor dies 70 (which is an array of third memory dies 40) in the fourth wafer 400 may have the same shape for each unit area UA, and may have the same two-dimensional periodicity. Generally, a fourth wafer 400 including a two-dimensional array of fourth semiconductor dies 70 (which is a two-dimensional array of third memory dies 40) including arrays of fourth front metal bonding pads 18 and arrays of fourth backside metal bonding pads 19 may be attached to the third wafer 300 by performing a third metal-to-metal bonding process in which the arrays of third front metal bonding pads 18 are bonded to the arrays of fourth backside metal bonding pads 19 through third intermetallic diffusion.

While the present disclosure is described using an embodiment in which three wafers (such as the second wafer 200, the third wafer 300, and the fourth wafer 400) including a respective array of memory dies (20, 30, 40) are bonded to the first wafer 100 including an array of processor dies 10 using metal-to-metal bonding, the total number of wafers including a respective array of memory dies (20, 30, 40) and bonded to the first wafer 100 may be generally in a range from 1 to 10, such as from 2 to 6. In embodiments in which additional wafers including a respective array of memory dies are bonded to the bonded assembly including the carrier wafer 601, the first wafer 100, the second wafer 200, the third wafer 300, and the fourth wafer 400, a set of processing steps used to attach the third wafer 300 or the fourth wafer 400 may be repeated as many times as needed with suitable modifications to the processing steps in view of pre-existing wafers in the bonded assembly.

It should be noted that the ordinals such as “first,” “second,” “third,” and “fourth” are not parts of a name for an element, but are merely adjectives. As such, the first wafer 100 as described in the specification may be referred to as a first wafer, a second wafer, a third wafer, or as an i-th wafer in which i is an integer greater than 3. Likewise, the second wafer 200 as described in the specification may be referred to as a first wafer, a second wafer, a third wafer, or as a j-th wafer in which j is an integer greater than 3. Similarly, the third wafer 300 as described in the specification may be referred to as a first wafer, a second wafer, a third wafer, or as a k-th wafer in which k is an integer greater than 3. Likewise, the fourth wafer 400 as described in the specification may be referred to as a first wafer, a second wafer, a third wafer, or as an 1-th wafer in which 1 is an integer greater than 3.

Each unit area UA in the second wafer 200 includes a first memory die 20, which may include only a single second semiconductor die 70 or a plurality of second semiconductor dies 70. Each unit area UA in the third wafer 300 includes a second memory die 30, which may include only a single third semiconductor die 70 or a plurality of third semiconductor dies 70. Each unit area UA in the fourth wafer 400 includes a third memory die 40, which may include only a single fourth semiconductor die 70 or a plurality of fourth semiconductor dies 70. In embodiments in which each unit area UA in any wafer (200, 300, or 400) comprises a plurality of semiconductor dies 70, the plurality of semiconductor dies 70 may comprise a first-type semiconductor die 70A including a first-type memory array and a second-type semiconductor die 70B including a second-type memory array that is a different type of memory array than the first-type memory array.

Referring to a sixth processing step S6, the carrier wafer 601 may be detached from the assembly of at least two wafers (100, 200, optionally 300, optionally 400). For example, the adhesive layer located between the carrier wafer 601 and the first wafer 100 may be decomposed by ultraviolet radiation or by a thermal anneal at a debonding temperature. In embodiments in which the carrier wafer 601 includes an optically transparent material and the adhesive layer thereupon includes an LTHC layer, the adhesive layer may be decomposed by irradiating ultraviolet light through the transparent carrier substrate. In embodiments in which the adhesive layer includes a thermally decomposing adhesive material, a thermal anneal process may be performed at a debonding temperature (which is higher than the metal-to-metal bonding temperatures used to form the bonded wafer assembly (100, 200, optionally 300, optionally 400.

On-die bump structures 192 (shown in FIG. 2A) of the processor dies 10 in the first wafer 100 may be physically exposed upon detaching the carrier wafer 601 from the bonded wafer assembly (100, 200, optionally 300, optionally 400). Arrays of solder material portions (not illustrated) may be attached to the arrays of on-die bump structures 192.

Referring to a seventh processing step S7, the bonded wafer assembly (100, 200, optionally 300, optionally 400) comprising at least the first wafer 100 and the second wafer 200 may be diced into a plurality of composite packages 80. Each of the composite packages 80 may comprise an assembly of a respective processor die 10, a respective first memory die 20 containing a respective set of one (or more) of the second semiconductor dies 70, optionally a respective second memory die 30 containing a respective one (or more) of the third semiconductor dies 70, and optionally a respective third memory die 40 containing a respective one (or more) of the fourth semiconductor dies 70.

Physically exposed sidewalls of each die (10, 20, 30, 40) within each composite package 80 may be vertically coincident among one another, i.e., may be located within a same vertical plane. Specifically, each outer sidewall of any selected die (10, 20, 30, 40) within a composite package 80 is vertically coincident with a respective outer sidewall of each die other than the selected die (10, 20, 30, 40). For example, each outer sidewall of a processor die 10 within a composite package 80 is vertically coincident with a sidewall of each memory die (20, 30, 40) within the composite package 80. It is understood that the sidewalls of component semiconductor dies 70 within a reconstituted memory die that contains multiple component semiconductor dies are not exposed to the ambient, and thus, are not outer sidewalls of the reconstituted memory die.

Each composite package 80 comprises a bonded assembly of a processor die 10, a first memory die 20, an optional second memory die 30, an optional third memory die 40, and any additional optional memory die (not illustrated). Referring collectively to FIGS. 1-5C, each of the processor die 10 and the at least one memory die (20, 30, 40) may be provided as a die within a respective wafer including a respective two-dimensional array of dies. At least one wafer bonding process that provides metal-to-metal bonding among a set of wafers including the processor die 10 and the at least one memory die (20, 30, 40) may be performed to form a bonded wafer assembly (100, 200, 300, 400) in which the set of wafers is bonded to one another. In this embodiment, each bonded assembly 80 of the processor die 10 and the at least one memory die (20, 30, 40) is formed within the bonded wafer assembly (100, 200, 300, 400) as a portion of the bonded wafer assembly (100, 200, 300, 400), and become a stand-alone structure upon dicing of the bonded wafer assembly (100, 200, 300, 400) into a plurality of composite packages 80. In other words, upon dicing the bonded wafer assembly (100, 200, 300, 400), each bonded assembly 80 of the processor die 10 and the at least one memory die (20, 30, 40) is a singulated piece of the bonded wafer assembly (100, 200, 300, 400) that remains after the dicing.

During manufacture of the bonded wafer assembly (100, 200, 300, 400), a first wafer bonding process (which uses metal-to-metal bonding and optionally dielectric-to-dielectric bonding) may be performed which bonds a first wafer 100 including an array of processor dies 10 to a carrier wafer 601. Subsequently, a second wafer bonding process (which uses metal-to-metal bonding) may be performed which bonds a second wafer 200 including an array of first memory dies 20 to the first wafer 100. The processor die 10 within each composite die 80 may be a die within the array of processor dies 10, and one of the at least one memory die (20, 30, 40) (such as a first memory die 20) within each composite die 80 may be a die within the array of first memory dies (20, 30, 40). The carrier wafer 601 may be detached from an assembly including the set of wafers (100, 200, 300, 400) and the bonded wafer assembly (100, 200, 300, 400) may be provided.

In one embodiment, the at least one memory die (20, 30, 40) comprises multiple memory dies (20, 30, 40). In this embodiment, a third wafer bonding process may be performed, which bonds a third wafer 300 including an array of second memory dies 30 to the second wafer 200. In this embodiment, another of the multiple memory dies (20, 30, 40) (such as a second memory die 30) may be a die within the array of second memory dies 30.

In one embodiment, a processor die 10 may be bonded with multiple memory dies (20, 30, 40) in embodiments in which the first wafer 100 is bonded with at least two wafers (200, 300, 400) including a respective array of memory dies (20, 30, 40). Each vertically neighboring pair of dies among the processor die 10 and the multiple memory dies (20, 30, 40) may be bonded to each other (while being a portion of a respective wafer (100, 200, 300, 400) by performing a respective metal-to-metal bonding process in which each mating pair of metal bonding pads (18, 19) are in direct contact at grain boundaries (which is a characteristic of metal-to-metal bonding processes). Generally, the processor die 10 comprises processing units for performing logical operations, and each of the multiple memory dies (20, 30, 40) comprises at least one type of memory array selected from a gain cell random access memory array, and magnetoresistive random access memory array, and a resistive random access memory array. A bonded assembly 80 of the processor die 10 and the at least one memory die (20, 30, 40) may be formed as a portion of the bonded wafer assembly (100, 200, 300, 400).

In one embodiment, each of the multiple memory dies (20, 30, 40) comprises a respective set of memory address input nodes as described above. The processor die 10 may comprise a unified memory controller unit 114 including a set of memory address output nodes that are electrically connected to each set of memory address input nodes within the at least one memory die (20, 30, 40).

Upon dicing the bonded wafer assembly (100, 200, 300, 400), a diced portion of the bonded wafer assembly (100, 200, 300, 400) comprises a bonded assembly 80 of a processor die 10 and at least one memory die (20, 30, 40). Generally, the processor die 10 is a die from the array of processor dies 10, and one of the at least one memory die (20, 30, 40) (i.e., a first memory die 20) is a die from the array of first memory dies 20. Each vertically neighboring pair of dies among the processor die 10 and the at least one memory die (20, 30, 40) is bonded to each other through metal-to-metal bonding process, the processor die 10 comprises processing units for performing logical operations, and the at least one memory die (20, 30, 40) comprises at least two types of memory arrays selected from a static random access memory array, a gain cell random access memory array, and magnetoresistive random access memory array, and a resistive random access memory; and

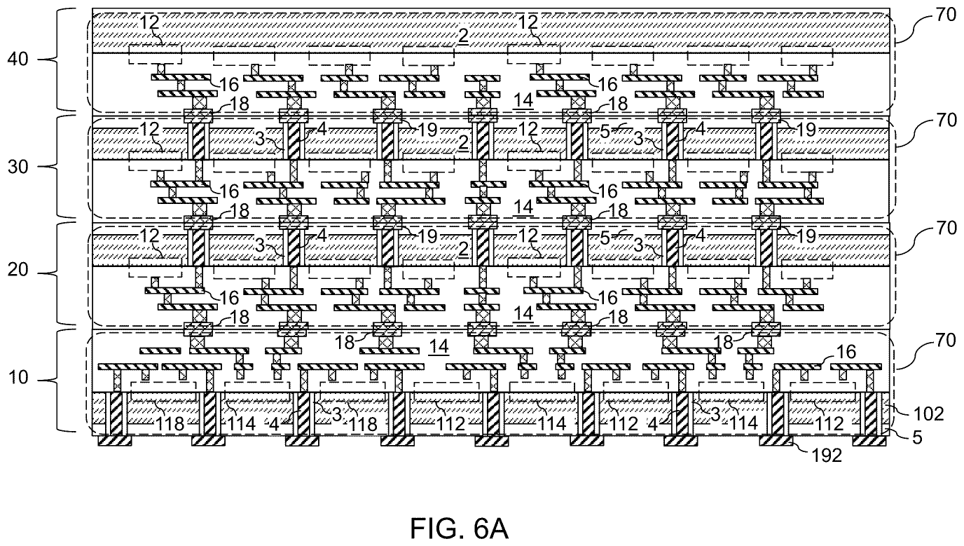

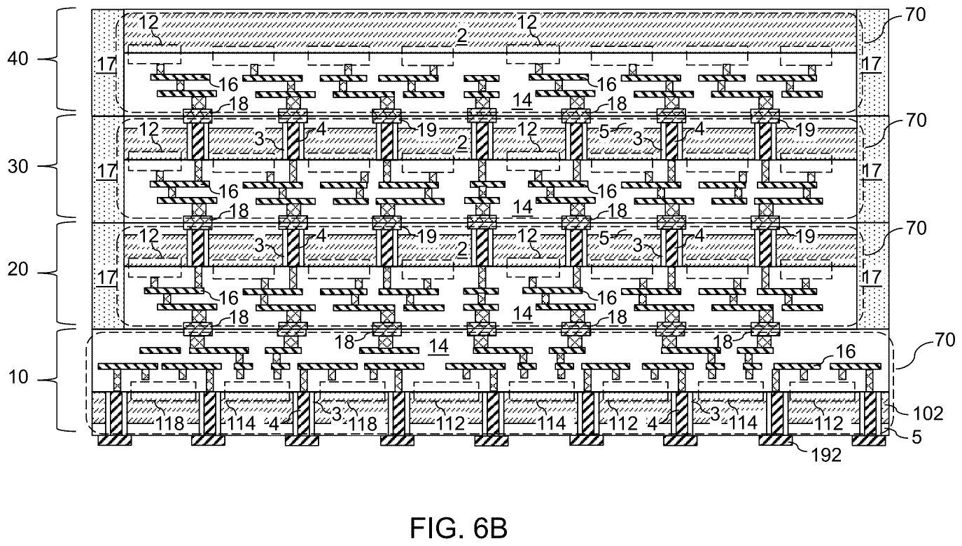

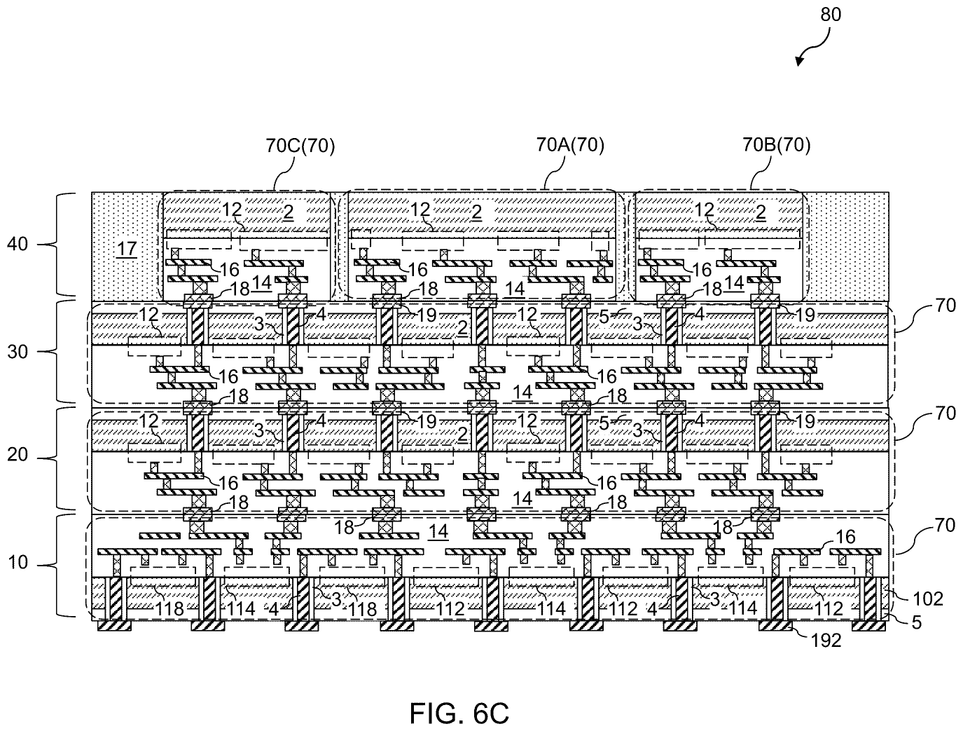

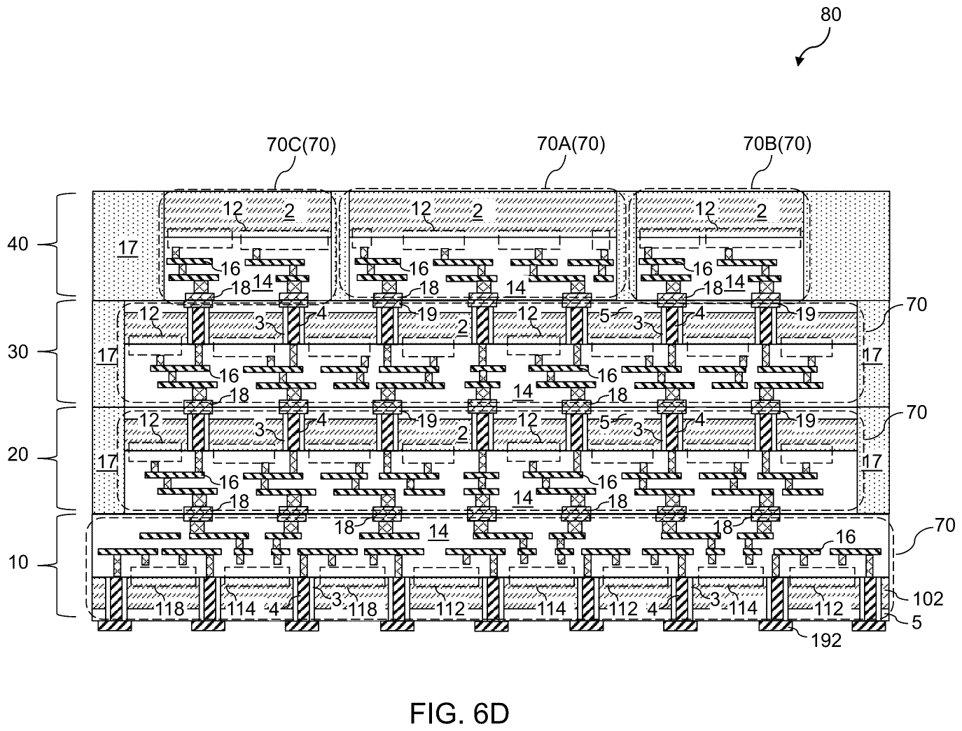

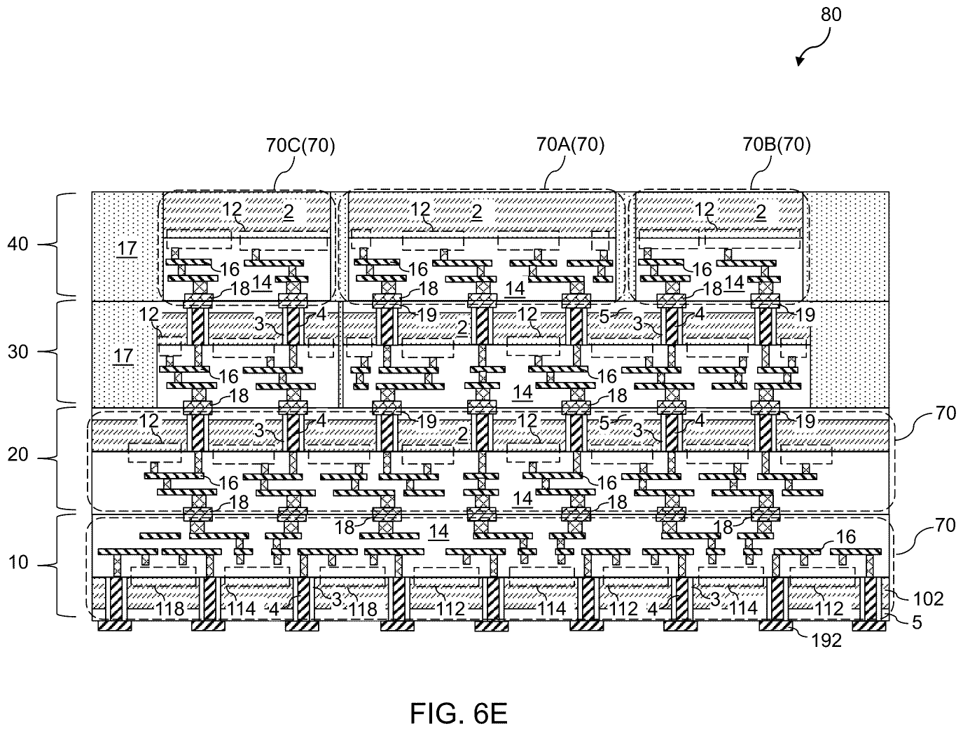

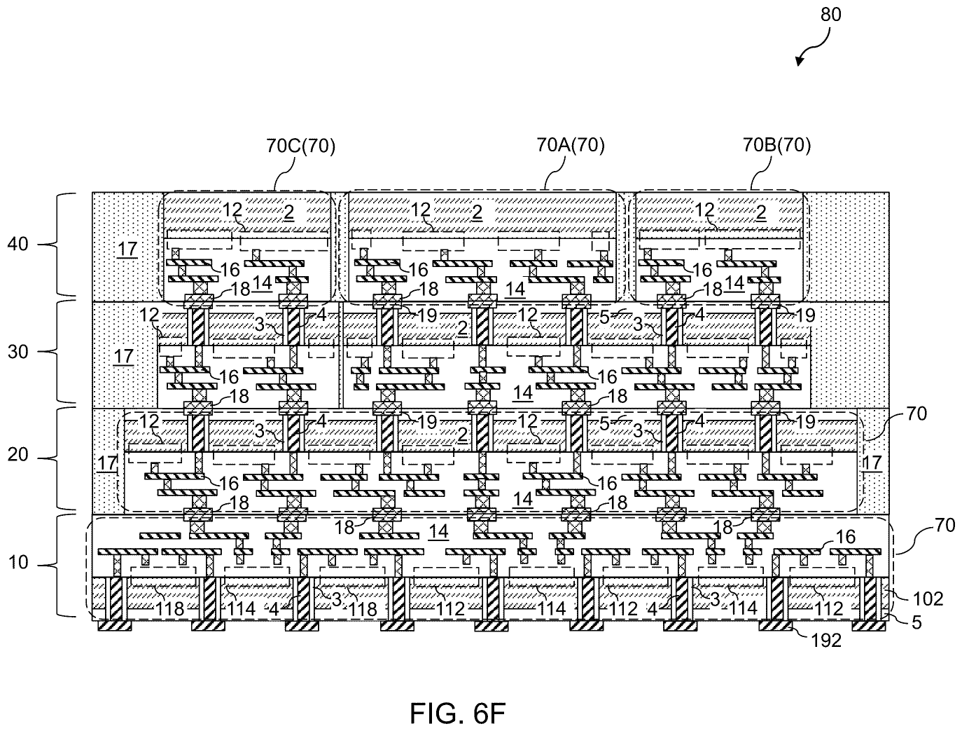

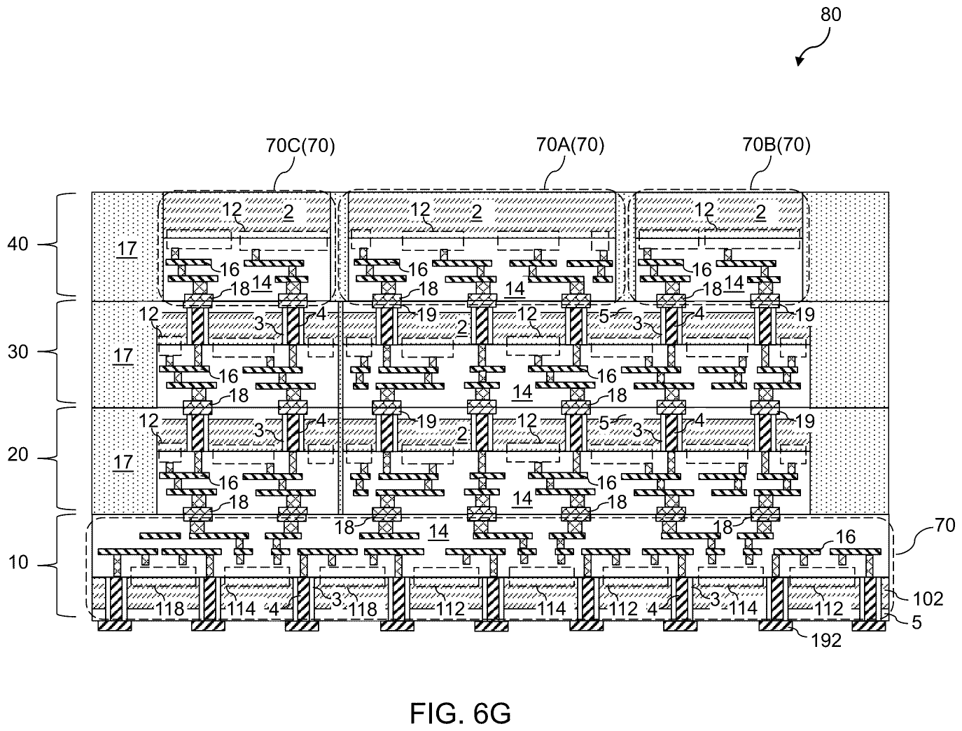

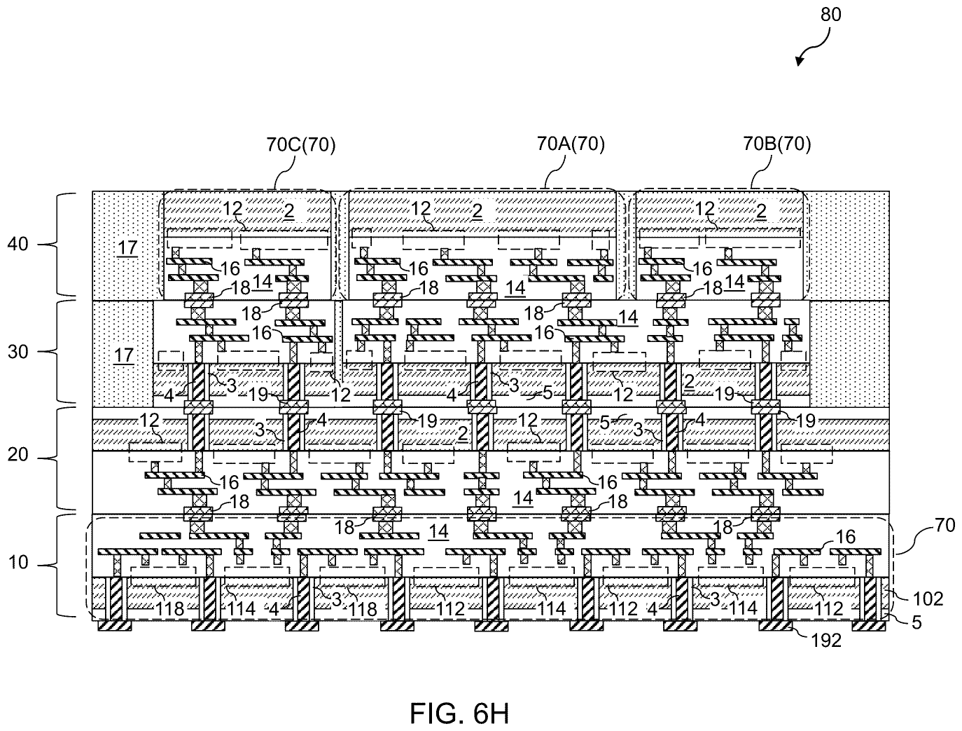

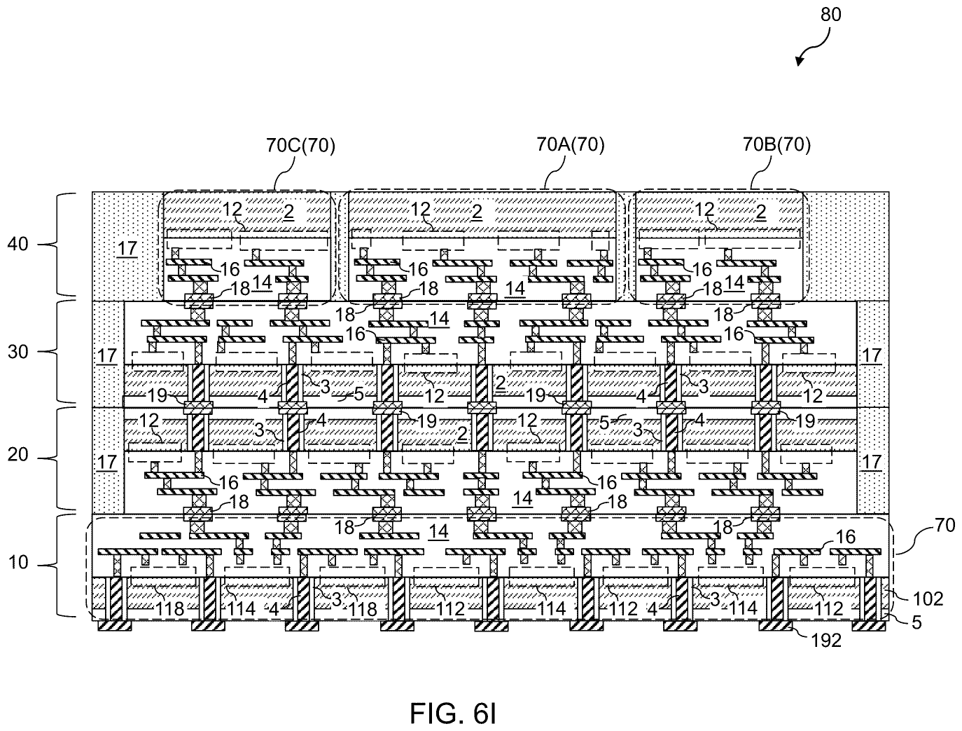

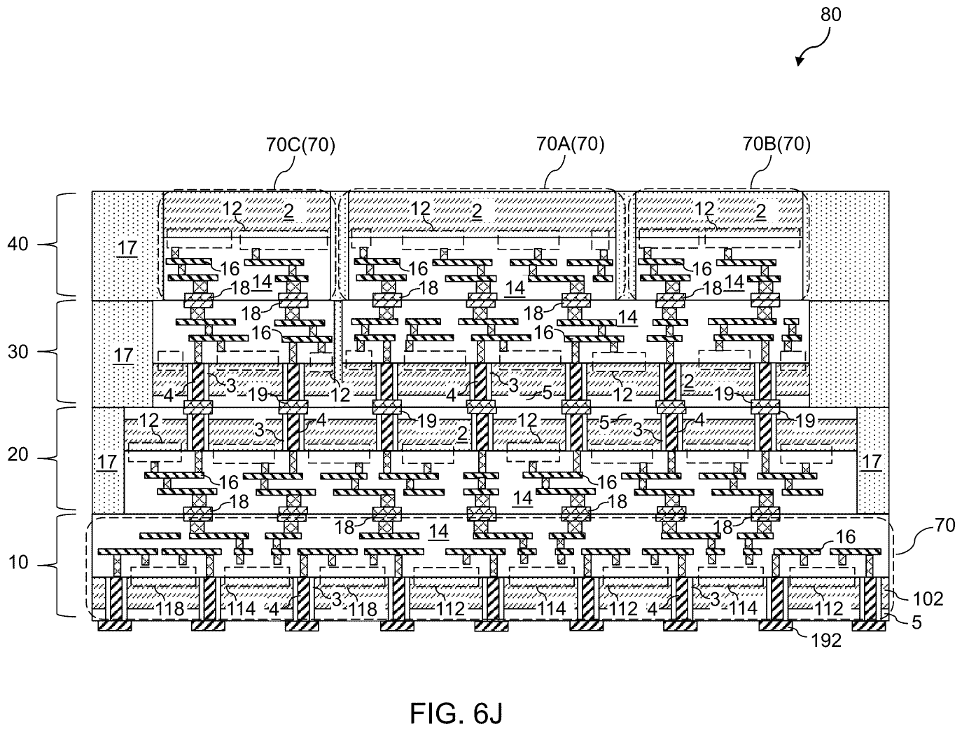

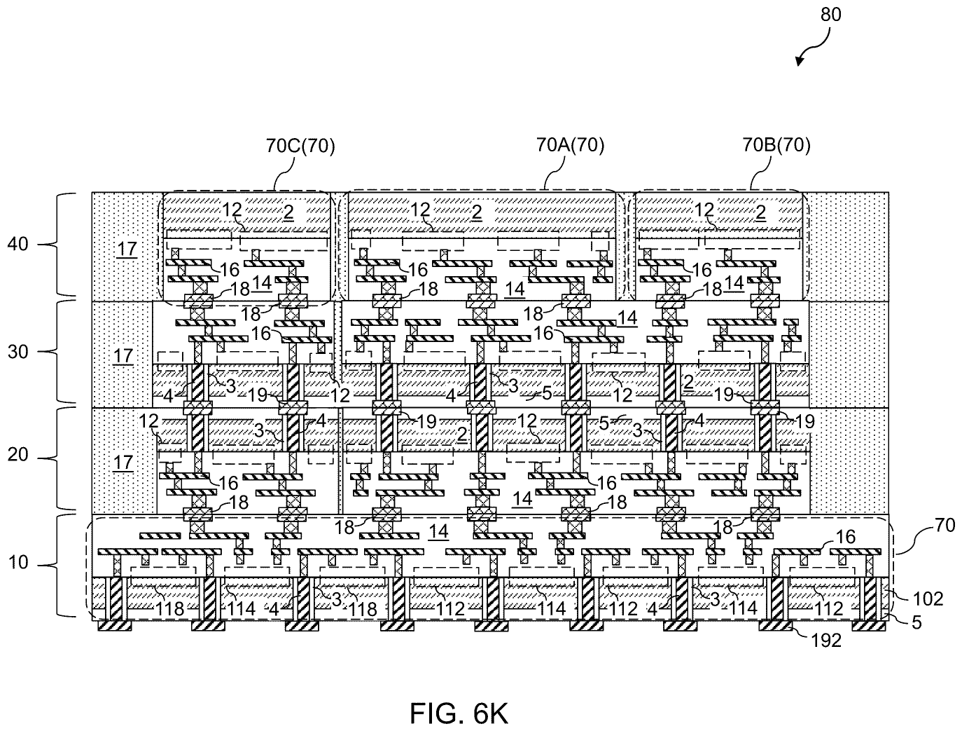

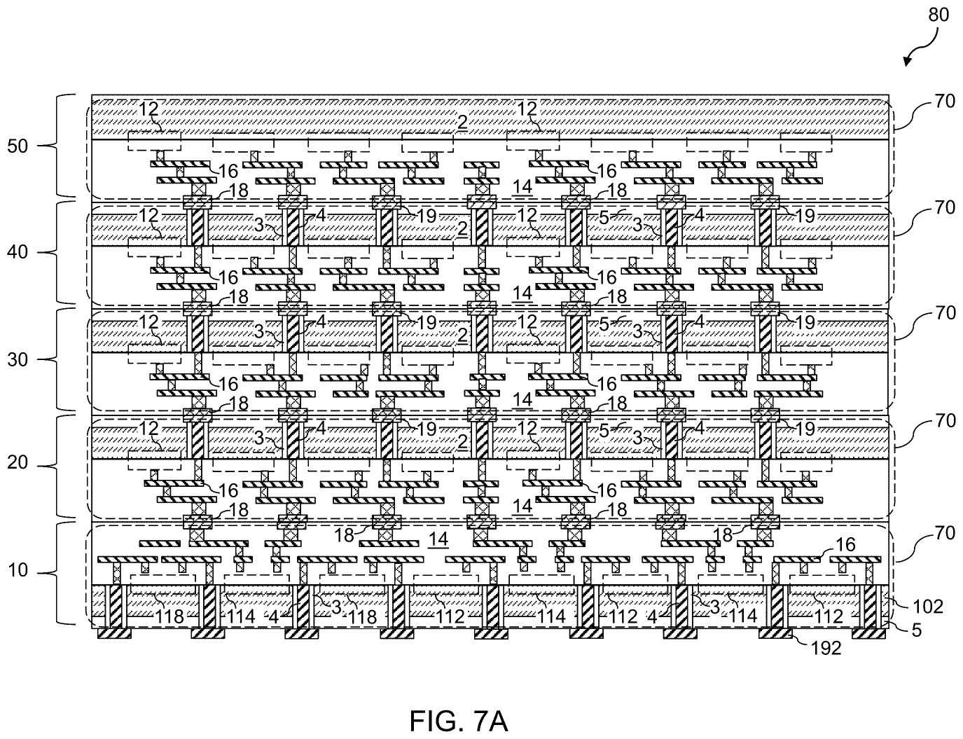

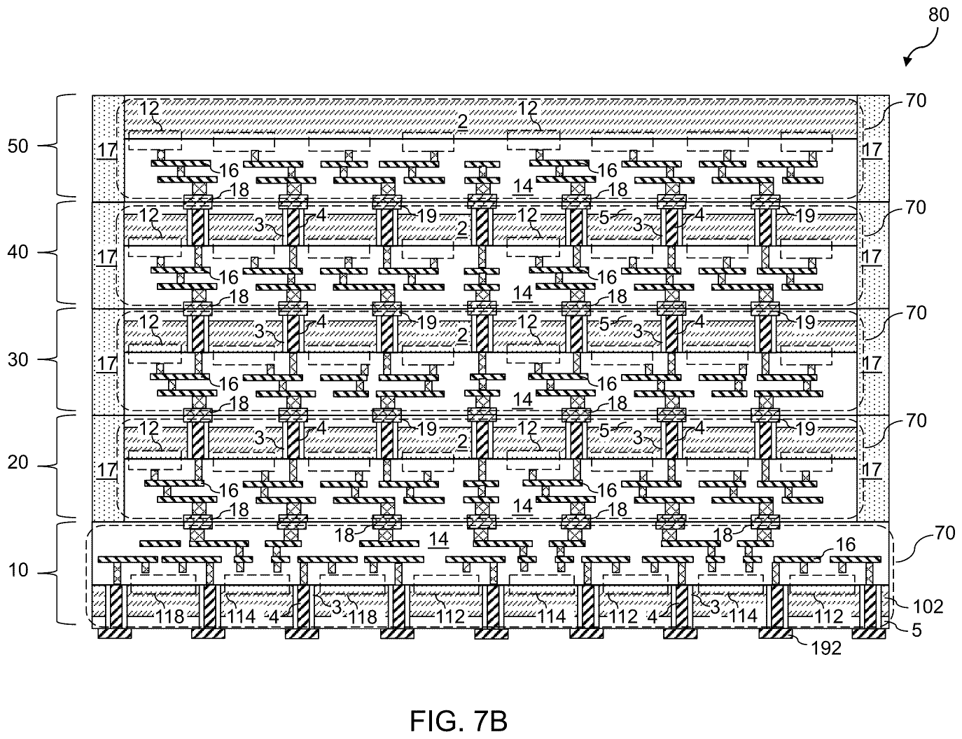

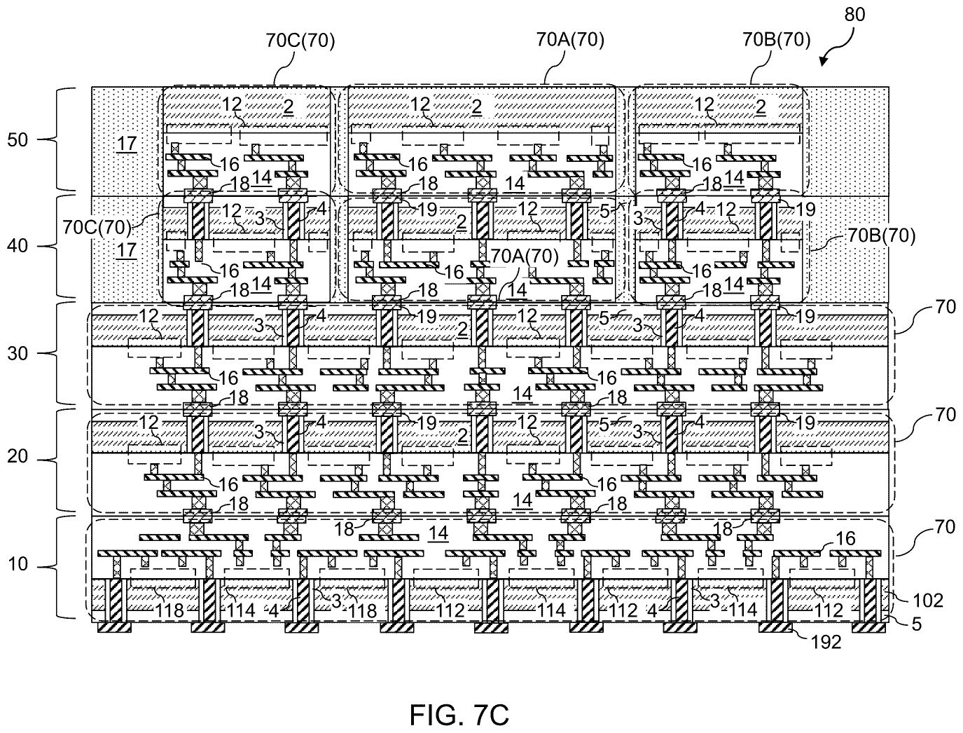

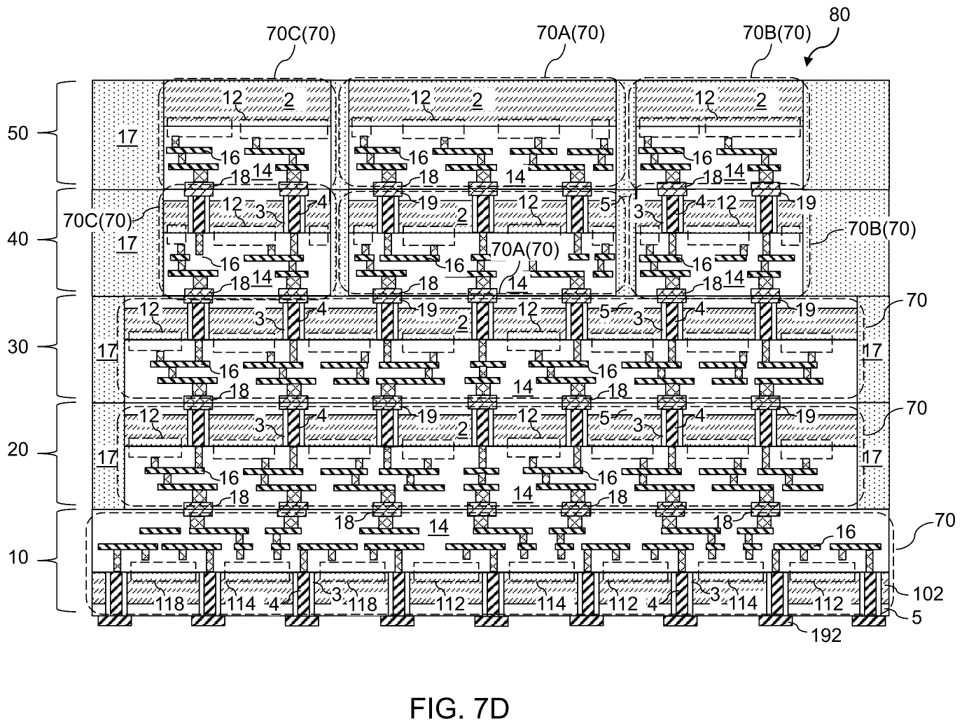

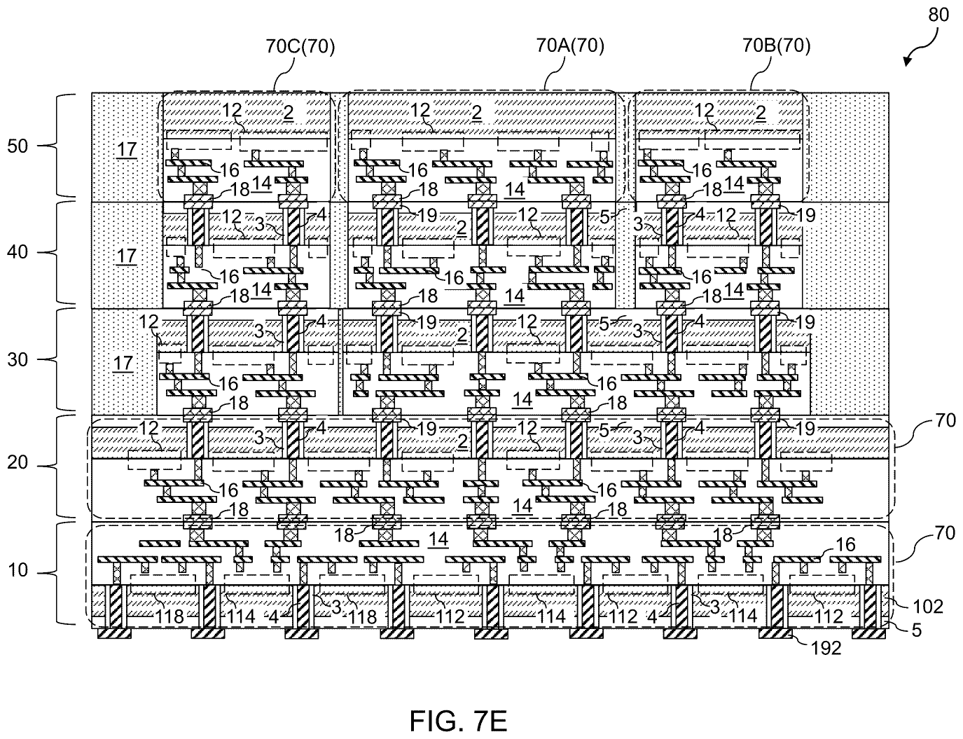

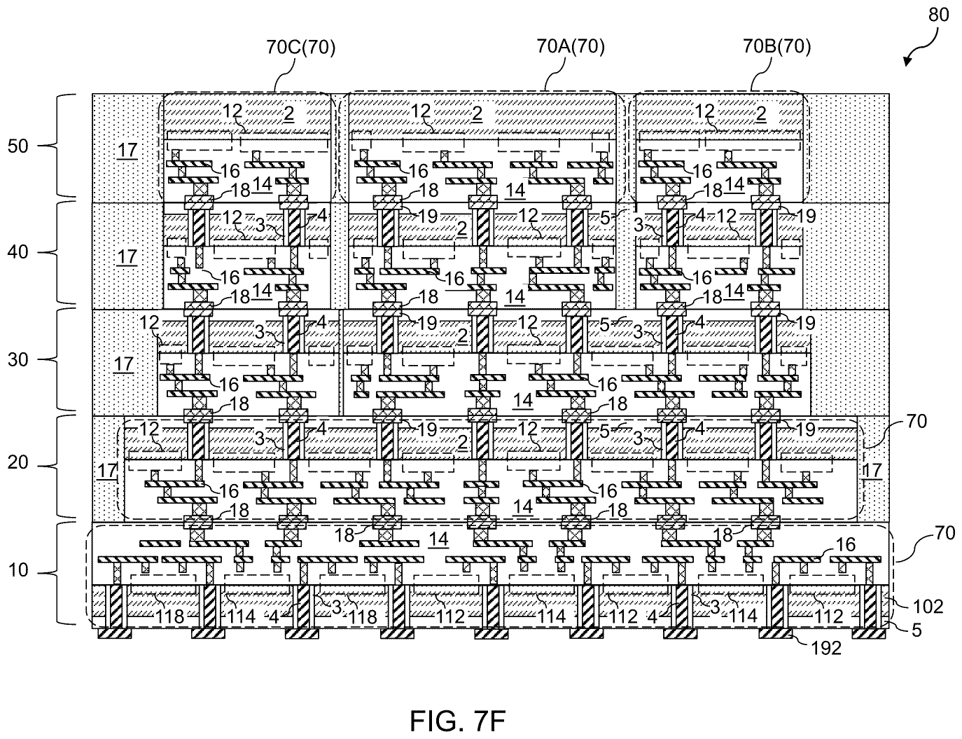

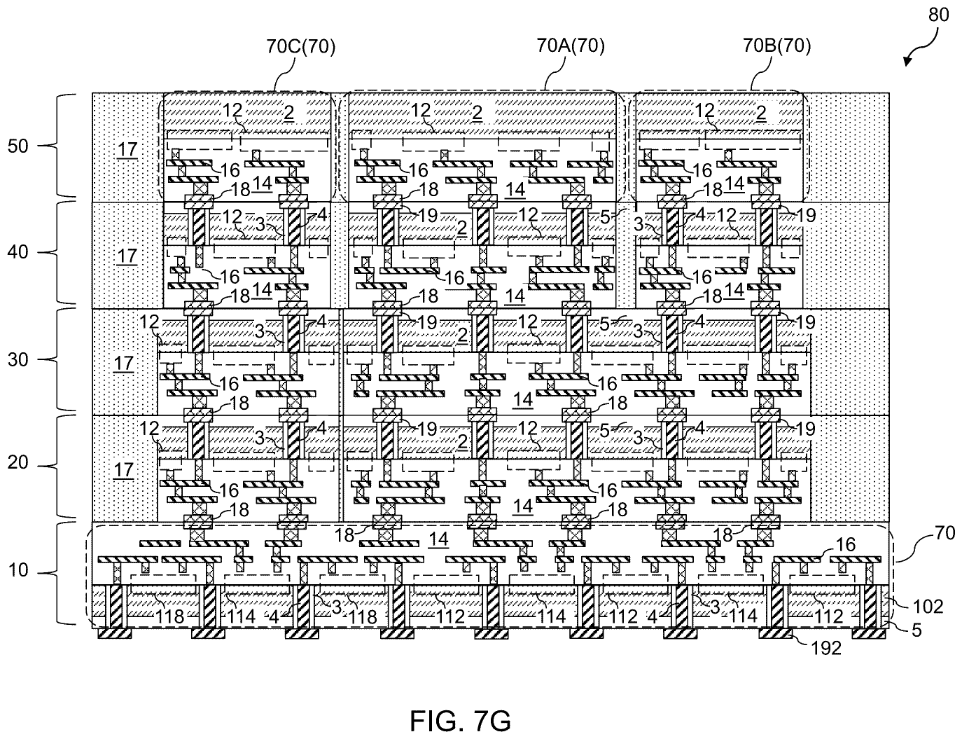

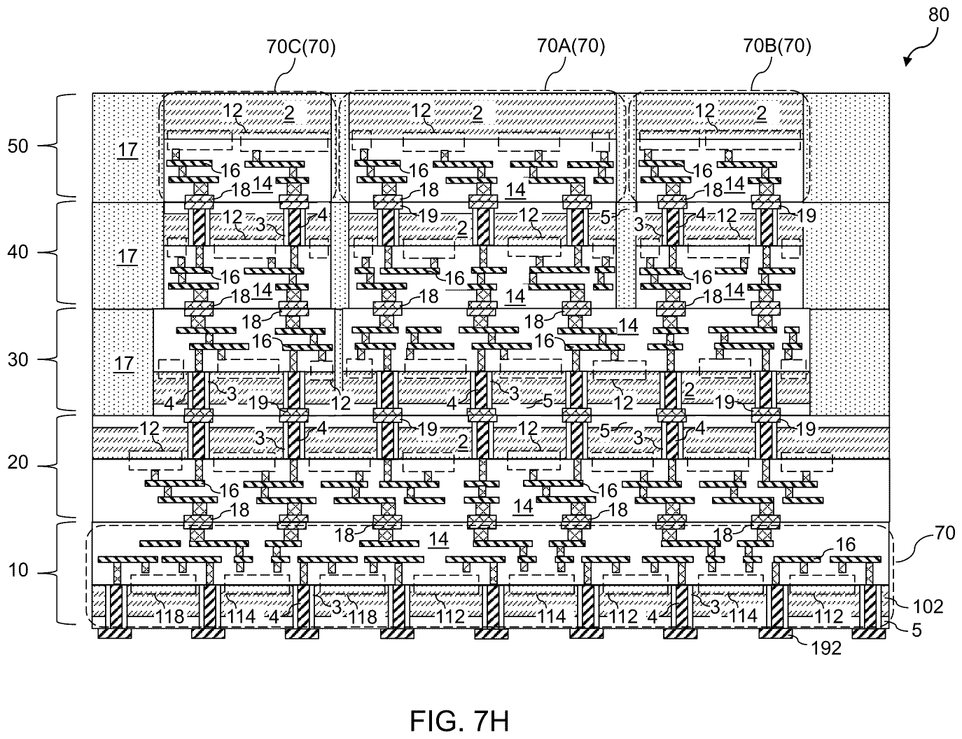

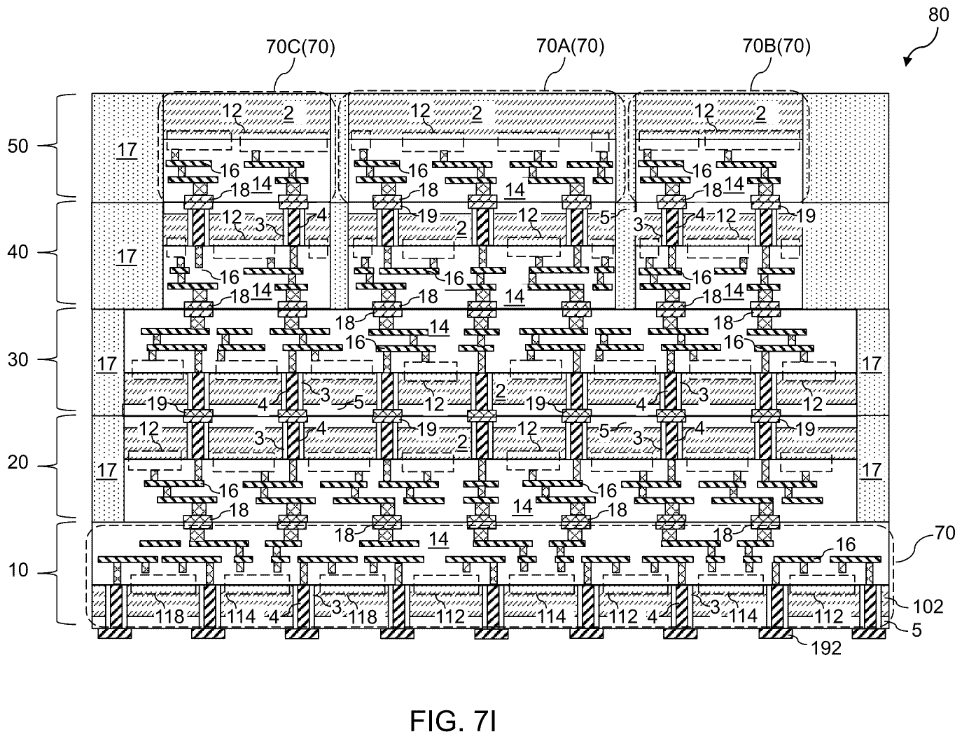

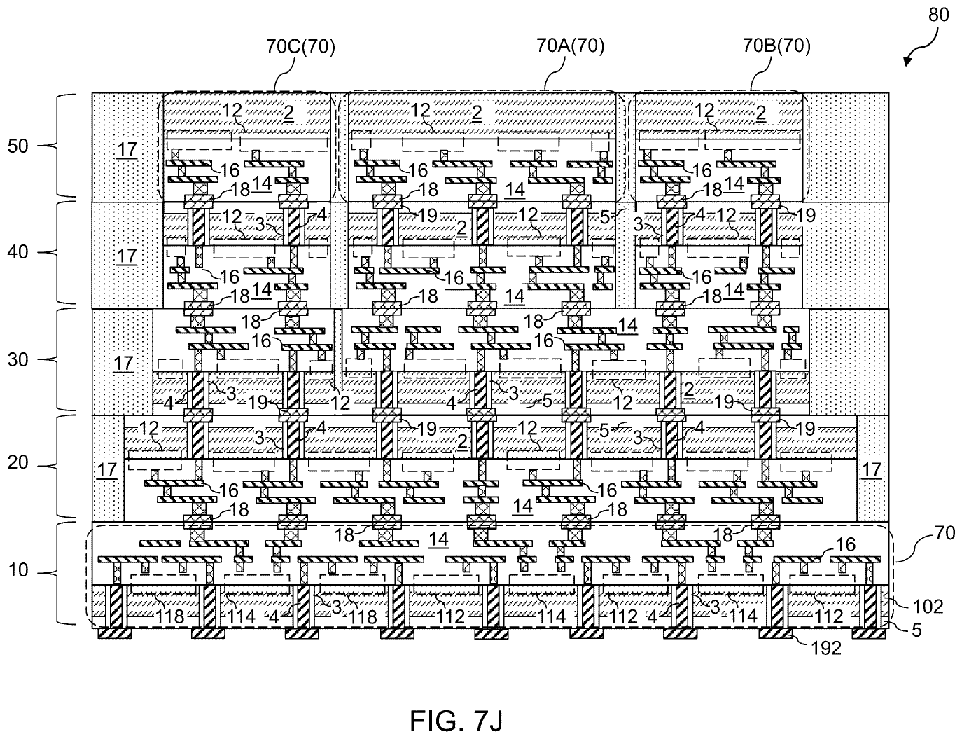

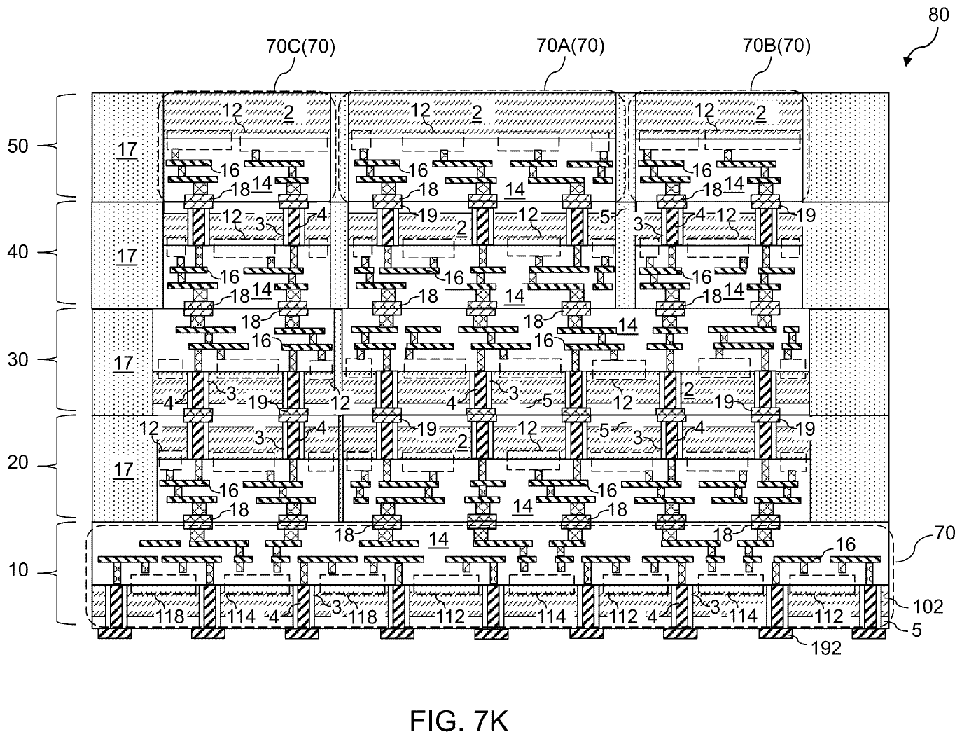

The composite package 80 of the present disclosure may be provided in various configurations depending on the configurations of each memory die (20, 30, 40) and the total number of wafers (100, 200, 300, 400) in the bonded wafer assembly (100, 200, 300, 400) that is diced. FIGS. 6A-6K are vertical cross-sectional view of various configurations of a first composite package 80 according to embodiments of the present disclosure. FIGS. 7A-7K are vertical cross-sectional view of various configurations of a second composite package 80 according to embodiments of the present disclosure.

Each memory die (20, 30, 40) comprises at least one semiconductor die 70. Each memory die (20, 30, 40) may consist of a single semiconductor die 70, or may comprise a molding compound die frame 17 and at least one semiconductor die 70 (which may be a single semiconductor die 70 or a plurality of semiconductor dies 70) that is laterally surrounded by the molding compound die frame 17.

Each first memory die 20 may, or may not comprise, a molding compound die frame 17; each second memory die 30 may, or may not comprise, a molding compound die frame 17; and each third memory die 40 may, or may not comprise, a molding compound die frame 17. Each molding compound die frame 17 comprises a diced portion of a respective molding compound matrix. The sidewalls of the processor die 10, the first memory die 20, the second memory die 30, the third memory die 40, and any other additional memory die (not shown), if present, within a same composite package 80 are vertically coincident. As used herein, a first surface and a second surface are vertically coincident with each other in instances in which the second surface overlies or underlies the first surface and if there exists a vertical plane including the first surface and the second surface.

The configurations illustrated in FIGS. 6A-6K may be obtained by using the processing schemes illustrated in FIG. 1. In this embodiment, each composite die 80 may comprise a bonded assembly of a processor die 10, a first memory die 20, a second memory die 30, and a third memory die 40. It is understood that TSV structures 4 and insulating spacers 3 may be omitted from the third memory die 40 in embodiments in which front metal bonding pads 18 of the fourth memory die 50 are used for metal-to-metal bonding with the second memory die 30.

The configuration illustrated in FIG. 6A corresponds to an embodiment in which each of the first memory die 20, the second memory die 30, and the third memory die 40 is a diced portion of a respective semiconductor-based wafer. The front metal bonding pads 18 of the first memory die 20 are bonded to the front metal bonding pads 18 of the processor die 10. The front metal bonding pads 18 of the second memory die 30 are bonded to the backside metal bonding pads 19 of the first memory die 20. The front metal bonding pads 18 of the third memory die 40 are bonded to the backside metal bonding pads 19 of the second memory die 30.

The configuration illustrated in FIG. 6B corresponds to an embodiment in which each of the first memory die 20, the second memory die 30, and the third memory die 40 is a diced portion of a respective reconstituted wafer 120, which may be provided as described with reference to FIGS. 4A-4C or FIGS. 5A-5C. In the illustrated example, each of the first memory die 20, the second memory die 30, and the third memory die 40 may be a diced portion of a respective reconstituted wafer 120 formed using the processing steps described with reference to FIGS. 4A-4C. The front metal bonding pads 18 of the first memory die 20 are bonded to the front metal bonding pads 18 of the processor die 10. The front metal bonding pads 18 of the second memory die 30 are bonded to the backside metal bonding pads 19 of the first memory die 20. The front metal bonding pads 18 of the third memory die 40 are bonded to the backside metal bonding pads 19 of the second memory die 30.

The configuration illustrated in FIG. 6C corresponds to an embodiment in which each of the first memory die 20 and the second memory die 30 is a diced portion of a respective semiconductor-based wafer described with reference to FIG. 3, and the third memory die 40 is a diced portion of a reconstituted wafer 120, which may be provided as described with reference to FIGS. 4A-4C or FIGS. 5A-5C. The front metal bonding pads 18 of the first memory die 20 are bonded to the front metal bonding pads 18 of the processor die 10. The front metal bonding pads 18 of the second memory die 30 are bonded to the backside metal bonding pads 19 of the first memory die 20. The front metal bonding pads 18 of the third memory die 40 are bonded to the backside metal bonding pads 19 of the second memory die 30.

The configuration illustrated in FIG. 6D corresponds to an embodiment in which each of the first memory die 20, the second memory die 30, and the third memory die 40 is a diced portion of a respective reconstituted wafer 120, which may be provided as described with reference to FIGS. 4A-4C or FIGS. 5A-5C. In the illustrated example, each of the first memory die 20 and the second memory die 30 comprises only one semiconductor die 70, respectively, and the third memory die 40 comprises a plurality of semiconductor dies 70 (which may be memory dies including a respective type of memory arrays that may, or may not, be different from one another). The front metal bonding pads 18 of the first memory die 20 are bonded to the front metal bonding pads 18 of the processor die 10. The front metal bonding pads 18 of the second memory die 30 are bonded to the backside metal bonding pads 19 of the first memory die 20. The front metal bonding pads 18 of the third memory die 40 are bonded to the backside metal bonding pads 19 of the second memory die 30.

The configuration illustrated in FIG. 6E corresponds to an embodiment in which the first memory die 20 is a diced portion of a semiconductor-based wafer, and each of the second memory die 30 and the third memory die 40 comprises a diced portion of a respective reconstituted wafer 120, which may be provided as described with reference to FIGS. 4A-4C or FIGS. 5A-5C. In the illustrated example, each of the second memory die 30 and the third memory die 40 may be a diced portion of a reconstituted wafer 120 that is formed using the processing steps described with reference to FIGS. 5A-5C. In one embodiment, each of the second memory die 30 and the third memory die 40 comprises a respective plurality of semiconductor dies 70 (which may be memory dies including a respective type of memory arrays that may, or may not, be different from one another). The front metal bonding pads 18 of the first memory die 20 are bonded to the front metal bonding pads 18 of the processor die 10. The front metal bonding pads 18 of the second memory die 30 are bonded to the backside metal bonding pads 19 of the first memory die 20. The front metal bonding pads 18 of the third memory die 40 are bonded to the backside metal bonding pads 19 of the second memory die 30.

The configuration illustrated in FIG. 6F corresponds to an embodiment in which each of the first memory die 20, the second memory die 30, and the third memory die 40 is a diced portion of a respective reconstituted wafer 120, which may be provided as described with reference to FIGS. 4A-4C or FIGS. 5A-5C. In the illustrated example, the first memory die 20 may be a diced portion of a reconstituted wafer 120 formed using the processing steps described with reference to FIGS. 4A-4C, and each of the second memory die 30 and the third memory die 40 may be a diced portion of a respective reconstituted wafer 120 formed using the processing steps described with reference to FIGS. 5A-5C. In one embodiment, each of the second memory die 30 and the third memory die 40 comprises a respective plurality of semiconductor dies 70 (which may be memory dies including a respective type of memory arrays that may, or may not, be different from one another). The front metal bonding pads 18 of the first memory die 20 are bonded to the front metal bonding pads 18 of the processor die 10. The front metal bonding pads 18 of the second memory die 30 are bonded to the backside metal bonding pads 19 of the first memory die 20. The front metal bonding pads 18 of the third memory die 40 are bonded to the backside metal bonding pads 19 of the second memory die 30.

The configuration illustrated in FIG. 6G corresponds to an embodiment in which each of the first memory die 20, the second memory die 30, and the third memory die 40 is a diced portion of a respective reconstituted wafer 120, which may be provided as described with reference to FIGS. 4A-4C or FIGS. 5A-5C. In the illustrated example, each of the first memory die 20, the second memory die 30, and the third memory die 40 may be a diced portion of a respective reconstituted wafer 120 formed using the processing steps described with reference to FIGS. 5A-5C. In one embodiment, each of the first memory die 20, the second memory die 30, and the third memory die 40 comprises a respective plurality of semiconductor dies 70 (which may be memory dies including a respective type of memory arrays that may, or may not, be different from one another). The front metal bonding pads 18 of the first memory die 20 are bonded to the front metal bonding pads 18 of the processor die 10. The front metal bonding pads 18 of the second memory die 30 are bonded to the backside metal bonding pads 19 of the first memory die 20. The front metal bonding pads 18 of the third memory die 40 are bonded to the backside metal bonding pads 19 of the second memory die 30.

The configuration illustrated in FIG. 6H corresponds to an embodiment in which the first memory die 20 is a diced portion of a semiconductor-based wafer, and each of the second memory die 30 and the third memory die 40 comprises a diced portion of a respective reconstituted wafer 120, which may be provided as described with reference to FIGS. 4A-4C or FIGS. 5A-5C. In the illustrated example, each of the second memory die 30 and the third memory die 40 may be a diced portion of a respective reconstituted wafer 120 that is formed using the processing steps described with reference to FIGS. 5A-5C. In one embodiment, each of the second memory die 30 and the third memory die 40 comprises a respective plurality of semiconductor dies 70 (which may be memory dies including a respective type of memory arrays that may, or may not, be different from one another). The front metal bonding pads 18 of the first memory die 20 are bonded to the front metal bonding pads 18 of the processor die 10. The backside metal bonding pads 19 of the second memory die 30 are bonded to the backside metal bonding pads 19 of the first memory die 20. The front metal bonding pads 18 of the third memory die 40 are bonded to the front metal bonding pads 18 of the second memory die 30.

The configuration illustrated in FIG. 6I corresponds to an embodiment in which each of the first memory die 20, the second memory die 30, and the third memory die 40 is a diced portion of a respective reconstituted wafer 120, which may be provided as described with reference to FIGS. 4A-4C or FIGS. 5A-5C. In the illustrated example, each of the first memory die 20 and the second memory die 30 comprises only one semiconductor die 70, respectively, and the third memory die 40 comprises a plurality of semiconductor dies 70 (which may be memory dies including a respective type of memory arrays that may, or may not, be different from one another). The front metal bonding pads 18 of the first memory die 20 are bonded to the front metal bonding pads 18 of the processor die 10. The backside metal bonding pads 19 of the second memory die 30 are bonded to the backside metal bonding pads 19 of the first memory die 20. The front metal bonding pads 18 of the third memory die 40 are bonded to the front metal bonding pads 18 of the second memory die 30.

The configuration illustrated in FIG. 6J corresponds to an embodiment in which each of the first memory die 20, the second memory die 30, and the third memory die 40 is a diced portion of a respective reconstituted wafer 120, which may be provided as described with reference to FIGS. 4A-4C or FIGS. 5A-5C. In the illustrated example, the first memory die 20 comprises only one semiconductor die 70, respectively, and each of the second memory die 30 and the third memory die 40 comprises a respective plurality of semiconductor dies 70 (which may be memory dies including a respective type of memory arrays that may, or may not, be different from one another), and is formed by dicing of a respective reconstituted wafer 120 formed using the processing steps described with reference to FIGS. 5A-5C. The front metal bonding pads 18 of the first memory die 20 are bonded to the front metal bonding pads 18 of the processor die 10. The backside metal bonding pads 19 of the second memory die 30 are bonded to the backside metal bonding pads 19 of the first memory die 20. The front metal bonding pads 18 of the third memory die 40 are bonded to the front metal bonding pads 18 of the second memory die 30.

The configuration illustrated in FIG. 6K corresponds to an embodiment in which each of the first memory die 20, the second memory die 30, and the third memory die 40 is a diced portion of a respective reconstituted wafer 120, which may be provided as described with reference to FIGS. 4A-4C or FIGS. 5A-5C. In the illustrated example, each of the first memory die 20, the second memory die 30, and the third memory die 40 may be a diced portion of a respective reconstituted wafer 120 formed using the processing steps described with reference to FIGS. 5A-5C. In one embodiment, each of the first memory die 20, the second memory die 30, and the third memory die 40 comprises a respective plurality of semiconductor dies 70 (which may be memory dies including a respective type of memory arrays that may, or may not, be different from one another). The front metal bonding pads 18 of the first memory die 20 are bonded to the front metal bonding pads 18 of the processor die 10. The backside metal bonding pads 19 of the second memory die 30 are bonded to the backside metal bonding pads 19 of the first memory die 20. The front metal bonding pads 18 of the third memory die 40 are bonded to the front metal bonding pads 18 of the second memory die 30.

The configurations illustrated in FIGS. 7A-7K may be obtained by modifying the processing schemes illustrated in FIG. 1 through additional bonding of a fifth wafer including an array of fourth memory dies 50 prior to dicing a bonded wafer assembly. In this embodiment, each composite die 80 may comprise a bonded assembly of a processor die 10, a first memory die 20, a second memory die 30, a third memory die 40, and a fourth memory die 50. It is understood that TSV structures 4 and insulating spacers 3 may be omitted from the fourth memory die 50 in embodiments in which front metal bonding pads 18 of the fourth memory die 50 are used for metal-to-metal bonding with the third memory die 40.

The configuration illustrated in FIG. 7A corresponds to an embodiment in which each of the first memory die 20, the second memory die 30, the third memory die 40, and the fourth memory die 50 is a diced portion of a respective semiconductor-based wafer. The front metal bonding pads 18 of the first memory die 20 are bonded to the front metal bonding pads 18 of the processor die 10. The front metal bonding pads 18 of the second memory die 30 are bonded to the backside metal bonding pads 19 of the first memory die 20. The front metal bonding pads 18 of the third memory die 40 are bonded to the backside metal bonding pads 19 of the second memory die 30. The front metal bonding pads 18 of the fourth memory die 50 are bonded to the backside metal bonding pads 19 of the third memory die 40.

The configuration illustrated in FIG. 7B corresponds to an embodiment in which each of the first memory die 20, the second memory die 30, the third memory die 40, and the fourth memory die 50 is a diced portion of a respective reconstituted wafer 120, which may be provided as described with reference to FIGS. 4A-4C or FIGS. 5A-5C. In the illustrated example, each of the first memory die 20, the second memory die 30, the third memory die 40, and the fourth memory die 50 may be a diced portion of a respective reconstituted wafer 120 formed using the processing steps described with reference to FIGS. 4A-4C. The front metal bonding pads 18 of the first memory die 20 are bonded to the front metal bonding pads 18 of the processor die 10. The front metal bonding pads 18 of the second memory die 30 are bonded to the backside metal bonding pads 19 of the first memory die 20. The front metal bonding pads 18 of the third memory die 40 are bonded to the backside metal bonding pads 19 of the second memory die 30. The front metal bonding pads 18 of the fourth memory die 50 are bonded to the backside metal bonding pads 19 of the third memory die 40.

The configuration illustrated in FIG. 7C corresponds to an embodiment in which each of the first memory die 20 and the second memory die 30 is a diced portion of a respective semiconductor-based wafer described with reference to FIG. 3, and each of the third memory die 40 and the fourth memory die 50 is a diced portion of a reconstituted wafer 120, which may be provided as described with reference to FIGS. 4A-4C or FIGS. 5A-5C. The front metal bonding pads 18 of the first memory die 20 are bonded to the front metal bonding pads 18 of the processor die 10. The front metal bonding pads 18 of the second memory die 30 are bonded to the backside metal bonding pads 19 of the first memory die 20. The front metal bonding pads 18 of the third memory die 40 are bonded to the backside metal bonding pads 19 of the second memory die 30. The front metal bonding pads 18 of the fourth memory die 50 are bonded to the backside metal bonding pads 19 of the third memory die 40.

The configuration illustrated in FIG. 7D corresponds to an embodiment in which each of the first memory die 20, the second memory die 30, the third memory die 40, and the fourth memory die 50 is a diced portion of a respective reconstituted wafer 120, which may be provided as described with reference to FIGS. 4A-4C or FIGS. 5A-5C. In the illustrated example, each of the first memory die 20 and the second memory die 30 comprises only one semiconductor die 70, respectively. In one embodiment, each of the third memory die 40 and the fourth memory die 50 comprises a respective plurality of semiconductor dies 70 (which may be memory dies including a respective type of memory arrays that may, or may not, be different from one another). The front metal bonding pads 18 of the first memory die 20 are bonded to the front metal bonding pads 18 of the processor die 10. The front metal bonding pads 18 of the second memory die 30 are bonded to the backside metal bonding pads 19 of the first memory die 20. The front metal bonding pads 18 of the third memory die 40 are bonded to the backside metal bonding pads 19 of the second memory die 30. The front metal bonding pads 18 of the fourth memory die 50 are bonded to the backside metal bonding pads 19 of the third memory die 40.

The configuration illustrated in FIG. 7E corresponds to an embodiment in which the first memory die 20 is a diced portion of a semiconductor-based wafer, and each of the second memory die 30, the third memory die 40, and the fourth memory die 50 comprises a diced portion of a respective reconstituted wafer 120, which may be provided as described with reference to FIGS. 4A-4C or FIGS. 5A-5C. In the illustrated example, each of the second memory die 30, the third memory die 40, and the fourth memory die 50 may be a diced portion of a respective reconstituted wafer 120 that is formed using the processing steps described with reference to FIGS. 5A-5C. In one embodiment, each of the second memory die 30, the third memory die 40, and the fourth memory die 50 comprises a respective plurality of semiconductor dies 70 (which may be memory dies including a respective type of memory arrays that may, or may not, be different from one another). The front metal bonding pads 18 of the first memory die 20 are bonded to the front metal bonding pads 18 of the processor die 10. The front metal bonding pads 18 of the second memory die 30 are bonded to the backside metal bonding pads 19 of the first memory die 20. The front metal bonding pads 18 of the third memory die 40 are bonded to the backside metal bonding pads 19 of the second memory die 30. The front metal bonding pads 18 of the fourth memory die 50 are bonded to the backside metal bonding pads 19 of the third memory die 40.

The configuration illustrated in FIG. 7F corresponds to an embodiment in which each of the first memory die 20, the second memory die 30, the third memory die 40, and the fourth memory die 50 is a diced portion of a respective reconstituted wafer 120, which may be provided as described with reference to FIGS. 4A-4C or FIGS. 5A-5C. In the illustrated example, the first memory die 20 may be a diced portion of a reconstituted wafer 120 formed using the processing steps described with reference to FIGS. 4A-4C, and each of the second memory die 30, the third memory die 40, and the fourth memory die 50 may be a diced portion of a respective reconstituted wafer 120 formed using the processing steps described with reference to FIGS. 5A-5C. In one embodiment, each of the second memory die 30, the third memory die 40, and the fourth memory die 50 comprises a respective plurality of semiconductor dies 70 (which may be memory dies including a respective type of memory arrays that may, or may not, be different from one another). The front metal bonding pads 18 of the first memory die 20 are bonded to the front metal bonding pads 18 of the processor die 10. The front metal bonding pads 18 of the second memory die 30 are bonded to the backside metal bonding pads 19 of the first memory die 20. The front metal bonding pads 18 of the third memory die 40 are bonded to the backside metal bonding pads 19 of the second memory die 30. The front metal bonding pads 18 of the fourth memory die 50 are bonded to the backside metal bonding pads 19 of the third memory die 40.

The configuration illustrated in FIG. 7G corresponds to an embodiment in which each of the first memory die 20, the second memory die 30, the third memory die 40, and the fourth memory die 50 is a diced portion of a respective reconstituted wafer 120, which may be provided as described with reference to FIGS. 4A-4C or FIGS. 5A-5C. In the illustrated example, each of the first memory die 20, the second memory die 30, the third memory die 40, the fourth memory die 50 may be a diced portion of a respective reconstituted wafer 120 formed using the processing steps described with reference to FIGS. 5A-5C. In one embodiment, each of the first memory die 20, the second memory die 30, the third memory die 40, and the fourth memory die 50 comprises a respective plurality of semiconductor dies 70 (which may be memory dies including a respective type of memory arrays that may, or may not, be different from one another). The front metal bonding pads 18 of the first memory die 20 are bonded to the front metal bonding pads 18 of the processor die 10. The front metal bonding pads 18 of the first memory die 20 are bonded to the front metal bonding pads 18 of the processor die 10. The front metal bonding pads 18 of the second memory die 30 are bonded to the backside metal bonding pads 19 of the first memory die 20. The front metal bonding pads 18 of the third memory die 40 are bonded to the backside metal bonding pads 19 of the second memory die 30. The front metal bonding pads 18 of the fourth memory die 50 are bonded to the backside metal bonding pads 19 of the third memory die 40.

The configuration illustrated in FIG. 7H corresponds to an embodiment in which the first memory die 20 is a diced portion of a semiconductor-based wafer, and each of the second memory die 30, the third memory die 40, and the fourth memory die 50 comprises a diced portion of a respective reconstituted wafer 120, which may be provided as described with reference to FIGS. 4A-4C or FIGS. 5A-5C. In the illustrated example, each of the second memory die 30, the third memory die 40, and the fourth memory die 50 may be a diced portion of a respective reconstituted wafer 120 that is formed using the processing steps described with reference to FIGS. 5A-5C. In one embodiment, each of the second memory die 30, the third memory die 40, and the fourth memory die 50 comprises a respective plurality of semiconductor dies 70 (which may be memory dies including a respective type of memory arrays that may, or may not, be different from one another). The front metal bonding pads 18 of the first memory die 20 are bonded to the front metal bonding pads 18 of the processor die 10. The backside metal bonding pads 19 of the second memory die 30 are bonded to the backside metal bonding pads 19 of the first memory die 20. The front metal bonding pads 18 of the third memory die 40 are bonded to the front metal bonding pads 18 of the second memory die 30. The front metal bonding pads 18 of the fourth memory die 50 are bonded to the backside metal bonding pads 19 of the third memory die 40.

The configuration illustrated in FIG. 7I corresponds to an embodiment in which each of the first memory die 20, the second memory die 30, the third memory die 40, and the fourth memory die 50 is a diced portion of a respective reconstituted wafer 120, which may be provided as described with reference to FIGS. 4A-4C or FIGS. 5A-5C. In the illustrated example, each of the first memory die 20 and the second memory die 30 comprises only one semiconductor die 70, respectively, and each of the third memory die 40 and the fourth memory die 50 comprises a respective plurality of semiconductor dies 70 (which may be memory dies including a respective type of memory arrays that may, or may not, be different from one another). The front metal bonding pads 18 of the first memory die 20 are bonded to the front metal bonding pads 18 of the processor die 10. The backside metal bonding pads 19 of the second memory die 30 are bonded to the backside metal bonding pads 19 of the first memory die 20. The front metal bonding pads 18 of the third memory die 40 are bonded to the front metal bonding pads 18 of the second memory die 30. The front metal bonding pads 18 of the fourth memory die 50 are bonded to the backside metal bonding pads 19 of the third memory die 40.

The configuration illustrated in FIG. 7J corresponds to an embodiment in which each of the first memory die 20, the second memory die 30, the third memory die 40, and the fourth memory die 50 is a diced portion of a respective reconstituted wafer 120, which may be provided as described with reference to FIGS. 4A-4C or FIGS. 5A-5C. In the illustrated example, the first memory die 20 comprises only one semiconductor die 70, respectively, and each of the second memory die 30, the third memory die 40, and the fourth memory die 50 comprises a respective plurality of semiconductor dies 70 (which may be memory dies including a respective type of memory arrays that may, or may not, be different from one another), and is formed by dicing of a respective reconstituted wafer 120 formed using the processing steps described with reference to FIGS. 5A-5C. The front metal bonding pads 18 of the first memory die 20 are bonded to the front metal bonding pads 18 of the processor die 10. The backside metal bonding pads 19 of the second memory die 30 are bonded to the backside metal bonding pads 19 of the first memory die 20. The front metal bonding pads 18 of the third memory die 40 are bonded to the front metal bonding pads 18 of the second memory die 30. The front metal bonding pads 18 of the fourth memory die 50 are bonded to the backside metal bonding pads 19 of the third memory die 40.

The configuration illustrated in FIG. 7K corresponds to an embodiment in which each of the first memory die 20, the second memory die 30, the third memory die 40, and the fourth memory die 50 is a diced portion of a respective reconstituted wafer 120, which may be provided as described with reference to FIGS. 4A-4C or FIGS. 5A-5C. In the illustrated example, each of the first memory die 20, the second memory die 30, the third memory die 40, and the fourth memory die 50 may be a diced portion of a respective reconstituted wafer 120 formed using the processing steps described with reference to FIGS. 5A-5C. In one embodiment, each of the first memory die 20, the second memory die 30, the third memory die 40, and the fourth memory die 50 comprises a respective plurality of semiconductor dies 70 (which may be memory dies including a respective type of memory arrays that may, or may not, be different from one another). The front metal bonding pads 18 of the first memory die 20 are bonded to the front metal bonding pads 18 of the processor die 10. The backside metal bonding pads 19 of the second memory die 30 are bonded to the backside metal bonding pads 19 of the first memory die 20. The front metal bonding pads 18 of the third memory die 40 are bonded to the front metal bonding pads 18 of the second memory die 30. The front metal bonding pads 18 of the fourth memory die 50 are bonded to the backside metal bonding pads 19 of the third memory die 40.

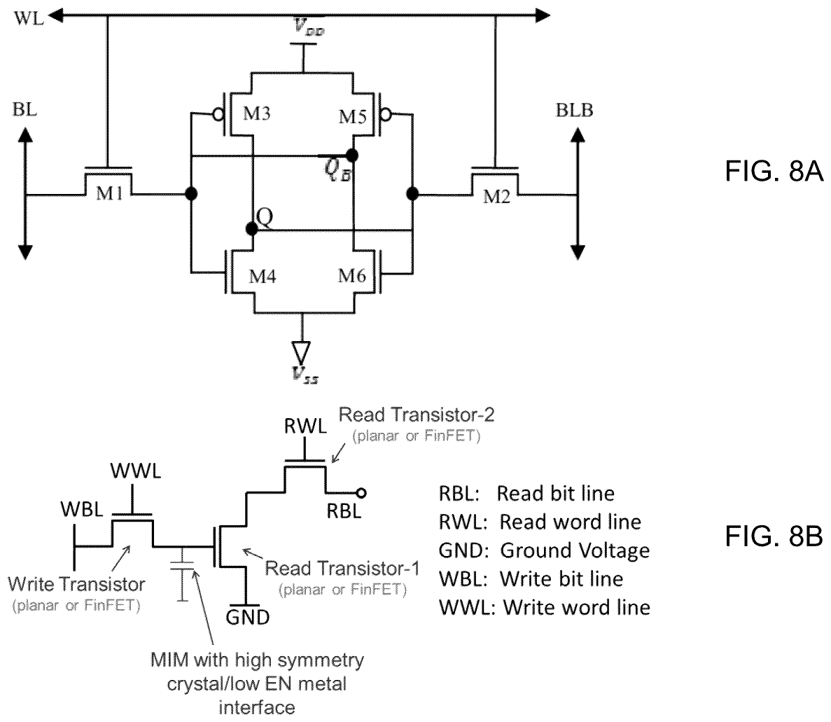

FIGS. 8A-8C are circuit schematics of various memory elements that may be used in the memory dies (20, 30, 40, 50) of the present disclosure. The performance of different memory types used in various cache levels may influence both the speed and cost of a computing system. Static random access memory (SRAM) offers the highest speed with the lowest latency, enabling rapid data access that enhances processor performance. However, SRAM's complexity and high transistor count make SRAM more expensive and consume more power, limiting SRAM's use to smaller cache sizes. Gain cell random access memory (GCRAM) presents a balance between speed and density, offering moderate latency at a lower cost compared to SRAM. GCRAM allows for a larger cache size without the substantial cost increase seen with SRAM. Magnetoresistive random access memory (MRAM) and resistive random access memory (RRAM) provide non-volatile storage, ensuring data persistence and reducing power consumption. While MRAM and RRAM exhibit higher latency than SRAM and GCRAM, their durability and ability to retain data without power make them cost-effective for larger, slower cache tiers. These trade-offs between speed, cost, and non-volatility in cache memory design can significantly impact the overall system performance and efficiency.

FIG. 8A illustrates an exemplary circuit schematic for a static random access memory (SRAM) cell using six CMOS field effect transistors. The SRAM cells may use additional CMOS field effect transistors to enhance speed and stability. SRAM cells using eight CMOS field effect transistors or more may also be used.

FIG. 8B illustrates an exemplary circuit schematic for a gain cell random access memory (GCRAM) cell using a combination of a write transistor and two read transistors. In an embodiment, a GCRAM cell may be implemented as a three-transistor one-transistor (3T1C) device as illustrated in FIG. 8B, or may be implemented as a three-transistor (3T) device. Alternatively, in other embodiments, a GCRAM cell may be implemented as a two-transistor (2T) device, or a two-transistor one capacitor (2T1C) device.

FIG. 8C illustrates an exemplary circuit schematic for a magnetoresistive random access memory (MRAM) cell. The MRAM cell may comprise a parallel connection of a magnetic tunnel junction structure 140 and an access transistor 130. The magnetic tunnel junction structure 140 may comprise a magnetic tunnel junction (144, 145, 146), a first electrode 142, and a second electrode 148. The magnetic tunnel junction (144, 145, 146) may comprise a reference magnetization layer 144, an insulating barrier layer 145, and a free magnetization layer 146, and may provide tunneling magnetoresistance (TMR) effect in which the resistance of the magnetic tunnel junction (144, 145, 146) depends the relative orientation of the magnetizations of the reference magnetization layer 144 and the free magnetization layer 146. Source lines SL, word lines WL, and bit lines BL may be provided to enable access of each MRAM cell in an array environment.

A resistive random access memory (RRAM) cell uses a material that may provide at least two different resistive states depending on the programming conditions. As such, RRAM cells are non-volatile memory cells that do not require periodic refreshing of data. The memory material of a RRAM cell may include a filament-forming dielectric oxide material such as titanium oxide or hafnium oxide, or may include materials that provide electrochemical reactions or field-induced effects. Alternatively, a phase change material such as a germanium-antimony-tellurium alloy may be used as a memory material that may provide at least two different resistive states. In this embodiment, the RRAM may be referred to as a phase change memory random access memory (PCMRAM). In the present disclosure, a PCMRAM memory is considered to be a type of an RRAM memory.

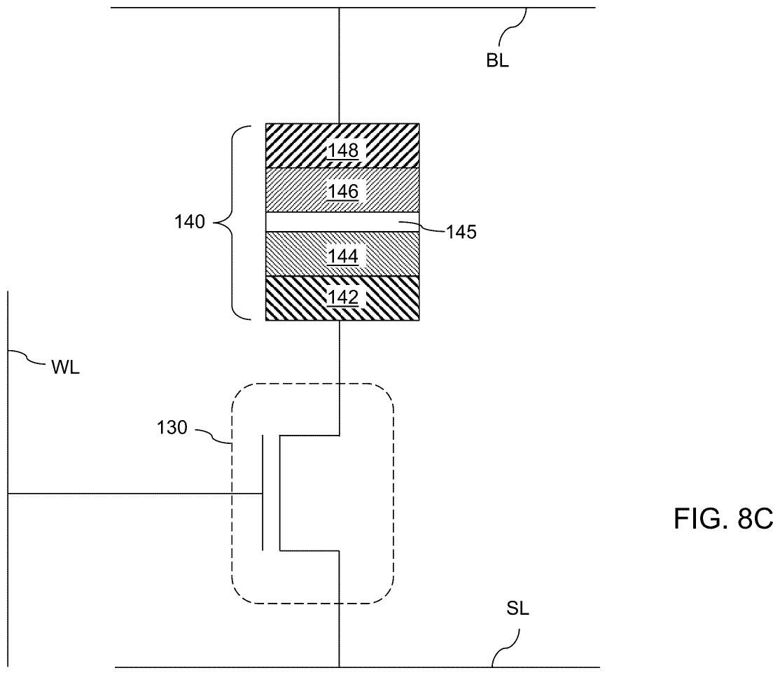

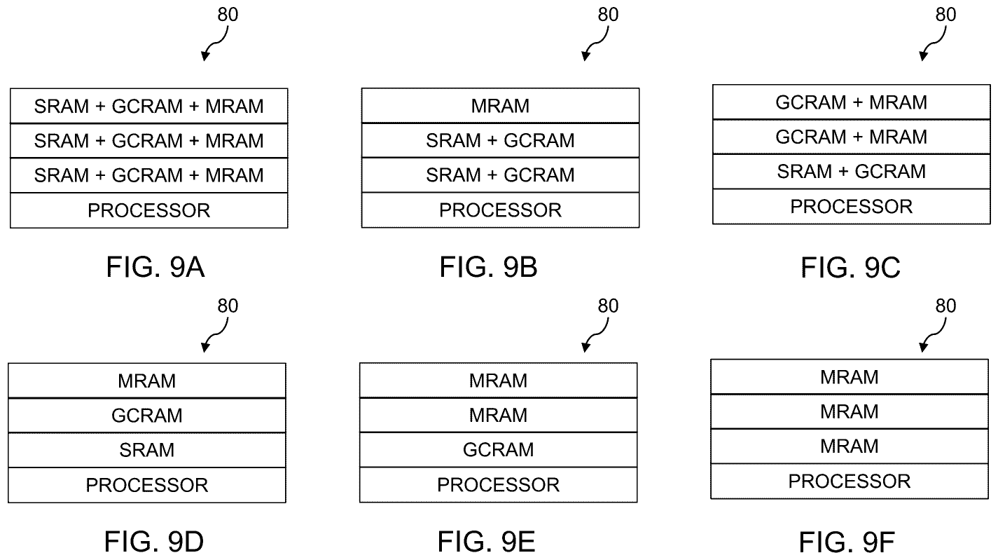

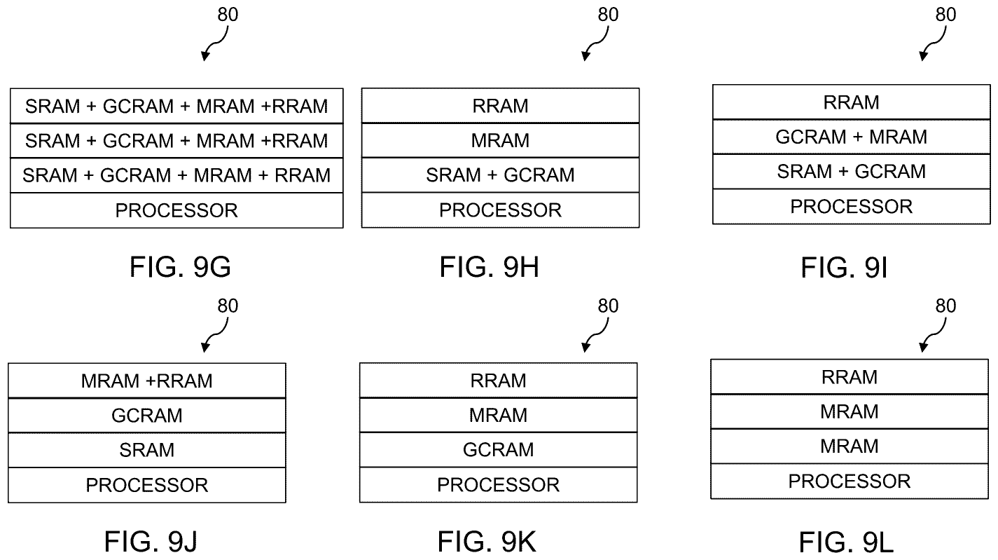

FIGS. 9A-9L are schematic vertical cross-sectional views of various configurations of the first composite package 80 of the present disclosure. Each first composite package 80 may be formed by dicing a bonded wafer assembly including a first wafer 100, a second wafer 200, a third wafer 300, and a fourth wafer 400. Each first composite package 80 may include a bonded assembly of a processor die 10, a first memory die 20, a second memory die 30, and a third memory die 40.

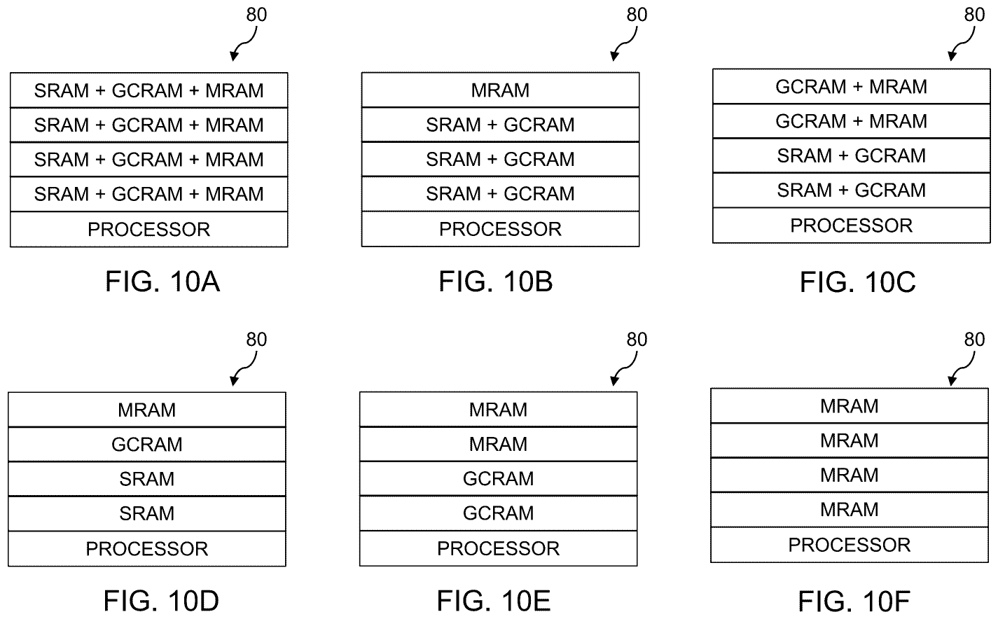

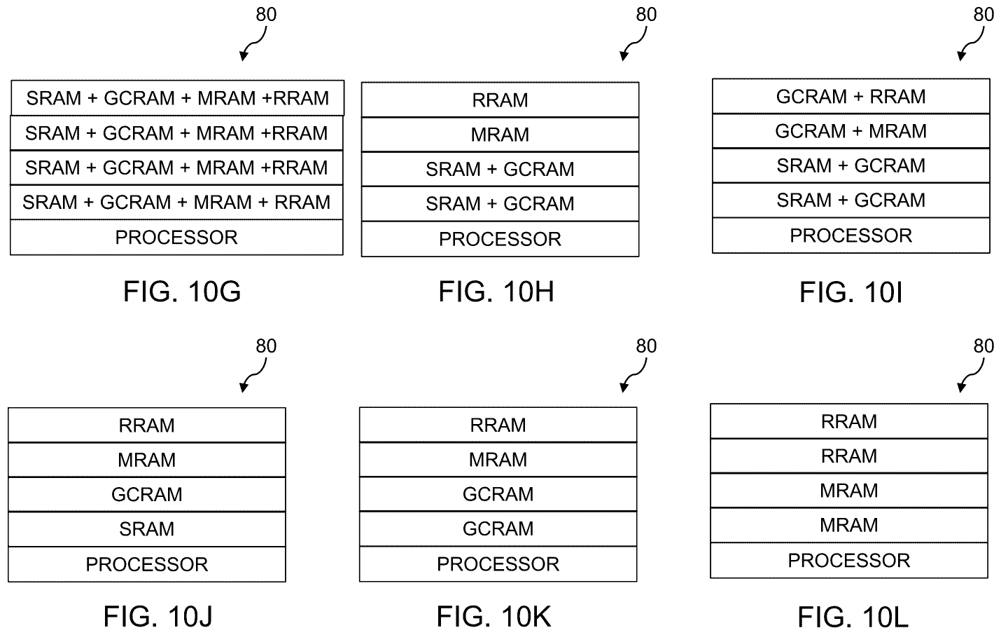

FIGS. 10A-10L are schematic vertical cross-sectional views of various configurations of the second composite package of the present disclosure. Each second composite package 80 may be formed by dicing a bonded wafer assembly including a first wafer 100, a second wafer 200, a third wafer 300, a fourth wafer 400, and a fifth wafer. Each second composite package 80 may include a bonded assembly of a processor die 10, a first memory die 20, a second memory die 30, a third memory die 40, and a fourth memory die 50.

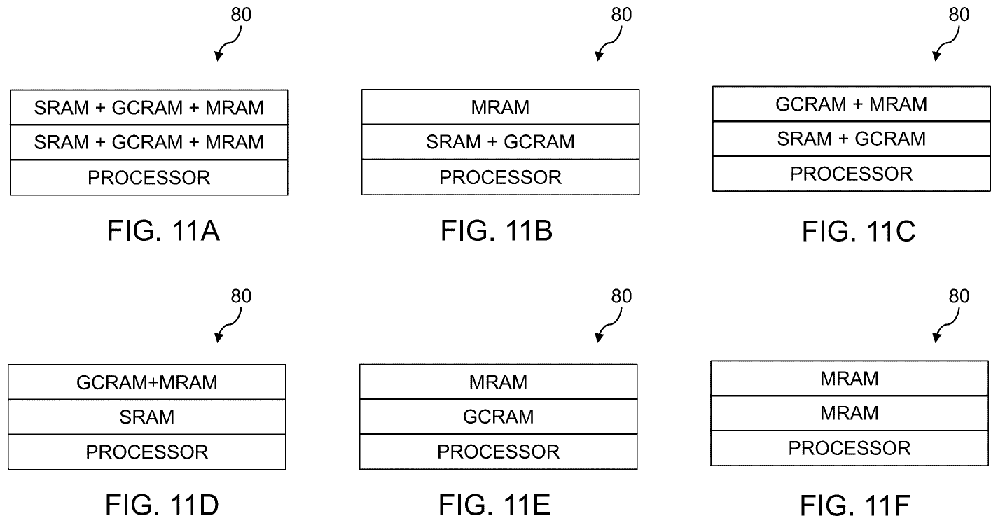

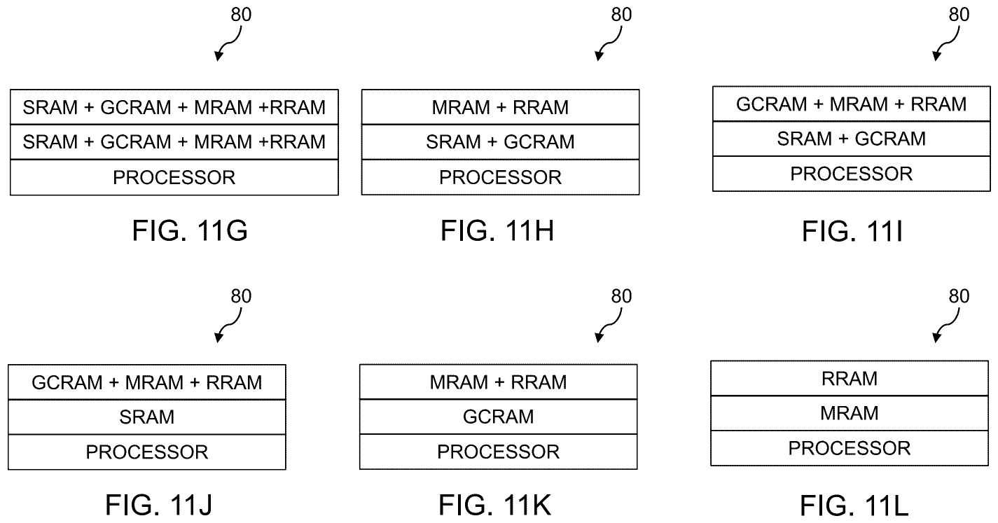

FIGS. 11A-11L are schematic vertical cross-sectional views of various configurations of a third composite package of the present disclosure. Each third composite package 80 may be formed by dicing a bonded wafer assembly including a first wafer 100, a second wafer 200, and a third wafer 300. Each third composite package 80 may include a bonded assembly of a processor die 10, a first memory die 20, and a second memory die 30.

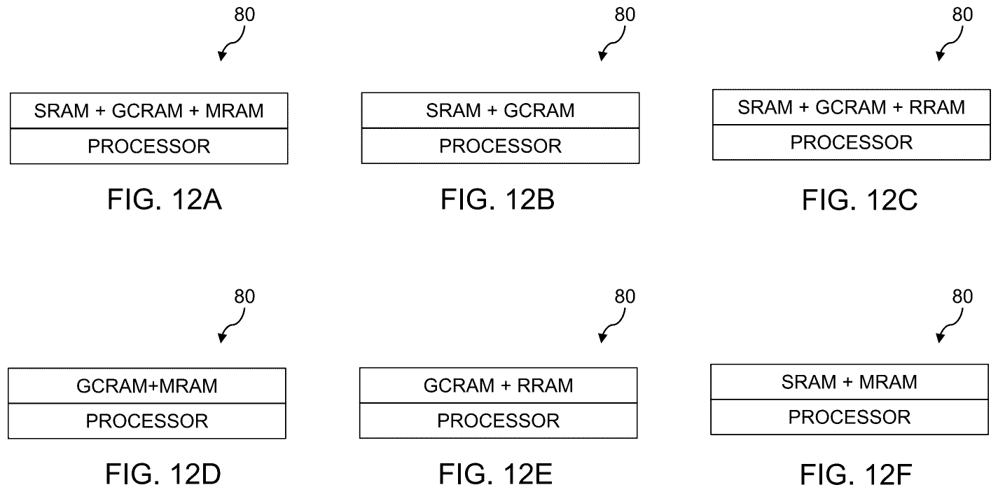

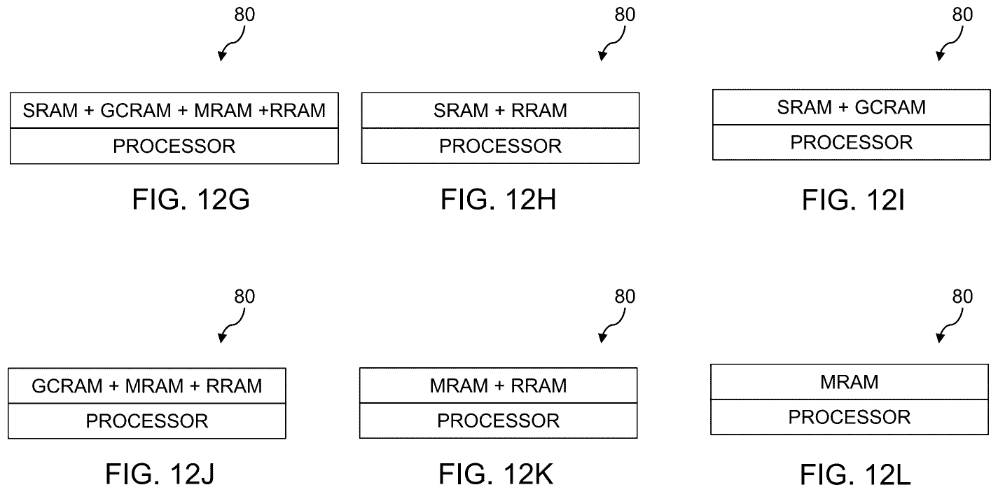

FIGS. 12A-12L are schematic vertical cross-sectional views of various configurations of a fourth composite package of the present disclosure. Each fourth composite package 80 may be formed by dicing a bonded wafer assembly including a first wafer 100 and a second wafer 200. Each fourth composite package 80 may include a bonded assembly of a processor die 10 and a first memory die 20.

Referring collectively to FIGS. 9A-12K, the various types of memory arrays as provided in the memory dies (20, 30, 40, 50) within the composite package 80 of the present disclosure may be used to provide different levels of cache memory for the processor die 10 within the composite package 80. A processing unit (such as a central processing unit (CPU), a graphics processing unit (GPU), digital signal processor (DSP), a neural processing unit (NPU), an artificial intelligence (AI) accelerator, etc.) within the processor die 10 of the present disclosure may use multiple levels of cache memories. The multiple levels of cache memories may include a level 1 (L1) cache memory, a level 2 (L2) cache memory, a level 3 (L3) cache memory, and a level 4 (L4) cache memory.

The level 1 cache memory, or the L1 cache, is the smallest in memory size and the fastest in access speed (i.e., has the smallest latency), and is typically built directly inside a processing unit, and as such, is located within the processor die 10. The level 1 cache memory may include an SRAM array that is located inside the processing unit. The level 1 cache memory stores frequently accessed data and instructions, providing the quickest data access to the processing unit. The level 1 cache may include separate caches for instructions (L1i) and data (L1d).

The level 2 cache memory, or the L2 cache, is larger in memory size than the level 1 cache memory, but is slightly slower in access speed than the level 1 cache memory. According to an aspect of the present disclosure, the level 2 cache memory may be provided within one or more of the memory dies (20, 30, 40, 50) within the composite package 80. The level 2 cache memory may comprise at least one SRAM array located within at least one memory die (20, 30, 40, 50) selected from the memory dies (20, 30, 40, 50) within the composite package 80. Optionally, additional level 2 cache memory may be provided, which may use at least one GCRAM array located within at least one memory die (20, 30, 40, 50) selected from the memory dies (20, 30, 40, 50) within the composite package 80. Each level 2 cache memory may be dedicated to a respective processing unit, or may be shared between multiple processing units. The level 2 cache memory serves as a secondary cache, holding additional data and instructions that the processing unit utilizes less often than the level 1 cache memory.

The level 3 cache memory, or the L3 cache is shared between multiple processing units. The level 3 cache memory functions as a shared cache for all the processing units in a processor die 10 including multiple processing units, thereby allowing data to be shared between all the processing units. The level 3 cache memory, is larger in memory size than the level 2 cache memory, but is slower in access speed than the level 2 cache memory. According to an aspect of the present disclosure, the level 3 cache memory may be provided within one or more of the memory dies (20, 30, 40, 50) within the composite package 80. The level 3 cache memory may comprise at least one GCRAM array located within at least one memory die (20, 30, 40, 50) selected from the memory dies (20, 30, 40, 50) within the composite package 80.

The level 4 cache memory, or the L4 cache, is shared between multiple processing units. The level 4 cache memory functions as a shared cache for all the processing units in a processor die 10 including multiple processing units, thereby allowing data to be shared between all the processing units. The level 4 cache memory, is typically larger in memory size than the level 3 cache memory, but is slower in access speed than the level 3 cache memory. According to an aspect of the present disclosure, the level 4 cache memory may be provided within one or more of the memory dies (20, 30, 40, 50) within the composite package 80. The level 4 cache memory may comprise at least one MRAM array and/or as at least one RRAM located within at least one memory die (20, 30, 40, 50) selected from the memory dies (20, 30, 40, 50) within the composite package 80.

Latency, or memory latency or response time, of a memory refers to the time delay between a time point at which a request for data access or retrieval is made at a processing unit and the time point at which the data becomes available at the processing unit. Memory latency includes various components such as the time taken for the memory controller to issue a command, the access time of the memory cells, and the time needed for the data to be retrieved and transferred. Memory latency may be measured in terms of clock cycles or in time units (e.g., nanoseconds), and varies widely depending on the type of memory array that is addressed.

The memory latency for a level 1 cache memory, comprising a SRAM array embedded within a processing unit 112 (illustrated in FIG. 2B) is very low, typically ranging from 1 to 4 clock cycles. The memory latency for a level 2 cache memory, comprising a SRAM array located in one of the at least one memory die (20, 30, 40, 50) in the composite package 80, may be in a range from 8 clock cycles to 20 clock cycles. The memory latency for a level 2 cache memory, comprising a GCRAM array located in one of the at least one memory die (20, 30, 40, 50) in the composite package 80, may be in a range from 8 clock cycles to 30 clock cycles. The memory latency for a level 3 cache memory, comprising a GCRAM array located in one of the at least one memory die (20, 30, 40, 50) in the composite package 80, may be in a range from 30 clock cycles to 120 clock cycles due to the increase in the size of the memory array relative to the a GCRAM array used as a level 2 cache memory. The memory latency for a level 4 cache memory, comprising a MRAM array or as a RRAM array located in one of the at least one memory die (20, 30, 40, 50) in the composite package 80, may be in a range from 100 clock cycles to 1,000 clock cycles.

The multiple cache levels are used to reduce the time taken to fetch data from the main memory that may be randomly accessed (and thus, is stored in various types of random access memory devices). During operation, a processing unit searches for data first in the fastest cache (i.e., from the level 1 cache memory) and progressively checks the larger but slower caches until the data is eventually found. The longer it takes for the processing unit to find the searched data, the longer the delay in the operation of the processing unit while waiting for the retrieval of the data.

Generally, the level 1 cache memory may be provided within each processing unit 112 (shown in FIG. 2B). The level 2 cache memory may be provided within at least one memory die (20, 30, 40, 50) in the composite package 80. The level 2 cache memory may comprise at least one SRAM array and/or at least one GCRAM array. The level 3 cache memory may be provided within at least one memory die (20, 30, 40, 50) in the composite package 80. The level 3 cache memory may comprise at least one GCRAM array. The level 4 cache memory may be provided within at least one memory die (20, 30, 40, 50) in the composite package 80. The level 4 cache memory may comprise at least one MRAM array and/or at least one RRAM array. Cache memories of different levels (such as the L2 level, the L3 level, and the L4 level) may be present in any of the memory dies (20, 30, 40, 50) in the composite package 80. At least one unified memory controller unit 114 in the processor die 10 describe above may be used to access each of the cache memories that are provided in the memory dies (20, 30, 40, 50).

In a non-limiting first illustrative example, the first memory die 20 may comprise an L2 cache, an L3 cache, and an L4 cache. If a second memory die 30, a third memory die 40, and/or a fourth memory die 50 is/are present, such memory dies (30, 40, 50) may comprise a respective L2 cache, a respective L3 cache, and/or a respective L4 cache. In a non-limiting second illustrative example, the first memory die 20 may comprise an L2 cache, the second memory die 30 may comprise an L3 cache, and the third memory die 40 and the optional fourth memory die 50 may comprise a respective L4 cache. In a non-limiting third illustrative example, the first memory die 20 may comprise an L2 cache and an L3 cache, the second memory die 30 may comprise an optional L3 cache and an L4 cache, and the third memory die 40 and the optional fourth memory die 50 may comprise a respective L4 cache. In a non-limiting fourth illustrative example, an L2 cache and/or an L3 cache may be provided within the processing unit 112 (shown in FIG. 2B) as an embedded memory. In this embodiment, the composite package 80 may comprise at least one L3 cache and/or at least one L4 cache without an L2 cache. The specific examples of combinations of the various types of memory arrays within each composite package 80 illustrated in FIGS. 9A-12L are only illustrative, but are not exhaustive. Any combination of cache memories selected from L2 cache, L3 cache, and L4 cache may be implemented in each of the at least one memory die (20, 30, 40, 50) irrespective of the cache memory configuration in any other memory die (20, 30, 40, 50) within the composite package 80.

In some embodiments, the arrangement of memory dies (20, 30, 40, 50) within the composite package may adhere to a specific hierarchy based on the memory type to provide optimized performance and access speed. In one embodiment in which SRAM, GCRAM, MRAM, and RRAM are all present within the composite package, the SRAM die is positioned closest to the processor unit to leverage its low latency and high speed, followed by the GCRAM die due to its balanced performance characteristics. Subsequently, MRAM and RRAM dies are placed farther from the processor, as these memory types are typically used for higher cache levels (L3 and L4) due to their larger capacity and non-volatile nature. This hierarchical arrangement ensures the most efficient access times for the processor by prioritizing proximity based on the speed and usage frequency of the different memory types. In embodiments in which not all these memory types are present, the same hierarchy may be maintained for the available types, ensuring that the memory dies are positioned to provide optimal performance and latency benefits in accordance with their respective cache levels.

Referring collectively to FIGS. 1-12L and according to various embodiments of the present disclosure, a composite package 80 may be formed by bonding a processor die 10 with at least one memory die (20, 30, 40, 50). Each vertically neighboring pair of dies surrounding the processor die 10 and the at least one memory die (20, 30, 40, 50) is bonded to each other by performing a respective metal-to-metal bonding process in which each mating pair of metal bonding pads (18, 19) are in direct contact at grain boundaries. The processor die 10 comprises processing units for performing logical operations. The at least one memory die (20, 30, 40, 50) comprises at least two types of memory arrays selected from a static random access memory array, a gain cell random access memory array, and magnetoresistive random access memory array, and a resistive random access memory array, whereby a bonded assembly 80 of the processor die 10 and the at least one memory die (20, 30, 40, 50) is formed.

In one embodiment, each of the at least one memory die (20, 30, 40, 50) comprises a respective set of memory address input nodes, and the processor die 10 comprises a unified memory controller unit 114 including a set of memory address output nodes that are electrically connected to each set of memory address input nodes within the at least one memory die (20, 30, 40, 50). In one embodiment, the at least one memory die (20, 30, 40, 50) comprises at least two memory dies (20, 30, 40, 50) that are directly bonded for each vertically neighboring pair thereamongst by metal-to-metal bonding. In one embodiment, a first memory die (20, 30, 40, 50) within the at least two memory dies (20, 30, 40, 50) comprises a first-type memory array that is selected from the at least two types of memory arrays, and a second memory die (20, 30, 40, 50) within the at least two memory dies (20, 30, 40, 50) comprises a second-type memory array that is selected from the at least two types of memory arrays, the second-type memory array being a different type of memory array from the first-type memory array.

In one embodiment, the unified memory controller unit 114 is configured to access each memory element within the at least two types of memory arrays through selection of bit values of a memory address that is transmitted to the set of memory address output nodes. In one embodiment, the unified memory controller unit 114 includes a set of data input nodes, each of the at least one memory die (20, 30, 40, 50) comprises a respective set of data output nodes that is electrically connected to the set of data input nodes, and the unified memory controller unit 114 is configured to receive data stored in any memory element within the at least two types of memory arrays through the set of data input nodes. Thus, data stored in cache memories of different levels (e.g., L2, L3, and L4) and/or memories of different types (e.g., SRAM, GCRAM, MRAM, and RRAM) may be accessed using a same unified memory controller unit 114. Thus, the unified memory controller unit 114 provides a “unified” data control channel that controls all of the level 2 cache memories, the level 3 cache memories, and the level 4 cache memories.

In one embodiment, one the at least one memory die (20, 30, 40, 50) comprises a plurality of types of memory dies (20, 30, 40, 50), and the unified memory controller unit 114 is configured to access each type of memory array selected from the plurality of types of memory dies (20, 30, 40, 50). In one embodiment, memory latencies are different from the at least two types of memory arrays, and the unified memory controller unit 114 is configured to sequentially address two different types of memory arrays selected from the at least two types of memory arrays, and to sequentially receive two sets of data stored in the two different types of memory arrays with a temporal offset using a same set of data input nodes.

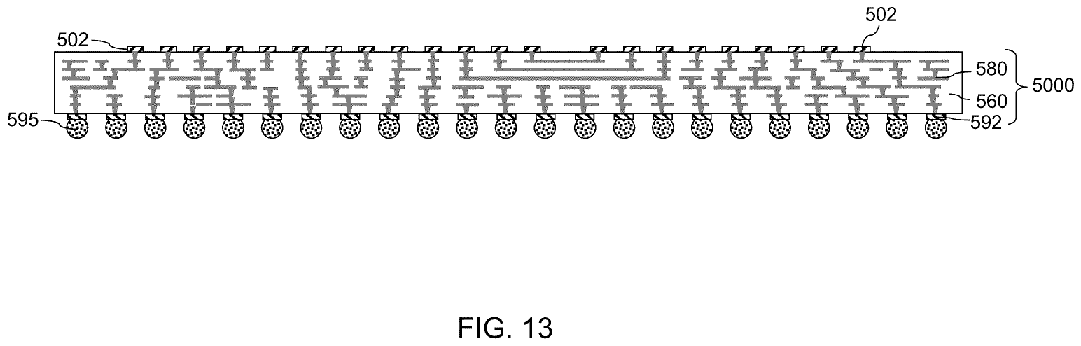

Referring to FIG. 13, an interposer 5000 according to an embodiment of the present disclosure. The interposer 5000 may comprise redistribution wiring interconnects 580 that are formed within redistribution dielectric layers 560. Each of the redistribution dielectric layer 560 may comprise a respective dielectric polymer material such as polyimide (PI), benzocyclobutene (BCB), or polybenzobisoxazole (PBO). Other suitable dielectric polymer materials may also be used. The thickness of each redistribution dielectric layer 560 may be in a range from 2 microns to 40 microns, such as from 4 microns to 20 microns. Each of the redistribution wiring interconnects 580 may comprise a metallic seed layer and a metal layer (which may comprise, for example, copper, nickel, or copper and nickel). The thickness of each redistribution wiring interconnects 580 may be in a range from 2 microns to 40 microns, such as from 4 microns to 10 microns, although lesser or greater thicknesses may also be used. The redistribution wiring interconnects 580 provide various electrically conductive paths through the interposer 5000.

The interposer 5000 may comprise first bump structures 502 (which are also referred to as on-die bump structure) located on a first side of the interposer 5000 and second bump structures 592 (which are also referred to as package-side bump structures) located on a second side of the interposer 5000. The periodicity and the size of a first subset of the first bump structures 502 may be the same as the periodicity and the size of the on-die bump structures 192. Solder material portions, which are herein referred to as interposer-substrate (IS) solder material portions 595 may be attached to the second bump structures 592.

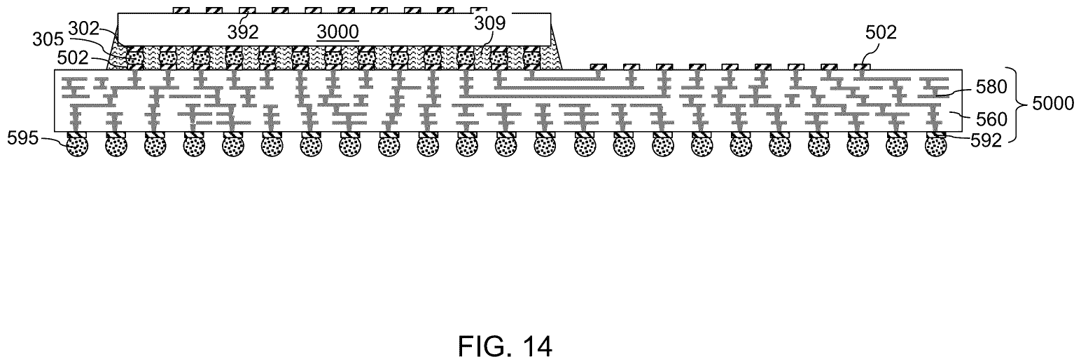

Referring to FIG. 14, a logic die 3000 may be provided. The logic die 3000 comprises a semiconductor die that is configured for direct connection with a high-bandwidth memory (HBM) die. Generally, the logic die 3000 may comprise a semiconductor die that includes a processing unit that requires fast access of data at a high bandwidth. For example, the logic die 3000 may comprise a graphics processing unit (GPU) die, a field-programmable gate array (FPGA) die, or an application-specific integrated circuit (ASIC) die. The logic die 3000 may comprise on-die bump structures 302 having the same periodicity and the same size as a second subset of the first bump structures 502 of the interposer 5000 on one side, and may comprise memory-side bump structures 392 located on another side.

The logic die 3000 may be bonded to the interposer 5000 using solder material portions, which are herein referred to as logic-die-interposer (LDI) solder material portions 305. The LDI solder material portions 305 may be bonded to a respective pair of an on-die bump structure 302 of the logic die and a first bump structure 502 within the second subset of the first bump structures 502 of the interposer 5000. An underfill material portion, which is herein referred to as an logic-die-interposer (LDI) underfill material portion 309, may be applied around the array of LDI solder material portions 305.

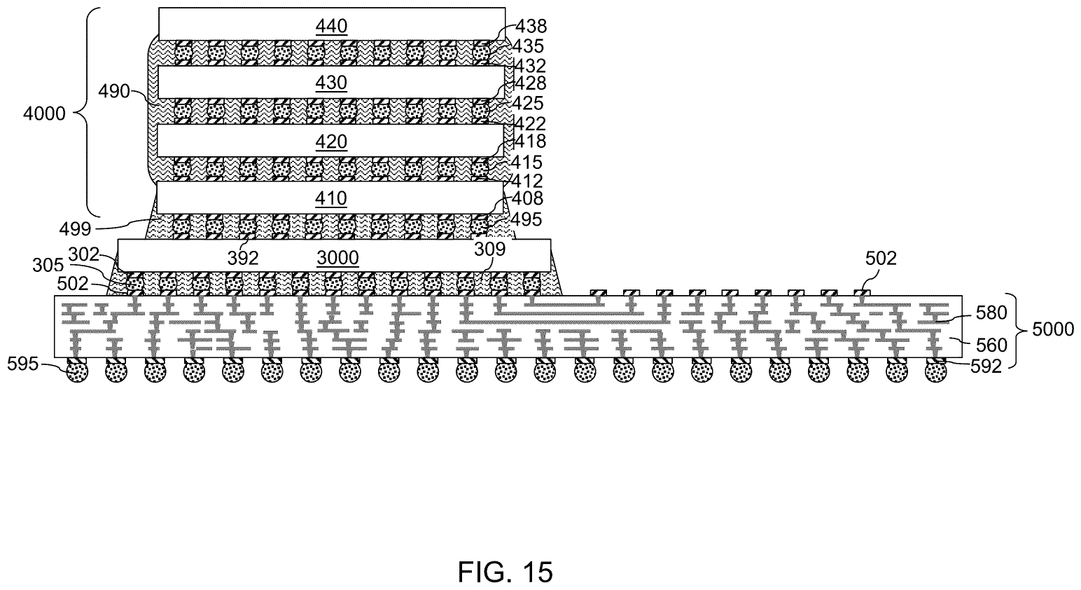

Referring to FIG. 15, a high-bandwidth (HBM) die 4000 is provided. The HBM die 4000 may be any commercially available HBM die 4000. The HBM die 4000 includes a plurality of memory layers (410, 420, 430, 440). Each memory layer (410, 420, 430, 440) may include a respective substrate (not expressly shown), a respective memory array (such as a dynamic random access memory (DRAM) array) located on the respective substrate, a respective set of through-substrate via (TSV) structures (not expressly shown) vertically extending through the respective substrate, a respective set of backside bonding pads (408, 418, 428, 438) connected to the respective set of TSV structures, and respective metal interconnect structures (not shown) and optionally a respective set of front bonding pads (412, 422, 432) that are formed in respective dielectric material layers. The backside bonding pads (408, 418, 428, 438) and the front bonding pads (412, 422, 432) may comprise microbump structures. Solder material portions (415, 425, 435) may be used to provide chip-to-chip bonding between vertically neighboring pairs of memory layers (410, 420, 430, 440). Underfill material portions 490 may laterally surround each array of solder material portions (415, 425, 435) and fill the gap between vertically neighboring pairs of memory layers (410, 420, 430, 440).

The HBM die 4000 may be bonded to the memory-side bump structures 392 of the logic die 3000 using an array of solder material portions, which are herein referred to as memory-logic (ML) solder material portions 495. For example, each ML solder material portion 495 may be bonded to a respective one of the memory-side bump structures 392 of the logic die 3000 and a respective one of the backside bonding pads 408 of the bottommost memory layer 410 of the HBM die 4000. An underfill material portion, which is herein referred to as a memory-logic (ML) underfill material portion 499, may be applied around the array of ML solder material portions 495. Generally, the HBM die 4000 may be attached to a top side of the logic die 3000 using an array of solder material portions (such as the array of ML solder material portions 495).

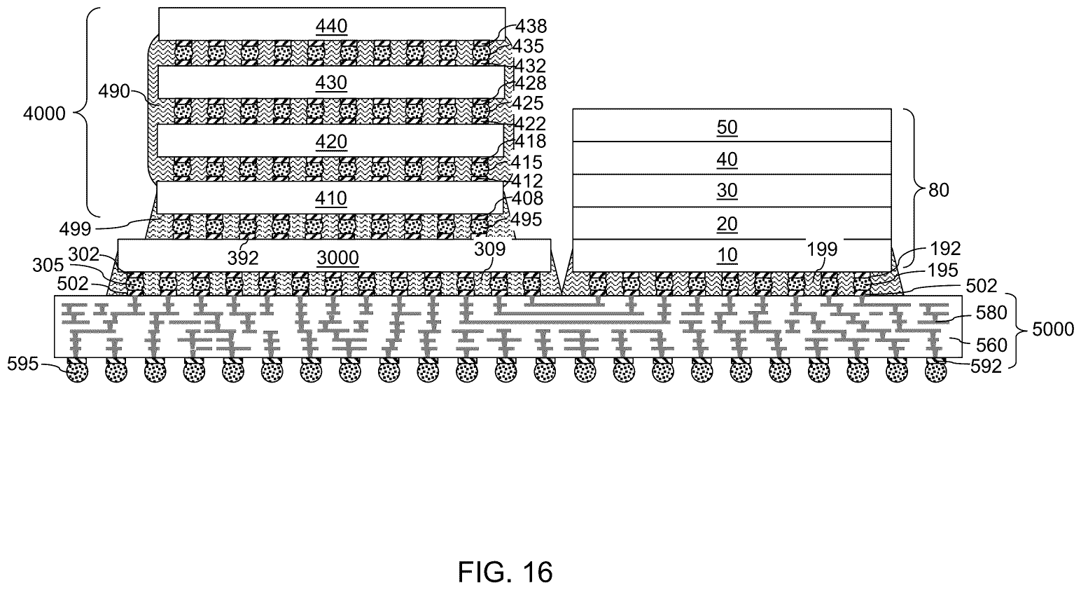

Referring to FIG. 16, any of the composite packages 80 (which is a bonded assembly of a processor die 10 and at least one memory die (20, 30, 40, 50) described above may be bonded to the interposer 5000. For example, an array of solder material portions, which are herein referred to as package-interposer (PI) solder material portions 195, may be attached to the on-die bump structures 192. The array of PI solder material portions 195 may be bonded to the first subset of the first bump structures 502 of the interposer 5000. An underfill material portion, which is herein referred to as a package-interposer (PI) dielectric material portion 199, may laterally surround the array of PI solder material portions 195. A bonded assembly including the interposer 5000, the logic die 3000, the HBM die 4000, and the composite package 80 may be formed.

Thus, the composite packages 80 (which is a bonded assembly of a processor die 10 and at least one memory die (20, 30, 40, 50) may be bonded to the interposer 5000 using an array of PI solder material portions 195. The array of PI solder material portions 195 may be bonded to the on-die bump structures 192 of the processor die 10 and to the first subset of the first bump structures 502 of the interposer 5000.

Generally, the bonding of the logic die 3000 to the second subset of the first bump structures 502 of the interposer 5000 may be performed prior to, or after, bonding the bonded assembly 80 to the interposer 5000. Further, a first array of solder material portions (such as the array of PI solder material portions 195) may be used to bond the composite package 80 to the interposer 5000, and a second array of solder material portions 305 (such as the array of LDI solder material portions 305) may be used to bond the logic die 3000 to the interposer 5000. In one embodiment, electrically conductive paths are formed through a subset of the redistribution wiring interconnects 580 in the interposer 5000 between an input-output controller unit 118 within the processor die 10 and an input-output controller unit (not expressly shown) within the logic die 3000. The input-output controller units 118 of the processor die 10 and the input-output controller units of the logic die 3000 are also referred to as “physical layers,” and include various input/output control circuits configurated to provide fast signal transmission between the processor die 10 and the logic die 3000.

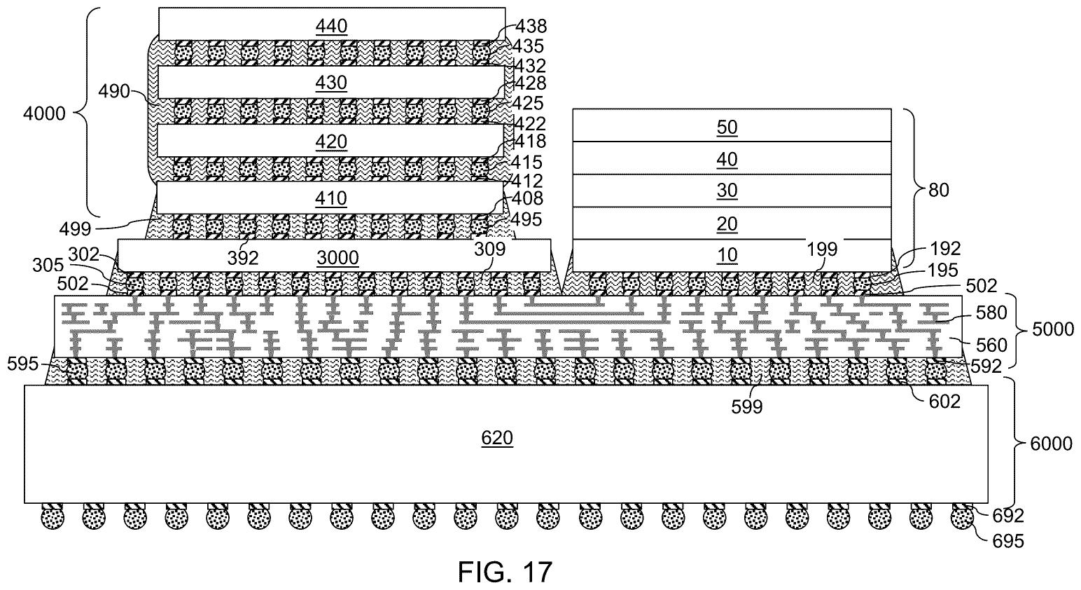

Referring to FIG. 17, a packaging substrate 6000 may be provided. The packaging substrate 6000 may comprise a substrate body 620 including various electrically conductive paths formed within at least one insulating layer, first bonding pads 602 located on one side of the substrate body 620, and second bonding pads 692 located on another side of the substrate body 620. Generally, the packaging substrate 6000 may be a cored packaging substrate, or a coreless packaging substrate that does not include a package core. Alternatively, the packaging substrate 6000 may include a system-on-integrated packaging substrate (SoIS) including redistribution layers, dielectric interlayers, and/or at least one embedded interposer (such as a silicon interposer). Such a system-integrated packaging substrate may include layer-to-layer interconnections using solder material portions, microbumps, underfill material portions (such as molded underfill material portions), and/or an adhesion film. The packaging substrate 6000 may include board-side surface laminar circuit (SLC) and/or a chip-side surface laminar circuit.

The array of interposer-substrate (IS) solder material portions 595 may be bonded to the first bonding pads 602 of the packaging substrate 6000. An underfill material portion, which is herein referred to as an interposer-substrate (IS) underfill material portion 599, may be formed around the array of IS solder material portions 595. Solder balls 695 may be attached to the second bonding pads 692 of the packaging substrate 6000. A bonded assembly including the interposer 5000, the logic die 3000, the HBM die 4000, the composite package 80, and the packaging substrate 6000 may be formed.

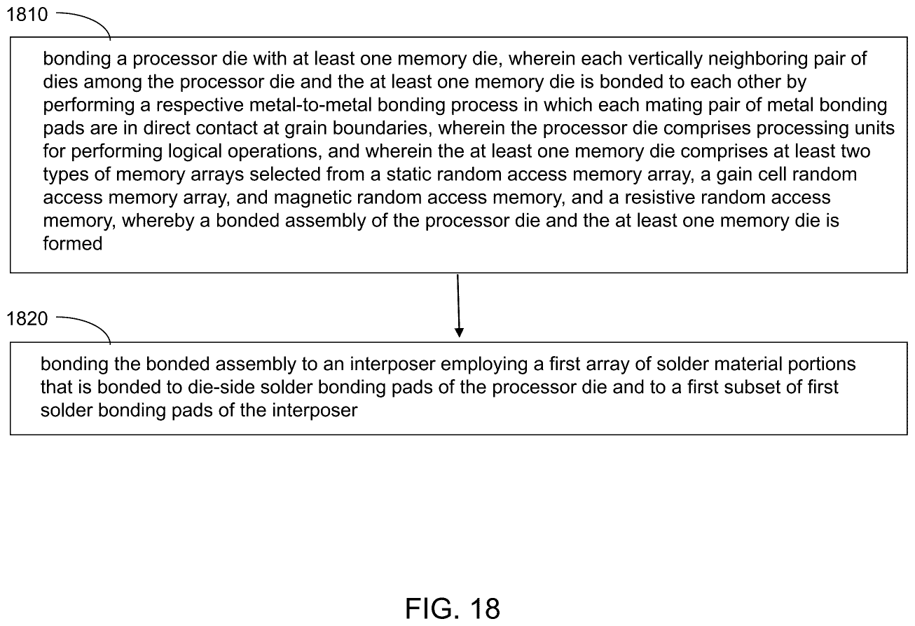

FIG. 18 is a first flowchart illustrating steps for forming a device structure according to an embodiment of the present disclosure.

Referring to step 1810 and FIGS. 1-12L, a processor die 10 may be bonded with at least one memory die (20, 30, 40, 50), which may be multiple memory dies (20, 30, 40, 50). Each vertically neighboring pair of dies surrounding the processor die 10 and the at least one memory die (20, 30, 40, 50) is bonded to each other by performing a respective metal-to-metal bonding process in which each mating pair of metal bonding pads (18, 19) are in direct contact at grain boundaries. The processor die 10 comprises processing units for performing logical operations. The at least one memory die (20, 30, 40, 50) comprises at least two types of memory arrays selected from a static random access memory array, a gain cell random access memory array, and magnetoresistive random access memory array, and a resistive random access memory array. A bonded assembly 80 (which is a composite package 80) of the processor die 10 and the at least one memory die (20, 30, 40, 50) is formed.

Referring to step 1820 and FIGS. 13-17, the bonded assembly 80 (which is a composite package 80) may be bonded to an interposer 5000 using a first array of solder material portions (such as an array of package-interposer (PI) solder material portions 195) that is bonded to on-die bump structures 192 of the processor die 10 and to a first subset of first bump structures 502 of the interposer 5000.

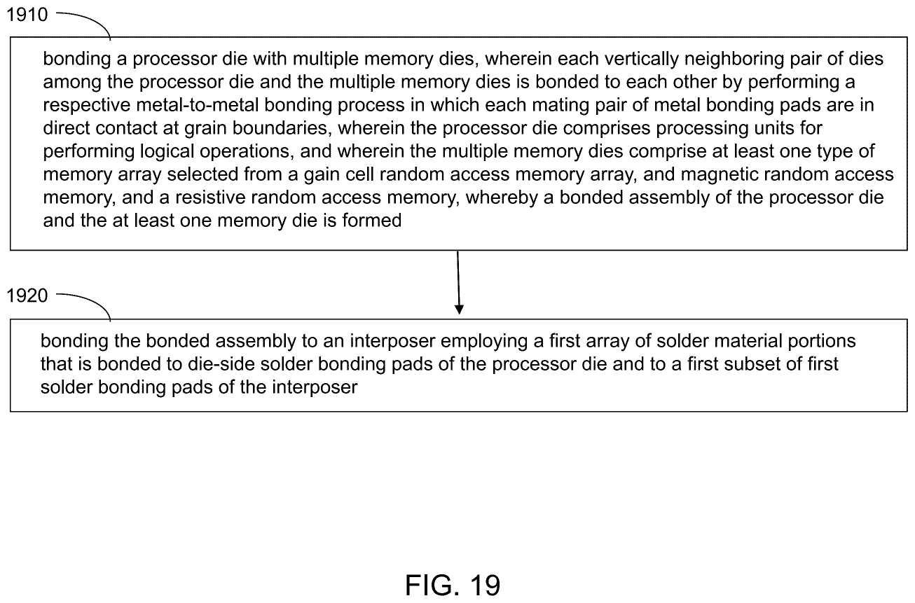

FIG. 19 is a second flowchart illustrating steps for forming a device structure according to an embodiment of the present disclosure.

Referring to step 1910 and FIGS. 1-12L, a processor die 10 may be bonded with multiple memory dies (20, 30, 40, 50). Each vertically neighboring pair of dies surrounding the processor die 10 and the multiple memory dies (20, 30, 40, 50) is bonded to each other by performing a respective metal-to-metal bonding process in which each mating pair of metal bonding pads (18, 19) are in direct contact at grain boundaries. The processor die 10 comprises processing units for performing logical operations. The multiple memory dies (20, 30, 40, 50) comprise at least one type of memory array selected from a gain cell random access memory array, and magnetoresistive random access memory array, and a resistive random access memory array, whereby a bonded assembly 80 of the processor die 10 and the at least one memory die (20, 30, 40, 50) is formed.

Referring to step 1920 and FIGS. 13-17, the bonded assembly 80 may be bonded to an interposer 5000 using a first array of solder material portions (such as an array of package-interposer (PI) solder material portions 195) that is bonded to on-die bump structures 192 of the processor die 10 and to a first subset of first bump structures 502 of the interposer 5000.

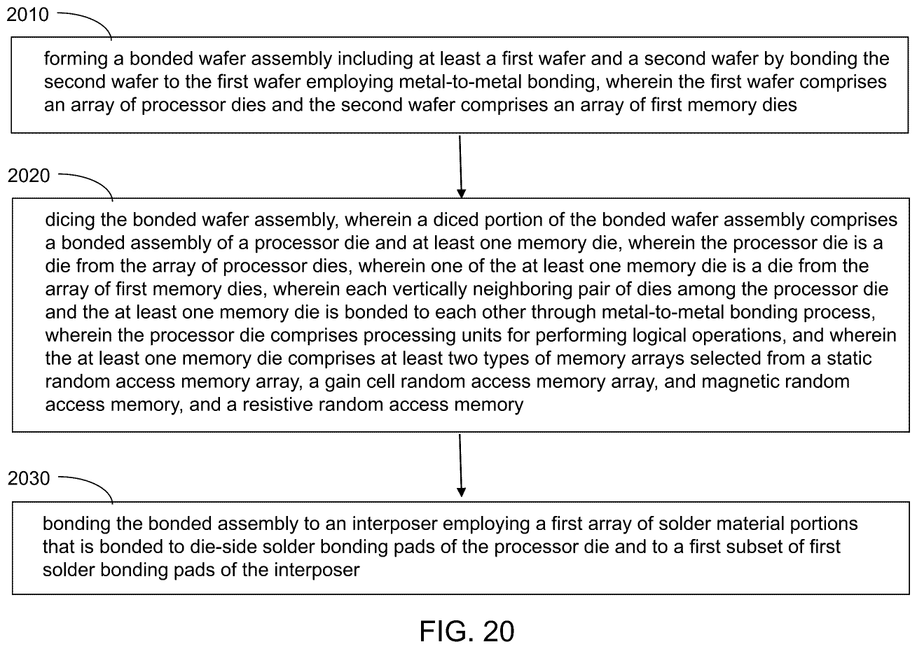

FIG. 20 is a third flowchart illustrating steps for forming a device structure according to an embodiment of the present disclosure.

Referring to step 2010 and FIGS. 1-5C, a bonded wafer assembly (100, 200, 300, 400) including at least a first wafer 100 and a second wafer 200 may be formed by bonding the second wafer 200 to the first wafer 100 using metal-to-metal bonding. The first wafer 100 comprises an array of processor dies 10 and the second wafer comprises an array of first memory dies 20.

Referring to step 2020 and FIGS. 1 and 6A-12L, the bonded wafer assembly (100, 200, 300, 400) may be diced. A diced portion of the bonded wafer assembly (100, 200, 300, 400) comprises a bonded assembly 80 (which is a composite package 80) of a processor die 10 and at least one memory die (20, 30, 40, 50), which may be multiple memory dies (20, 30, 40, 50). The processor die 10 is a die from the array of processor dies 10. One of the at least one memory die (20, 30, 40, 50) (such as a first memory die 20) is a die from the array of first memory dies (20, 30, 40, 50). Each vertically neighboring pair of dies surrounding the processor die 10 and the at least one memory die (20, 30, 40, 50) is bonded to each other through metal-to-metal bonding process. The processor die 10 comprises processing units for performing logical operations. The at least one memory die (20, 30, 40, 50) comprises at least two types of memory arrays selected from a static random access memory array, a gain cell random access memory array, and magnetoresistive random access memory array, and a resistive random access memory.

Referring to step 2030 and FIGS. 13-17, the bonded assembly 80 may be bonded to an interposer 5000 using a first array of solder material portions (such as an array of package-interposer (PI) solder material portions 195) that is bonded to on-die bump structures 192 of the processor die 10 and to a first subset of first bump structures 502 of the interposer 5000.

The three flowcharts shown in FIGS. 18, 19, and 20 do not represent three different inventions or three different methods of forming a bonded assembly comprising a composite die 80, or comprising a combination of the composite die 80 and an interposer 5000. Rather, the three flowcharts shown in FIGS. 18, 19, and 20 illustrate exemplary combinations of features that may be manifested during a same processing scheme for forming a composite die 80 and subsequently attaching the composite die 80 to an interposer 5000. Thus, it is possible to use all of the features described in the three flowcharts, to use only common features among the three flowcharts, or to selectively use features in one or more of the flowcharts.

Referring collectively to all drawings and according to various embodiments of the present disclosure, a device structure is provided. The device structure may comprise: a bonded assembly 80 (which is a composite package 80) of a processor die 10 and at least one memory die (20, 30, 40, 50), wherein each vertically neighboring pair of dies among the processor die 10 and the at least one memory die (20, 30, 40, 50) is bonded to each other by metal-to-metal bonding process, wherein the at least one memory die (20, 30, 40, 50) comprises at least two types of memory arrays selected from a static random access memory array, a gain cell random access memory array, and magnetoresistive random access memory array, and a resistive random access memory; and an interposer 5000 that is bonded to of the processor die 10 through a first array of solder material portions (such as an array of package-interposer (PI) solder material portions 195).

In one embodiment, each of the at least one memory die (20, 30, 40, 50) comprises a respective set of memory address input nodes; and the processor die 10 comprises a unified memory controller unit 114 including a set of memory address output nodes that are electrically connected to each set of memory address input nodes within the at least one memory die (20, 30, 40, 50). In one embodiment, the at least one memory die (20, 30, 40, 50) comprises at least two memory dies (20, 30, 40, 50) that are directly bonded for each vertically neighboring pair thereamongst by metal-to-metal bonding. In one embodiment, a first memory die (20, 30, 40, 50) within the at least two memory dies (20, 30, 40, 50) comprises a first-type memory array that is selected from the at least two types of memory arrays; and a second memory die (20, 30, 40, 50) within the at least two memory dies (20, 30, 40, 50) comprises a second-type memory array that is selected from the at least two types of memory arrays, the second-type memory array being a different type of memory array from the first-type memory array.

In one embodiment, the unified memory controller unit 114 is configured to access each memory element within the at least two types of memory arrays through selection of bit values of a memory address that is transmitted to the set of memory address output nodes. In one embodiment, the unified memory controller unit 114 includes a set of data input nodes; each of the at least one memory die (20, 30, 40, 50) comprises a respective set of data output nodes that is electrically connected to the set of data input nodes; and the unified memory controller unit 114 is configured to receive data stored in any memory element within the at least two types of memory arrays through the set of data input nodes.

In one embodiment, one the at least one memory die (20, 30, 40, 50) comprises a plurality of types of memory dies (20, 30, 40, 50); and the unified memory controller unit 114 is configured to access each type of memory array among the plurality of types of memory dies (20, 30, 40, 50). In one embodiment, memory latencies are different among the at least two types of memory arrays; and the unified memory controller unit 114 is configured to sequentially address two different types of memory arrays among the at least two types of memory arrays, and to sequentially receive two sets of data stored in the two different types of memory arrays with a temporal offset using a same set of data input nodes.

In one embodiment, the device structure comprises a logic die 3000 that is bonded to the interposer 5000. Electrically conductive paths are present through a subset of the redistribution wiring interconnects 580 in the interposer 5000 between an input-output controller unit within the processor die 10 and an input-output controller unit within the logic die 3000. In one embodiment, the device structure comprises a high-bandwidth memory (HBM) die 4000 that is attached to a top side of the logic die 3000 using a third array of solder material portions (such as the array of memory-logic (ML) solder material portions 495). In one embodiment, each sidewall of the at least one memory die (20, 30, 40, 50) is vertically coincident with a respective sidewall of the processor die 10 due to usage of the dicing process during formation of the bonded assembly 80 (which is a composite package 80).

According to another aspect of the present disclosure, a device structure is provided, which comprises: a bonded assembly 80 of a processor die 10 and multiple memory dies (20, 30, 40, 50), wherein each vertically neighboring pair of dies among the processor die 10 and the multiple memory dies (20, 30, 40, 50) is bonded to each other by metal-to-metal bonding in which each mating pair of metal bonding pads (18, 19) are in direct contact at grain boundaries, wherein the processor die 10 comprises processing units for performing logical operations, and wherein the multiple memory dies (20, 30, 40, 50) comprise at least one type of memory array selected from a gain cell random access memory array, and magnetoresistive random access memory array, and a resistive random access memory array, whereby a bonded assembly 80 of the processor die 10 and the at least one memory die (20, 30, 40, 50) is formed; and an interposer 5000 that is bonded to the bonded assembly 80 through a first array of solder material portions (such as an array of package-interposer (PI) solder material portions 195) that is bonded to on-die bump structures 192 of the processor die 10 and to a first subset of first bump structures 502 of the interposer 5000.

In one embodiment, each of the multiple memory dies (20, 30, 40, 50) comprises a respective set of memory address input nodes; and the processor die 10 comprises a unified memory controller unit 114 including a set of memory address output nodes that are electrically connected to each set of memory address input nodes within the at least one memory die (20, 30, 40, 50) (which may be multiple memory dies (20, 30, 40, 50). In one embodiment, the unified memory controller unit 114 includes a set of data input nodes; each of the multiple memory dies (20, 30, 40, 50) comprises a respective set of data output nodes that is electrically connected to the set of data input nodes; and the unified memory controller unit 114 is configured to receive data stored in any memory element within the at least one type of memory array through the set of data input nodes.

In one embodiment, one of the multiple memory dies (20, 30, 40, 50) comprise a static random access memory (SRAM) array. In one embodiment, the unified memory controller unit 114 is configured to access each memory element within each of the multiple memory dies (20, 30, 40, 50) through selection of bit values of a memory address that is transmitted to the set of memory address output nodes.

According to yet another aspect of the present disclosure, a device structure is provided, which comprises: a bonded assembly 80 of a processor die 10 and at least one memory die (20, 30, 40, 50), wherein each vertically neighboring pair of dies among the processor die 10 and the at least one memory die (20, 30, 40, 50) is bonded to each other by metal-to-metal bonding in which each mating pair of metal bonding pads (18, 19) are in direct contact at grain boundaries, wherein the processor die 10 comprises processing units for performing logical operations, and wherein the at least one memory die (20, 30, 40, 50) comprises at least two types of memory arrays selected from a static random access memory array, a gain cell random access memory array, and magnetoresistive random access memory array, and a resistive random access memory; and an interposer 5000 comprising redistribution metal interconnects formed within redistribution dielectric layers and further comprising first bump structures 502. The processor die 10 comprises on-die bump structures 192 that are bonded to a first subset of first bump structures 502 of the interposer 5000 through a first array of solder material portions (such as an array of package-interposer (PI) solder material portions 195).

In one embodiment, each of the at least one memory die (20, 30, 40, 50) comprises a respective set of memory address input nodes; and the processor die 10 comprises a unified memory controller unit 114 including a set of memory address output nodes that are electrically connected to each set of memory address input nodes within the at least one memory die (20, 30, 40, 50). In one embodiment, each sidewall of the at least one memory die (20, 30, 40, 50) is vertically coincident with a respective sidewall of the processor die 10. In one embodiment, the device structure comprises a logic die 3000 that is bonded to a second subset of the first bump structures 502 of the interposer 5000 through a second array of solder material portions 305. Electrically conductive paths are present through a subset of the redistribution wiring interconnects 580 in the interposer 5000 between an input-output controller unit within the processor die 10 and an input-output controller unit within the logic die 3000.

The various embodiments of the present disclosure may be used to provide a processor die 10 in communication with a logic die 3000 on an interposer 5000 and having access to various levels of cache memories that are readily accessible. A large amount of cache memories at the L2 level, L3 level, and L4 level may be accessed from within a composite package 80 within which all dies (10, 20, 30, 40, 50) are interconnected among one another through metal-to-metal bonding. Unified memory controller units 114 may access memory arrays having different signal latencies by merely changing the address of the memory cells located within different types of memory arrays and providing different latencies. The unified memory controller units 114 may sequentially access different types of memory arrays having different latencies using a same set of input/output driver devices. The metal-to-metal bonding and use of the through-substrate via structures 4 enable a large bandwidth and a fast signal transmission time through the stacks of dies (10, 20, 30, 40, 50) within the composite package 80.

The foregoing outlines features of several embodiments so that those skilled in the art may better understand the aspects of the present disclosure. Each embodiment described using the term “comprises” also inherently discloses additional embodiments in which the term “comprises” is replaced with “consists essentially of” or with the term “consists of,” unless expressly disclosed otherwise herein. Whenever two or more elements are listed as alternatives in a same paragraph of in different paragraphs, a Markush group including a listing of the two or more elements is also impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure, comprising:
bonding a processor die with at least one memory die, wherein each vertically neighboring pair of dies among the processor die and the at least one memory die is bonded to each other by performing a respective metal-to-metal bonding process in which each mating pair of metal bonding pads are in direct contact at grain boundaries, wherein the processor die comprises processing units for performing logical operations, and wherein the at least one memory die comprises at least two types of memory arrays selected from a static random access memory array, a gain cell random access memory array, and magnetoresistive random access memory array, and a resistive random access memory array, whereby a bonded assembly of the processor die and the at least one memory die is formed; and
bonding the bonded assembly to an interposer using a first array of solder material portions that is bonded to on-die bump structures of the processor die and to a first subset of first bump structures of the interposer.

2. The method of claim 1, wherein:
each of the at least one memory die comprises a respective set of memory address input nodes; and
the processor die comprises a unified memory controller unit including a set of memory address output nodes that are electrically connected to each set of memory address input nodes within the at least one memory die.

3. The method of claim 2, wherein the at least one memory die comprises at least two memory dies that are directly bonded for each vertically neighboring pair thereamongst by metal-to-metal bonding.

4. The method of claim 3, wherein:
a first memory die within the at least two memory dies comprises a first-type memory array that is selected from the at least two types of memory arrays; and
a second memory die within the at least two memory dies comprises a second-type memory array that is selected from the at least two types of memory arrays, the second-type memory array being a different type of memory array from the first-type memory array.

5. The method of claim 2, wherein the unified memory controller unit is configured to access each memory element within the at least two types of memory arrays through selection of bit values of a memory address that is transmitted to the set of memory address output nodes.

6. The method of claim 5, wherein:
the unified memory controller unit includes a set of data input nodes;
each of the at least one memory die comprises a respective set of data output nodes that is electrically connected to the set of data input nodes; and
the unified memory controller unit is configured to receive data stored in any memory element within the at least two types of memory arrays through the set of data input nodes.

7. The method of claim 5, wherein:
one the at least one memory die comprises a plurality of types of memory dies; and
the unified memory controller unit is configured to access each type of memory array selected from the plurality of types of memory dies.

8. The method of claim 5, wherein:
memory latencies are different from the at least two types of memory arrays; and
the unified memory controller unit is configured to sequentially address two different types of memory arrays selected from the at least two types of memory arrays and to sequentially receive two sets of data stored in the two different types of memory arrays with a temporal offset using a same set of data input nodes.

9. The method of claim 1, further comprising bonding a logic die to a second subset of the first bump structures of the interposer prior to, or after, bonding the bonded assembly to the interposer using a second array of solder material portions such that electrically conductive paths are formed through a subset of redistribution wiring interconnects in the interposer between an input-output controller unit within the processor die and an input-output controller unit within the logic die.

10. The method of claim 9, further comprising attaching a high-bandwidth memory (HBM) die to a top side of the logic die using a third array of solder material portions.

11. The method of claim 1, wherein:
each of the processor die and the at least one memory die is provided as a die within a respective wafer including a respective two-dimensional array of dies; and
the method further comprises:
performing at least one wafer bonding process that provides metal-to-metal bonding to a set of wafers including the processor die and the at least one memory die and forms a bonded wafer assembly in which the set of wafers is bonded to one another, whereby the bonded assembly of the processor die and the at least one memory die is formed within the bonded wafer assembly; and
dicing the bonded wafer assembly, whereby the bonded assembly of the processor die and the at least one memory die is a singulated piece of the bonded wafer assembly that remains after said dicing.

12. The method of claim 11, further comprising:
performing a first wafer bonding process that bonds a first wafer including an array of processor dies to a carrier wafer, wherein the processor die is a die within the array of processor dies;
performing a second wafer bonding process that bonds a second wafer including an array of first memory dies to the first wafer, wherein one of the at least one memory die is a die within the array of first memory dies; and
detaching the carrier wafer from an assembly including the set of wafers, whereby the bonded wafer assembly is provided.

13. The method of claim 12, wherein:
the at least one memory die comprises multiple memory dies;
the method comprises performing a third wafer bonding process that bonds a third wafer including an array of second memory dies to the second wafer; and
another of the multiple memory dies is a die within the array of second memory dies.

14. A method of forming a device structure, comprising:
bonding a processor die with multiple memory dies, wherein each vertically neighboring pair of dies among the processor die and the multiple memory dies is bonded to each other by performing a respective metal-to-metal bonding process in which each mating pair of metal bonding pads are in direct contact at grain boundaries, wherein the processor die comprises processing units for performing logical operations, and wherein the multiple memory dies comprise at least one type of memory array selected from a gain cell random access memory array, and magnetoresistive random access memory array, and a resistive random access memory array, whereby a bonded assembly of the processor die and at least one memory die is formed; and
bonding the bonded assembly to an interposer using a first array of solder material portions that is bonded to on-die bump structures of the processor die and to a first subset of first bump structures of the interposer.

15. The method of claim 14, wherein:
each of the multiple memory dies comprises a respective set of memory address input nodes; and
the processor die comprises a unified memory controller unit including a set of memory address output nodes that are electrically connected to each set of memory address input nodes within the at least one memory die.

16. The method of claim 15, wherein:
the unified memory controller unit includes a set of data input nodes;
each of the multiple memory dies comprises a respective set of data output nodes that is electrically connected to the set of data input nodes; and
the unified memory controller unit is configured to receive data stored in any memory element within the at least one type of memory array through the set of data input nodes.

17. A device structure comprising:
a bonded assembly of a processor die and at least one memory die, wherein each vertically neighboring pair of dies among the processor die and the at least one memory die is bonded to each other by metal-to-metal bonding in which each mating pair of metal bonding pads are in direct contact at grain boundaries, wherein the processor die comprises processing units for performing logical operations, and wherein the at least one memory die comprises at least two types of memory arrays selected from a static random access memory array, a gain cell random access memory array, and magnetoresistive random access memory array, and a resistive random access memory; and
an interposer comprising redistribution metal interconnects formed within redistribution dielectric layers and further comprising first bump structures,
wherein the processor die comprises on-die bump structures that are bonded to a first subset of first bump structures of the interposer through a first array of solder material portions.

18. The device structure of claim 17, wherein:
each of the at least one memory die comprises a respective set of memory address input nodes; and
the processor die comprises a unified memory controller unit including a set of memory address output nodes that are electrically connected to each set of memory address input nodes within the at least one memory die.

19. The device structure of claim 17, wherein each sidewall of the at least one memory die is vertically coincident with a respective sidewall of the processor die.

20. The device structure of claim 17, further comprising a logic die that is bonded to a second subset of the first bump structures of the interposer through a second array of solder material portions, wherein electrically conductive paths are present through a subset of redistribution wiring interconnects in the interposer between an input-output controller unit within the processor die and an input-output controller unit within the logic die.
